(19) United States
(12) Patent Application Publication
(10) Pub. No.: US 2023/0189612 A1
(43) Pub. Date: Jun. 15, 2023

(54) LIGHT EMITTING ELEMENT AND DISPLAY DEVICE

(71) Applicant: Sony Semiconductor Solutions Corporation, Kanagawa (JP)

(72) Inventor: Eisuke Negishi, Tokyo (JP)

(21) Appl. No.: 18/016,010

(22) PCT Filed: Jul. 8, 2021
(86) PCT No.: PCT/JP2021/025747

§ 371 Date: Jan. 13, 2023

(30) Foreign Application Priority Data
Jul. 20, 2020 (JP) 2020-123951

(51) Int. Cl. H10K 59/38

(52) U.S. Cl. CPC H10K 59/38

(57) ABSTRACT

A light emitting element includes: a protrusion (28) surrounding a light emitting region (30); a first electrode (31) including a first portion (31A) formed on a portion of a base (26) constituting the light emitting region (28) and a second portion (31B) extending from the first portion (31A) and formed on the protrusion (28); an organic layer (33) formed on and above the first electrode (31); a second electrode (32) formed on the organic layer (33); a first wavelength conversion layer (41₁, 41₂) that is formed between the second portion (31B) of the first electrode (31) and a portion of the organic layer (33) formed above the protrusion (28) and converts light emitted from the organic layer (33) into light on a long wavelength side; and a second wavelength conversion layer (42₁, 42₂) that is formed on or above the second electrode (32) and converts light emitted from the organic layer (33) into light on a long wavelength side.

### FIELD

The present disclosure relates to a light emitting element and a display device.

### BACKGROUND

In recent years, a display device (organic electroluminescence (EL) display device) using an organic EL element as a light emitting element has been developed. This organic EL display device includes, for example, a plurality of light emitting elements in each of which an organic layer including at least a light emitting layer and a second electrode (an upper electrode, for example, a cathode electrode) are formed on a first electrode (a lower electrode, for example, an anode electrode) formed separately for each pixel. For example, each of a red light emitting element, a green light emitting element, and a blue light emitting element is disposed as a sub-pixel, and one pixel is constituted by these sub-pixels. For example, light from a light emitting layer is emitted to the outside via the second electrode (upper electrode).

As an organic EL display device with an improved contrast ratio and favorable visibility, a display device including a plurality of types of color conversion filters is known from, for example, JP 2003-243153 A. The display device causes light in a near-ultraviolet to visible region, preferably light in a blue to blue-green region, emitted from an organic EL layer, to be incident on a color conversion filter layer to emit visible light having a desired color. The color conversion filter includes, for example, a laminate of a color filter layer and a fluorescence conversion layer, and a black mask.

### CITATION LIST

### Patent Literature

Patent Literature 1: JP 2003-243153 A

### SUMMARY

### Technical Problem

By the way, a display device disclosed in JP 2003-243153 A has a problem that light in a near-ultraviolet to visible region emitted from an organic EL layer constituting a certain sub-pixel is incident on an organic EL layer constituting a sub-pixel adjacent to the certain sub-pixel, and light emitted in the certain sub-pixel is wasted, or so-called optical crosstalk occurs.

Therefore, an object of the present disclosure is to provide a light emitting element having a configuration and a structure in which light emitted in an organic layer can be efficiently used for image formation and optical crosstalk hardly occurs, and a display device including a plurality of the light emitting elements.

### Solution to Problem

A light emitting element according to a first aspect of the present disclosure in order to solve the above problem includes:

a protrusion surrounding a light emitting region;

a first electrode including a first portion formed on a portion of a base constituting the light emitting region and a second portion extending from the first portion and formed on the protrusion;

an organic layer formed on and above the first electrode;

a second electrode formed on the organic layer;

a first wavelength conversion layer that is formed between the second portion of the first electrode and a portion of the organic layer formed above the protrusion and converts light emitted from the organic layer into light on a long wavelength side; and

a second wavelength conversion layer that is formed on or above the second electrode and converts light emitted from the organic layer into light on a long wavelength side.

A light emitting element according to a second aspect of the present disclosure in order to solve the above problem includes:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits first light having a wavelength λ₁;

a second electrode formed on the organic layer;

a first-A wavelength conversion layer that is formed between the second portion of the first electrode and a portion of the organic layer formed above the protrusion and converts the first light emitted from the organic layer into second light having a wavelength λ₂ (λ₂>λ₁); and

a first-B wavelength conversion layer that is formed in a region between the second portion of the first electrode and a portion of the organic layer formed above the protrusion, different from the region where the first-A wavelength conversion layer is formed, and converts the first light emitted from the organic layer into third light having a wavelength λ₃ (λ₃>λ₂).

A display device according to a third aspect of the present disclosure in order to solve the above problem, in which a plurality of light emitting element units each including a first light emitting element, a second light emitting element, and a third light emitting element is arranged, wherein

the first light emitting element includes:

a protrusion surrounding a light emitting region;

a first electrode including a first portion formed on a portion of a base constituting the light emitting region and a second portion extending from the first portion and formed on the protrusion;

an organic layer that is formed on the first electrode and emits first light having a wavelength λ₁; and

a second electrode formed on the organic layer, the second light emitting element includes:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits the first light;

a second electrode formed on the organic layer;

a first-A wavelength conversion layer that is formed between the second portion of the first electrode and a portion of the organic layer formed above the protrusion, and converts the first light emitted from the organic layer into second light having a wavelength λ₂ (λ₂>λ₁); and

a second-A wavelength conversion layer that is formed on or above the second electrode and converts the first light emitted from the organic layer into the second light, and

the third light emitting element includes:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits the first light;

a second electrode formed on the organic layer;

a first-B wavelength conversion layer that is formed between the second portion of the first electrode and a portion of the organic layer formed above the protrusion, and converts the first light emitted from the organic layer into third light having a wavelength λ₃ (λ₃>λ₂); and

a second-B wavelength conversion layer that is formed on or above the second electrode and converts the first light emitted from the organic layer into the third light.

### BRIEF DESCRIPTION OF DRAWINGS

FIG. 1 is a schematic partial cross-sectional view of a light emitting element and a display device of Example 1.

FIG. 2 is a schematic partial cross-sectional view of Modification-1 of the light emitting element and the display device of Example 1.

FIG. 3 is a schematic partial cross-sectional view of Modification-2 of the light emitting element and the display device of Example 1.

FIG. 4 is a schematic partial cross-sectional view of Modification-3 of the light emitting element and the display device of Example 1.

FIG. 5 is a schematic partial cross-sectional view of Modification-4 of the light emitting element and the display device of Example 1.

FIG. 6 is a schematic partial cross-sectional view of Modification-5 of the light emitting element and the display device of Example 1.

FIG. 7A is a diagram schematically illustrating an arrangement of light emitting elements in the display device of Example 1.

FIG. 7B is a diagram schematically illustrating an arrangement of light emitting elements in the display device of Example 1.

FIG. 7C is a diagram schematically illustrating an arrangement of light emitting elements in the display device of Example 1.

FIG. 7D is a diagram schematically illustrating an arrangement of light emitting elements in a display device of Example 2.

FIG. 8A is a diagram schematically illustrating an arrangement state of an arrangement state of a base and a protrusion in the display device of Example 1.

FIG. 8B is a diagram schematically illustrating an arrangement state of first electrodes.

FIG. 9A is a diagram schematically illustrating an arrangement state of an arrangement state of an organic layer and a first wavelength conversion layer in the display device of Example 1.

FIG. 9B is a diagram schematically illustrating an arrangement state of second electrodes.

FIG. 10A is a diagram schematically illustrating an arrangement state of an arrangement state of first electrodes in Modification-1 of the display device of Example 1.

FIG. 10B is a diagram schematically illustrating an arrangement state of an organic layer and a first wavelength conversion layer.

FIG. 11 is a schematic partial cross-sectional view of the light emitting element and the display device of Example 2.

FIG. 12A is a diagram schematically illustrating an arrangement state of an arrangement state of a base and a protrusion in the display device of Example 2.

FIG. 12B is a diagram schematically illustrating an arrangement state of first electrodes.

FIG. 13A is a diagram schematically illustrating an arrangement state of an arrangement state of an organic layer and a first wavelength conversion layer in the display device of Example 2.

FIG. 13B is a diagram schematically illustrating an arrangement state of second electrodes.

FIG. 14 is a diagram schematically illustrating an arrangement state of an arrangement state of an organic layer and a first wavelength conversion layer in Modification-1 of the display device of Example 2.

FIG. 15A is a diagram schematically illustrating an arrangement state of first electrodes in Modification-2 of the display device of Example 2.

FIG. 15B is a diagram schematically illustrating an arrangement state of an arrangement state of an organic layer and a first wavelength conversion layer.

FIG. 16 is a diagram schematically illustrating an arrangement state of an arrangement state of an organic layer and a first wavelength conversion layer in Modification-3 of the display device of Example 2.

FIG. 17 is a schematic partial cross-sectional view of Modification-3 of the light emitting element and the display device of Example 2.

FIG. 18 is a schematic partial cross-sectional view of a light emitting element and a display device of Example 3.

FIG. 19A is a diagram schematically illustrating an arrangement state of an arrangement state of a base and a protrusion in the display device of Example 3.

FIG. 19B is a diagram schematically illustrating an arrangement state of first electrodes.

FIG. 20A is a diagram schematically illustrating an arrangement state of an arrangement state of an organic layer and a first wavelength conversion layer in the display device of Example 3.

FIG. 20B is a diagram schematically illustrating an arrangement state of second electrodes.

FIG. 21 is a schematic partial cross-sectional view of a light emitting element and a display device of Example 4.

FIG. 22 is a schematic partial cross-sectional view of a light emitting element and a display device of Example 5.

FIG. 23 is a schematic partial cross-sectional view of Modification-1 of the light emitting element and the display device of Example 5.

FIG. 24 is a schematic partial cross-sectional view of Modification-2 of the display device and the light emitting element of Example 5.

FIG. 25 is a schematic partial cross-sectional view of Modification-3 of the display device and the light emitting element of Example 5.

FIG. 26 is a schematic partial cross-sectional view of Modification-4 of the display device of Example 5, in which an optical path control unit is made of a light reflecting member.

FIG. 27 is a schematic partial cross-sectional view of a display device of Example 6.

FIG. 28 is a conceptual diagram for explaining a distance (offset amount) D₀ between a normal line LN passing through the center of a light emitting region and a normal line LN′ passing through the center of an optical path control unit in the display device of Example 6.

FIG. 29A is a schematic diagram illustrating a positional relationship between a light emitting element and a reference point in the display device of Example 6.

FIG. 29B is a schematic diagram illustrating a positional relationship between the light emitting element and the reference point in the display device of Example 6.

FIG. 30A is a diagram schematically illustrating a positional relationship between a light emitting element and a reference point in a modification of the display device of Example 6.

FIG. 30B is a diagram schematically illustrating a positional relationship between a light emitting element and a reference point in a modification of the display device of Example 6.

FIG. 31A is a diagram schematically illustrating a change in D_{0-X} with respect to a change in D_{1-X} and a change in D_{0-Y} with respect to a change in D_{1-Y}.

FIG. 31B is a diagram schematically illustrating a change in D_{0-X} with respect to a change in D_{1-X} and a change in D_{0-Y} with respect to a change in D_{1-Y}.

FIG. 31C is a diagram schematically illustrating a change in D_{0-X} with respect to a change in D_{1-X} and a change in D_{0-Y} with respect to a change in D_{1-Y}.

FIG. 31D is a diagram schematically illustrating a change in D_{0-X} with respect to a change in D_{1-X} and a change in D_{0-Y} with respect to a change in D_{1-Y}.

FIG. 32A is a diagram schematically illustrating a change in D_{0-X} with respect to a change in D_{1-X} and a change in D_{0-Y} with respect to a change in D_{1-Y}.

FIG. 32B is a diagram schematically illustrating a change in D_{0-X} with respect to a change in D_{1-X} and a change in D_{0-Y} with respect to a change in D_{1-Y}.

FIG. 32C is a diagram schematically illustrating a change in D_{0-X} with respect to a change in D_{1-X} and a change in D_{0-Y} with respect to a change in D_{1-Y}.

FIG. 32D is a diagram schematically illustrating a change in D_{0-X} with respect to a change in D_{1-X} and a change in D_{0-Y} with respect to a change in D_{1-Y}.

FIG. 33A is a diagram schematically illustrating a change in D_{0-X} with respect to a change in D_{1-X} and a change in D_{0-Y} with respect to a change in D_{1-Y}.

FIG. 33B is a diagram schematically illustrating a change in D_{0-X} with respect to a change in D_{1-X} and a change in D_{0-Y} with respect to a change in D_{1-Y}.

FIG. 33C is a diagram schematically illustrating a change in D_{0-X} with respect to a change in D_{1-X} and a change in D_{0-Y} with respect to a change in D_{1-Y}.

FIG. 33D is a diagram schematically illustrating a change in D_{0-X} with respect to a change in D_{1-X} and a change in D_{0-Y} with respect to a change in D_{1-Y}.

FIG. 34A is a diagram schematically illustrating a change in D_{0-X} with respect to a change in D_{1-X} and a change in D_{0-Y} with respect to a change in D_{1-Y}.

FIG. 34B is a diagram schematically illustrating a change in D_{0-X} with respect to a change in D_{1-X} and a change in D_{0-Y} with respect to a change in D_{1-Y}.

FIG. 34C is a diagram schematically illustrating a change in D_{0-X} with respect to a change in D_{1-X} and a change in D_{0-Y} with respect to a change in D_{1-Y}.

FIG. 34D is a diagram schematically illustrating a change in D_{0-X} with respect to a change in D_{1-X} and a change in D_{0-Y} with respect to a change in D_{1-Y}.

FIG. 35A is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 35B is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 35C is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 36 is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 37A is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 37B is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 38 is a conceptual diagram for explaining a relationship among a normal line LN passing through the center of a light emitting region, a normal line LN′ passing through the center of an optical path control unit, and a normal line LN″ passing through the center of a wavelength selection unit.

FIG. 39A is a schematic plan view of an optical path control unit having a truncated quadrangular pyramid shape.

FIG. 39B is a schematic perspective view of the optical path control unit having a truncated quadrangular pyramid shape.

FIG. 40 is a schematic partial cross-sectional view of another modification of the display device of Example 1.

FIG. 41 is a schematic partial cross-sectional view of still another modification of the display device of Example 1.

FIG. 42A is a front view of a digital still camera illustrating an example in which the display device of the present disclosure is applied to a lens interchangeable mirrorless type digital still camera.

FIG. 42B is a rear view of the digital still camera illustrating an example in which the display device of the present disclosure is applied to a lens interchangeable mirrorless type digital still camera.

### DESCRIPTION OF EMBODIMENTS

Hereinafter, the present disclosure will be described on the basis of Examples with reference to the drawings, but the present disclosure is not limited to Examples, and various numerical values and materials in Examples are examples. Note that description will be given in the following order.

1. General description of light emitting elements according to first and second aspects of present disclosure and display device of present disclosure

2. Example 1 (light emitting element according to first aspect of present disclosure and display device of present disclosure)

3. Example 2 (modification of Example 1)

4. Example 3 (another modification of Example 1)

5. Example 4 (light emitting element according to second aspect of present disclosure and display device of present disclosure)

6. Example 5 (modification of Examples 1 to 4)

7. Example 6 (modification of Examples 1 to 5)

8. Others

<General Description of Light Emitting Elements According to First and Second Aspects of Present Disclosure and Display Device of Present Disclosure>

In the following description, a light emitting element according to a first aspect of the present disclosure, and a second light emitting element and a third light emitting element constituting a display device of the present disclosure may be collectively referred to as “light emitting element or the like according to the first aspect of the present disclosure”.

In the light emitting element or the like according to the first aspect of the present disclosure,

a form can be adopted in which a light emitting region includes a light emitting region central portion and a light emitting region outer peripheral portion surrounding the light emitting region central portion, and

a first wavelength conversion layer extends to above a portion of a base constituting the light emitting region outer peripheral portion. That is, a form can be adopted in which the first wavelength conversion layer extends between a portion of a first electrode located on a portion of the base constituting the light emitting region outer peripheral portion and a portion of an organic layer located above a portion of the base constituting the light emitting region outer peripheral portion. Such a form can be applied to a first-A wavelength conversion layer and a first-B wavelength conversion layer in a light emitting element according to a second aspect of the present disclosure.

In the light emitting element or the like according to the first aspect of the present disclosure, the size of the light emitting region may be changed depending on the color of light emitted from the light emitting element, or the sizes of the light emitting region and a protrusion may be changed depending on the color of light emitted from the light emitting element. For example, a form can be adopted in which the size of a light emitting region of the second light emitting element is larger than the size of a light emitting region of a first light emitting element and the size of a light emitting region of the third light emitting element, but is not limited thereto. As a result, the amount of light emission of the second light emitting element can be made larger than the amount of light emission of the first light emitting element and the amount of light emission of the third light emitting element. Alternatively, the amount of light emission of the first light emitting element, the amount of light emission of the second light emitting element, and the amount of light emission of the third light emitting element can be made appropriate, and image quality can be improved.

In the light emitting element or the like according to the first aspect of the present disclosure including the above-described preferable forms, a form can be adopted in which the first wavelength conversion layer and a second wavelength conversion layer are made of the same material. Note that the present disclosure is not limited thereto, and the first wavelength conversion layer and the second wavelength conversion layer may be made of different materials as long as light emitted from the first wavelength conversion layer and light emitted from the second wavelength conversion layer have the same color.

In the light emitting element or the like according to the first aspect of the present disclosure including the above-described various preferable forms, a form can be adopted in which a wavelength selection unit through which at least light from the second wavelength conversion layer passes is further included. That is, in a case where the light emitting element includes the wavelength selection unit, a form can be adopted in which the wavelength selection unit is disposed above the second wavelength conversion layer, a second-A wavelength conversion layer, and a second-B wavelength conversion layer (hereinafter, also collectively referred to as “second wavelength conversion layer or the like”) (on a light emission side of the second wavelength conversion layer or the like). Note that a form in which light from the first wavelength conversion layer passes through the wavelength selection unit can be included. The wavelength selection unit may be disposed on a first substrate side or a second substrate side. In the former case, it is preferable to form the wavelength selection unit on a flattening layer formed on the second wavelength conversion layer or the like. Meanwhile, in the latter case, it is preferable to form the wavelength selection unit between the second wavelength conversion layer or the like and a first surface of the second substrate.

The wavelength selection unit can be constituted by, for example, a color filter layer. The color filter layer is made of a resin to which a colorant including a desired pigment or dye is added, and by selecting a pigment or dye, the color filter layer is adjusted such that light transmittance in a target wavelength region such as red, green, or blue is high and light transmittance in another wavelength region is low. Alternatively, the wavelength selection unit can also be constituted by a wavelength selection element to which a photonic crystal or a plasmon is applied (a color filter layer having a conductor lattice structure in which a lattice-shaped hole structure is formed in a conductor thin film. For example, see JP 2008-177191A), a thin film made of an inorganic material such as amorphous silicon, or a quantum dot. Hereinafter, the color filter layer may be described as a representative of the wavelength selection unit, but the wavelength selection unit is not limited to the color filter layer.

The size of the wavelength selection unit (for example, a color filter layer) may be appropriately changed according to light emitted from a light emitting element, or in a case where a light absorption layer (black matrix layer) is formed between the wavelength selection units (for example, color filter layers) of adjacent light emitting elements, the size of the light absorption layer (black matrix layer) may be appropriately changed according to light emitted from the light emitting element. In addition, the size of the wavelength selection unit (for example, a color filter layer) may be appropriately changed depending on a distance (offset amount) do (described later) between a normal line passing through the center of a light emitting region and a normal line passing through the center of the wavelength selection unit (for example, a color filter layer). The planar shape of the wavelength selection unit (for example, a color filter layer) may be the same as, similar to, approximate to, or different from the planar shape of a light emitting region, but the wavelength selection unit is preferably larger than the light emitting region. Alternatively, the planar shape of the wavelength selection unit may be the same as, similar to, approximate to, or different from the planar shape of an optical path control unit described later.

The center of the light emitting region refers to an area centroid point of a region occupied by the light emitting region. In addition, the center of the wavelength selection unit refers to an area centroid point of a region occupied by the wavelength selection unit. Alternatively, in a case where the planar shape of the wavelength selection unit is a circle, an ellipse, a square (including a square with rounded corners), a rectangle (including a rectangle with rounded corners), or a regular polygon (including a regular polygon with rounded corners), the center of each of these figures corresponds to the center of the wavelength selection unit. In a case where the planar shape of the wavelength selection unit is a figure obtained by cutting out a part of each of these figures, the center of a figure complementing the cutout part corresponds to the center of the wavelength selection unit. In a case where the planar shape of the wavelength selection unit is a figure obtained by connecting these figures, the center of a figure obtained by removing the connecting part and complementing the removed part corresponds to the center of the wavelength selection unit. Furthermore, when a planar shape of the optical path control unit is assumed, the center of the optical path control unit refers to an area centroid point of the planar shape. Alternatively, in a case where the planar shape of the optical path control unit is a circle, an ellipse, a square (including a square with rounded corners), a rectangle (including a rectangle with rounded corners), or a regular polygon (including a regular polygon with rounded corners), the center of each of these figures corresponds to the center of the optical path control unit.

In the light emitting element or the like according to the first aspect of the present disclosure including the above-described various preferable forms, a form can be adopted in which the first portion of the first electrode and the second portion of the first electrode are made of the same material, or a form can be adopted in which the first portion of the first electrode and the second portion of the first electrode are made of different materials. These forms can be applied to the light emitting element according to the second aspect of the present disclosure.

Furthermore, in the light emitting element or the like according to the first aspect of the present disclosure including the above-described various preferable forms, a form can be adopted in which the first wavelength conversion layer is covered with a transparent insulating material layer. In this case, a value n₁ of refractive index of a material constituting the first wavelength conversion layer can be higher than a value n₂ of refractive index of a material constituting the insulating material layer. As a result, a phenomenon occurs in which light incident on the insulating material layer from the first wavelength conversion layer is totally reflected at the insulating material layer and returned to the first wavelength conversion layer although depending on an incident angle on the insulating material layer, and as a result, wavelength conversion efficiency in the first wavelength conversion layer can be further improved. Here,

n₁−n₂≥0.1

can be exemplified. Such a form can be applied to a first-A wavelength conversion layer and a first-B wavelength conversion layer in a light emitting element according to a second aspect of the present disclosure.

Furthermore, in the light emitting element or the like according to the first aspect of the present disclosure including the above-described preferable forms, the protrusion can have a forward tapered shape, or a side surface of the protrusion can be perpendicular to the base. Here, 15 degrees to 75 degrees can be exemplified as a maximum inclination angle of the forward tapered shape, and the side surface of the protrusion can form an angle of 90 degrees ±10 degrees with respect to the base. These forms can be applied to the light emitting element according to the second aspect of the present disclosure.

In the light emitting element according to the second aspect of the present disclosure,

a form can be adopted in which a second-A wavelength conversion layer that is formed on or above a second electrode and converts first light emitted from an organic layer into second light, and

a second-B wavelength conversion layer that is formed on or above the second electrode and converts the first light emitted from the organic layer into third light

are further disposed. In the light emitting element according to the second aspect of the present disclosure including such a form, white light can be emitted to the outside. Note that the first-A wavelength conversion layer and the second-A wavelength conversion layer can be made of the same material, and the first-B wavelength conversion layer and the second-B wavelength conversion layer can be made of the same material. Note that the present disclosure is not limited thereto, and the first-A wavelength conversion layer and the second-A wavelength conversion layer may be made of different materials as long as light emitted from the first-A wavelength conversion layer and light emitted from the second-A wavelength conversion layer have the same color. Similarly, the first-B wavelength conversion layer and the second-B wavelength conversion layer may be made of different materials as long as light emitted from the first-B wavelength conversion layer and light emitted from the second-B wavelength conversion layer have the same color.

In the display device of the present disclosure, a light emitting element unit may include a fourth light emitting element constituted by the light emitting element according to the second aspect of the present disclosure in addition to the first light emitting element, the second light emitting element, and the third light emitting element. The fourth light emitting element emits white light to the outside. In this case, the size of the light emitting region of the second light emitting element or the fourth light emitting element is preferably larger than the size of the light emitting region of the first light emitting element or the third light emitting element from a viewpoint of luminance. In addition, the size of the light emitting region of the first light emitting element is preferably larger than the size of the light emitting region of the second light emitting element, the third light emitting element, or the fourth light emitting element from a viewpoint of a lifetime of the light emitting element. Note that the present disclosure is not limited to these.

Examples of a planar shape of the light emitting element (more specifically, a planar shape of the light emitting region) include a circle, an ellipse, an oval, and a polygon including a triangle, a quadrangle, a hexagon, and an octagon. The polygon includes a regular polygon (including a rectangle and a regular polygon such as a regular hexagon (honeycomb shape)).

The display device of the present disclosure specifically includes, for example, at least:

a first substrate and a second substrate;

a base disposed on the first substrate;

a plurality of light emitting elements arranged two-dimensionally on the base; and

a sealing resin layer formed between a light emitting element and the second substrate.

Note that, in the following description, a surface of the first substrate facing the second substrate is referred to as “second surface of the first substrate”, and a surface of the second substrate facing the first substrate is referred to as “first surface of the second substrate”. In addition, a surface of the first substrate facing the second surface of the first substrate is referred to as “first surface of the first substrate”, and a surface of the second substrate facing the first surface of the second substrate is referred to as “second surface of the second substrate”.

In the light emitting elements according to the first and second aspects of the present disclosure and the light emitting element constituting the display device of the present disclosure, the organic layer can include an organic electroluminescence layer. That is, the display device of the present disclosure can be constituted by an organic electroluminescence display device (organic EL display device), and the light emitting element can be constituted by an organic electroluminescence element (organic EL element). Here, the display device of the present disclosure can be a top emission type display device that emits light from the second substrate, or can be a bottom emission type display device that emits light from the first substrate.

The second wavelength conversion layer or the like may be formed on the first substrate side or the second substrate side. In a case where the second wavelength conversion layer or the like is formed on the first substrate side, the second wavelength conversion layer or the like may be formed on the second electrode or on a protective layer formed on the second electrode. In a case where the second wavelength conversion layer or the like is formed on the second substrate side, the second wavelength conversion layer or the like only needs to be formed on the first surface of the second substrate. In this case, the light emitting element includes the second wavelength conversion layer or the like above the second electrode via a sealing resin layer.

In order to control a light condensing property of light emitted from the light emitting element, an optical path control unit through which light emitted from the light emitting region passes, for example, a lens member may be disposed. The optical path control unit will be described in detail in Examples 5 and 6. In addition, the organic EL display device preferably has a resonator structure in order to further improve light extraction efficiency. The resonator structure will be described in detail in Example 4. In a case where the wavelength selection unit and the optical path control unit through which light emitted from the light emitting region passes are disposed, light emitted from the light emitting region can pass through the wavelength selection unit and the optical path control unit in this order, or can pass through the optical path control unit and the wavelength selection unit in this order. A distance (offset amount) D₀ between a normal line passing through the center of the light emitting region and a normal line passing through the center of the optical path control unit may be appropriately changed depending on a distance (offset amount) do between the normal line passing through the center of the light emitting region and a normal line passing through the center of the wavelength selection unit.

A light absorption layer (black matrix layer) can be formed between the wavelength selection unit and the wavelength selection unit, above a space between the wavelength selection unit and the wavelength selection unit, or between adjacent optical path control units. In addition, a light shielding unit may be formed between adjacent light emitting elements. These can reliably suppress occurrence of color mixing between adjacent light emitting elements. In a case where the light absorption layer is formed between the wavelength selection units of adjacent light emitting elements or between the optical path control units of adjacent light emitting elements, the size of the light absorption layer may be appropriately changed depending on light emitted from the light emitting element. The light absorption layer (black matrix layer) is constituted by, for example, a black resin film (specifically, for example, a black polyimide-based resin) mixed with a black colorant and having an optical density of 1 or more, or constituted by a thin film filter using interference of a thin film. The thin film filter is formed by, for example, laminating two or more thin films made of metal, metal nitride, or metal oxide and attenuates light using interference of the thin films. Specific examples of the thin film filter include a thin film filter in which Cr and chromium (III) oxide (Cr₂O₃) are alternately laminated. Specific examples of a light shielding material constituting the light shielding unit include a material capable of shielding light, such as titanium (Ti), chromium (Cr), tungsten (W), tantalum (Ta), aluminum (Al), or MoSi₂. The light shielding unit can be formed by a vapor deposition method including an electron beam vapor deposition method, a hot filament vapor deposition method, and a vacuum vapor deposition method, a sputtering method, a CVD method, an ion plating method, or the like.

In the display device of the present disclosure, examples of an arrangement of the first light emitting element, the second light emitting element, and the third light emitting element in a pixel (a light emitting element unit) include a delta arrangement, a stripe arrangement, a diagonal arrangement, a rectangle arrangement, and a pentile arrangement. An arrangement of the wavelength selection units also only needs to be a delta arrangement, a stripe arrangement, a diagonal arrangement, a rectangle arrangement, or a pentile arrangement in accordance with the arrangement of pixels (or sub-pixels).

Hereinafter, a form in which the organic layer constituting the light emitting element includes an organic electroluminescence layer, that is, a form in which the display device of the present disclosure is constituted by an organic electroluminescence display device (organic EL display device) will be described.

The organic EL display device includes:

a first substrate and a second substrate; and

a plurality of light emitting elements located between the first substrate and the second substrate and arranged two-dimensionally, in which

each of the light emitting elements disposed on a base formed on the first substrate includes at least:

a first electrode;

a second electrode; and

an organic layer (including a light emitting layer constituted by an organic electroluminescence layer) sandwiched between the first electrode and the second electrode, and

light from the organic layer is emitted to the outside via the second substrate or the first substrate.

The organic layer constituting each of the first light emitting element, the second light emitting element, and the third light emitting element emits blue light (wavelength λ₁: 450 nm to 495 nm). A form can be adopted in which the first light emitting element emits blue light toward the outside, the second light emitting element emits green light (wavelength λ2: 495 nm to 570 nm) toward the outside, and the third light emitting element emits red light (wavelength λ₃: 620 nm to 750 nm) toward the outside. That is, a form can be adopted in which the first light emitting element is constituted by a blue light emitting element, the second light emitting element is constituted by a green light emitting element, and the third light emitting element is constituted by a red light emitting element. The organic layer may be shared by the plurality of light emitting elements, or may be individually formed in each of the light emitting elements.

The first wavelength conversion layer and the second wavelength conversion layer perform wavelength conversion (color conversion) of blue light into green light or red light. The first-A wavelength conversion layer and the second-A wavelength conversion layer perform wavelength conversion (color conversion) of blue light into green light. The first-B wavelength conversion layer and the second-B wavelength conversion layer perform wavelength conversion (color conversion) of blue light into red light.

Specific examples of a wavelength conversion material that is excited by blue light and emits green light (a wavelength (color) conversion material constituting the first wavelength conversion layer and the second wavelength conversion layer, or constituting the first-A wavelength conversion layer and the second-A wavelength conversion layer) include a coumarin-based dye and a naphthalimide-based dye. Alternatively, specific examples of the wavelength conversion material include green light emitting phosphor particles, and more specific examples thereof include (ME:Eu)Ga₂S₄ [in which “ME” means at least one type of atom selected from the group consisting of Ca, Sr, and Ba, and the same applies to the following], (M:RE)ₓ(Si,Al)₁₂(O,N)₁₆ [in which “RE” means Tb and Yb], (M:Tb)ₓ(Si,Al)₁₂(O,N)₁₆, (M:Yb)ₓ(Si,Al)₁₂(O,N)₁₆, and Si_{6-Z}Al_{z}O_{z}N_{8-Z}:Eu.

Specific examples of a wavelength conversion material that is excited by blue light and emits red light (a wavelength (color) conversion material constituting the first wavelength conversion layer and the second wavelength conversion layer, or constituting the first-B wavelength conversion layer and the second-B wavelength conversion layer) include a pyridine-based dye, a rhodamine-based dye, and an oxazine-based dye. Alternatively, specific examples of the wavelength conversion material include red light emitting phosphor particles, and more specific examples thereof include (ME:Eu)S, (M:Sm)ₓ(Si,Al)₁₂(O,N)₁₆ [in which “M” means at least one type of atom selected from the group consisting of Li, Mg, and Ca, and the same applies to the following], ME₂Si₅N₈:Eu, (Ca:Eu)SiN₂, and (Ca:Eu)AlSiN₃.

Note that the wavelength conversion material may be used singly or in combination of two or more types thereof.

Note that the wavelength conversion material (color conversion material) is not limited to phosphor particles. For example, light emitting particles in which a wave function of carriers is localized and to which a quantum well structure such as a two-dimensional quantum well structure, a one-dimensional quantum well structure (quantum fine wire), or a zero-dimensional quantum well structure (quantum dot) using a quantum effect is applied in order to efficiently convert carriers into light as in a direct transition type in an indirect transition type silicon-based material can be exemplified. A rare earth atom added to a semiconductor material is known to sharply emit light by in-shell transition, and light emitting particles to which such a technique is applied can also be exemplified.

As the size (diameter) of a quantum dot decreases, band gap energy increases, and the wavelength of light emitted from the quantum dot decreases. That is, as the size of the quantum dot is smaller, light having a shorter wavelength (light on a blue light side) is emitted, and as the size of the quantum dot is larger, light having a longer wavelength (light on a red light side) is emitted. Therefore, it is possible to obtain a quantum dot that emits light having a desired wavelength (performs color conversion into a desired color) by using the same material constituting the quantum dot and adjusting the size of the quantum dot. Specifically, the quantum dot preferably has a core-shell structure. Examples of a material constituting the quantum dot include: Si; Se; CIGS(CuInGaSe), CIS(CuInSe₂), CuInS₂, CuAlS₂, CuAlSe₂, CuGaS₂, CuGaSe₂, AgAlS₂, AgAlSe₂, AgInS₂, and AgInSe₂ which are chalcopyrite-based compounds; a Perovskite-based material; GaAs, GaP, InP, InAs, InGaAs, AlGaAs, InGaP, AlGaInP, InGaAsP, and GaN which are III-V group compounds; CdSe, CdSeS, CdS, CdTe, In₂Se₃, In₂S₃, Bi:Se₃, Bi₂S₃, ZnSe, ZnTe, ZnS, HgTe, HgS, PbSe, PbS, and TiO₂, but are not limited thereto.

The base is formed on or above the first substrate. Examples of a material constituting the base include an insulating material such as SiO₂, SiN, or SiON. The base can be formed on the basis of a forming method suitable for a material constituting the base, specifically, for example, a known method such as various CVD methods, various coating methods, various PVD methods including a sputtering method and a vacuum vapor deposition method, various printing methods such as a screen printing method, a plating method, an electrodeposition method, an immersion method, or a sol-gel method.

A drive circuit (light emitting element driving unit) is disposed under or below the base, but is not limited thereto. The drive circuit is constituted by, for example, a transistor (specifically, for example, a MOSFET) formed on a silicon semiconductor substrate constituting the first substrate, or a thin film transistor (TFT) disposed on various substrates constituting the first substrate. A form can be adopted in which the transistor and the TFT constituting the drive circuit are connected to the first electrode via a contact hole (contact plug) formed in the base or the like. The drive circuit can have a known circuit configuration. For example, the second electrode is connected to the drive circuit via a contact hole (contact plug) formed in the base or the like at an outer peripheral portion (specifically, an outer peripheral portion of a pixel array unit) of the display device.

The first substrate or the second substrate can be constituted by a silicon semiconductor substrate, a high strain point glass substrate, a soda glass (Na₂O·CaO·SiO₂) substrate, a borosilicate glass (Na₂O·B₂O₃·SiO₂) substrate, a forsterite (2MgO·SiO₂) substrate, a lead glass (Na₂O·PbO·SiO₂) substrate, various glass substrates having an insulating film formed on a surface thereof, a quartz substrate, a quartz substrate having an insulating film formed on a surface thereof, an organic polymer (having a form of a flexible polymer material made of a polymer material, such as a plastic film, a plastic sheet, or a plastic substrate) such as polymethyl methacrylate (PMMA), polyvinyl alcohol (PVA), polyvinylphenol (PVP), polyethersulfone (PES), polyimide, polycarbonate, polyethylene terephthalate (PET), or polyethylene naphthalate (PEN). The materials constituting the first substrate and the second substrate may be the same or different. In a case of the upper surface emission type display device, the second substrate is required to be transparent to light from the light emitting element, and in a case of the lower surface emission type display device, the first substrate is required to be transparent to light from the light emitting element.

The first electrode is disposed for each of the light emitting elements. The second electrode may be an electrode shared by the plurality of light emitting elements. That is, the second electrode may be a so-called solid electrode. The first substrate is disposed below or under the base, and the second substrate is disposed above the second electrode. The light emitting element is formed on the first substrate side, and the light emitting region is formed on the base.

In a case where the first electrode functions as an anode electrode, examples of the material constituting the first electrode include a metal material having a high work function, such as platinum (Pt), gold (Au), silver (Ag), chromium (Cr), tungsten (W), nickel (Ni), copper (Cu), iron (Fe), cobalt (Co), or tantalum (Ta), and an alloy material having a high work function (for example, an Ag—Pd—Cu alloy containing silver as a main component and containing 0.3% by mass to 1% by mass of palladium (Pd) and 0.3% by mass to 1% by mass of copper (Cu), an Al—Nd alloy, an Al—Cu alloy, or an Al—Cu—Ni alloy). Furthermore, in a case where a conductive material having a small work function value and a high light reflectance, such as aluminum (Al) or an alloy containing aluminum, the first electrode can be used as an anode electrode by improving hole injection characteristics by forming an appropriate hole injection layer, for example. Alternatively, a structure can be adopted in which a transparent conductive material having excellent hole injection characteristics, such as an oxide of indium and tin (ITO) or an oxide of indium and zinc (IZO), is laminated on a dielectric multilayer film or a reflective film having high light reflectivity, such as aluminum (Al) or an alloy thereof (for example, an Al—Cu—Ni alloy). The thickness of the first electrode may be 0.1 μm to 1 μm, for example. Alternatively, in a case where a light reflecting layer constituting a resonator structure described later is formed or in a case where a bottom emission type display device is used, the first portion of the first electrode and the second portion of the first electrode are preferably made of different materials. In this case, the material constituting the first portion of the first electrode is required to be transparent to light from the light emitting element. Therefore, examples of the material constituting the first portion of the first electrode include various transparent conductive materials such as a transparent conductive material containing, as a base layer, indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), ITiO (Ti-doped In₂O₃), InSn, InSnZnO, tin oxide (SnO₂), ATO (Sb-doped SnO₂), FTO (F-doped SnO₂), zinc oxide (ZnO), aluminum oxide-doped zinc oxide (AZO), gallium-doped zinc oxide (GZO), B-doped ZnO, AlMgZnO (aluminum oxide and magnesium oxide-doped zinc oxide), antimony oxide, titanium oxide, NiO, spinel type oxide, oxide having a YbFe₂O₄ structure, gallium oxide, titanium oxide, niobium oxide, nickel oxide, or the like. In addition, examples of the material constituting the second portion of the first electrode include a dielectric multilayer film, aluminum (Al) or an alloy thereof (for example, an Al—Cu—Ni alloy), and a material having a high light reflectance (for example, silver or a silver alloy) among the above metal materials and alloy materials. Meanwhile, in a case where the first electrode functions as a cathode electrode, the first electrode is desirably made of a conductive material having a small work function value and a high light reflectance. However, the first electrode can also be used as a cathode electrode by improving electron injection characteristics by forming an appropriate electron injection layer in a conductive material having a high light reflectance used as an anode electrode, for example.

In a case where the display device is a top emission type display device, a material constituting the second electrode (semi-light transmissive material or light transmissive material) is desirably a conductive material having a small work function value so as to transmit emission light and to efficiently inject electrons into the organic layer (light emitting layer) in a case where the second electrode functions as a cathode electrode. Examples thereof include a metal or an alloy having a small work function, such as aluminum (Al), silver (Ag), magnesium (Mg), calcium (Ca), sodium (Na), strontium (Sr), an alkali metal or an alkaline earth metal and silver (Ag) [for example, an alloy of magnesium (Mg) and silver (Ag) (Mg—Ag alloy)], an alloy of magnesium-calcium (Mg—Ca alloy), or an alloy of aluminum (Al) and lithium (Li) (Al—Li alloy). Among these, a Mg—Ag alloy is preferable, and a volume ratio between magnesium and silver may be Mg:Ag=5:1 to 30:1, for example. Alternatively, as a volume ratio between magnesium and calcium may be Mg:Ca=2:1 to 10:1, for example. The thickness of the second electrode may be 4 nm to 50 nm, preferably 4 nm to 20 nm, and more preferably 6 nm to 12 nm, for example. Alternatively, at least one material selected from the group consisting of Ag—Nd—Cu, Ag—Cu, Au, and Al—Cu can be mentioned. Alternatively, the second electrode can have a laminated structure of the above-described material layer and a so-called transparent electrode (for example, having a thickness of 3×10⁻⁸ m to 1×10⁻⁵ m) made of, for example, ITO or IZO from the organic layer side. A bus electrode (auxiliary electrode) made of a low-resistance material such as aluminum, an aluminum alloy, silver, a silver alloy, copper, a copper alloy, gold, or a gold alloy may be disposed for the second electrode to reduce resistance of the second electrode as a whole. The second electrode desirably has an average light transmittance of 50% to 90%, preferably 60% to 90%. Meanwhile, in a case where the second electrode functions as an anode electrode, the second electrode is desirably made of a conductive material that transmits emitted light as necessary and has a large work function value. In a case where the display device is a bottom emission type display device, a material constituting the second electrode only needs to be appropriately selected from materials each having a high light reflectance.

Examples of a method for forming the first electrode and the second electrode include: a vapor deposition method including an electron beam vapor deposition method, a hot filament vapor deposition method, and a vacuum vapor deposition method, a sputtering method, a chemical vapor deposition method (CVD method), an MOCVD method, and a combination of an ion plating method and an etching method; various printing methods such as a screen printing method, an inkjet printing method, and a metal mask printing method; a plating method (an electroplating method or an electroless plating method); a lift-off method; a laser ablation method; and a sol-gel method. According to various printing methods and a plating method, it is possible to directly form the first electrode and the second electrode each having a desired shape (pattern). Note that, when the second electrode is formed after the organic layer is formed, it is particularly preferable to form the second electrode on the basis of a film forming method in which energy of film-forming particles is small, such as a vacuum vapor deposition method, or a film forming method such as an MOCVD method from a viewpoint of preventing the organic layer from being damaged. When the organic layer is damaged, a non-light emitting pixel (or a non-light emitting sub-pixel) called a “blinking point” due to generation of a leakage current may occur.

As described above, the protective layer can be formed so as to cover the second electrode, whereby occurrence of current leakage can be prevented. In addition, as described above, a flattening layer can be further formed on the protective layer and the second wavelength conversion layer or the like. A flattening layer functioning as the wavelength selection unit may be formed. That is, a flattening layer functioning as a red color filter layer or a flattening layer functioning as a green color filter layer may be formed. Such a flattening layer only needs to be made of a known color resist material. In the light emitting element according to the second aspect of the present disclosure, the light emitting element emitting white light, a transparent filter layer only needs to be formed. By causing the flattening layer to function also as a color filter layer as described above, the organic layer and the flattening layer (color filter layer) are close to each other. Therefore, color mixing can be effectively prevented even if an angle of light emitted from the light emitting element is widened, and viewing angle characteristics are improved.

Examples of materials constituting the protective layer and the flattening layer include an acrylic resin, an epoxy-based resin, a polyimide-based resin, and polysiloxane, and examples thereof further include various inorganic materials (for example, SiO₂, SiN, SiON, SiC, amorphous silicon (α-Si), Al₂O₃, and TiO₂). The protective layer and the flattening layer can each have a single-layer structure or a multilayer structure. The protective layer and the flattening layer can be formed on the basis of a known method such as various CVD methods, various coating methods, various PVD methods including a sputtering method and a vacuum vapor deposition method, and various printing methods such as a screen printing method. Furthermore, as the method for forming the protective layer and the flattening layer, an atomic layer deposition (ALD) method can also be adopted. Each of the protective layer and the flattening layer may be shared by a plurality of light emitting elements, or may be individually formed in each of the light emitting elements.

A portion of the first substrate facing the second substrate and a portion of the second substrate facing the first substrate are bonded to each other via, for example, a resin layer (sealing resin layer). Examples of a material constituting the sealing resin layer include a thermosetting adhesive such as an acrylic adhesive, an epoxy-based adhesive, a urethane-based adhesive, a silicone-based adhesive, or a cyanoacrylate-based adhesive, and an ultraviolet-curable adhesive. Depending on the structure of the display device, the sealing resin layer may also serve as the flattening layer.

An intermediate layer may be formed on the first substrate side of the sealing resin layer. In some cases, the intermediate layer can function as a color filter layer. Such an intermediate layer only needs to be made of a known color resist material. In a light emitting element that emits white light, a transparent filter layer only needs to be formed.

Examples of a material constituting the intermediate layer include an acrylic resin, an epoxy-based resin, and various inorganic materials (for example, SiN, SiON, SiO, Al₂O₃, and TiO₂). The intermediate layer can be formed on the basis of a known method such as various CVD methods, various coating methods, various PVD methods including a sputtering method and a vacuum vapor deposition method, and various printing methods such as a screen printing method. The intermediate layer may be shared by the plurality of light emitting elements, or may be individually formed in each of the light emitting elements.

On an outermost surface (specifically, for example, the second surface of the second substrate or the first surface of the first substrate) of the display device from which light is emitted, an ultraviolet absorption layer, a contamination preventing layer, a hard coat layer, and an antistatic layer may be formed, or a protective member (for example, cover glass) may be disposed.

In the display device, a protrusion and an interlayer insulating layer (base) described later, and an interlayer insulating material layer are formed, and examples of an insulating material constituting these layers include: a SiOₓ-based material (material constituting a silicon-based oxide film) such as SiO₂, non-doped silicate glass (NSG), boron phosphorus silicate glass (BPSG), PSG, BSG, AsSG, SbSG, PbSG, spin-on glass (SOG), low temperature oxide (LTO, low temperature CVD-SiO₂), low-melting-point glass, or glass paste; a SiN-based material including a SiON-based material; SiOC; SiOF; and SiCN. Alternatively, examples of the insulating material include an inorganic insulating material such as titanium oxide (TiO₂), tantalum oxide (Ta₂O₅), aluminum oxide (Al₂O₃), magnesium oxide (MgO), chromium oxide (CrOₓ), zirconium oxide (ZrO₂), niobium oxide (Nb₂O₅), tin oxide (SnO₂), or vanadium oxide (VOₓ). Alternatively, examples of the insulating material include various resins such as a polyimide-based resin, an epoxy-based resin, and an acrylic resin, various photoresist materials, and a low dielectric constant insulating material such as SiOCH, organic SOG, or a fluorine-based resin (for example, a material having a dielectric constant k (=ε/ε₀) of, for example, 3.5 or less, and specific examples thereof include fluorocarbon, a cycloperfluorocarbon polymer, benzocyclobutene, a cyclic fluorine-based resin, polytetrafluoroethylene, amorphous tetrafluoroethylene, polyaryl ether, fluorinated aryl ether, fluorinated polyimide, amorphous carbon, parylene (polyparaxylylene), and fluorinated fullerene), and also include Silk (which is a trademark of The Dow Chemical Co. and a coating type low dielectric constant interlayer insulating film material) and Flare (which is a trademark of Honeywell Electronic Materials Co. and a polyallyl ether (PAE)-based material). These can be used singly or in appropriate combination. In some cases, the base may be made of the materials described above. The transparent insulating material layer also only needs to be appropriately selected from the above-described materials, polysiloxane, and the like. The protrusion, the interlayer insulating layer (base), and the interlayer insulating material layer can be formed on the basis of a known method such as various CVD methods, various coating methods, various PVD methods including a sputtering method and a vacuum vapor deposition method, various printing methods such as a screen printing method, a plating method, an electrodeposition method, an immersion method, or a sol-gel method.

The organic layer includes a light emitting layer containing an organic light emitting material. Specifically, the organic layer can be constituted by, for example, a laminated structure of a hole transport layer, a light emitting layer, and an electron transport layer, a laminated structure of a hole transport layer and a light emitting layer serving also as an electron transport layer, or a laminated structure of a hole injection layer, a hole transport layer, a light emitting layer, an electron transport layer, and an electron injection layer. Examples a method for forming the organic layer include: a physical vapor deposition method (PVD method) such as a vacuum vapor deposition method; a printing method such as a screen printing method or an inkjet printing method; a laser transfer method in which a laminated structure of a laser absorption layer and an organic layer formed on a transfer substrate is irradiated with a laser to separate the organic layer on the laser absorption layer and transfer the organic layer, and various coating methods. When the organic layer is formed on the basis of a vacuum vapor deposition method, for example, a so-called metal mask is used, and a material that has passed through an opening formed in the metal mask is deposited to obtain the organic layer.

In the organic EL display device, the thickness of the hole transport layer (hole supply layer) and the thickness of the electron transport layer (electron supply layer) are desirably substantially equal to each other. Alternatively, the electron transport layer (electron supply layer) may be thicker than the hole transport layer (hole supply layer), and this makes it possible to supply electrons necessary for high efficiency at a low drive voltage and sufficient to the light emitting layer. That is, by forming the hole transport layer between the first electrode corresponding to the anode electrode and the light emitting layer and forming the hole transport layer with a film thickness thinner than that of the electron transport layer, supply of holes can be increased. As a result, it is possible to obtain a carrier balance in which there is no excess or deficiency of holes and electrons and a carrier supply amount is sufficiently large. Therefore, high light emission efficiency can be obtained. In addition, since there is no excess or deficiency of holes and electrons, the carrier balance is hardly lost, drive deterioration is suppressed, and a light emission lifetime can be extended.

The display device can be used as, for example, a monitor device constituting a personal computer, or can be used as a monitor device incorporated in a television receiver, a mobile phone, a personal digital assistant (PDA), or a game device, or a display device incorporated in a projector. Alternatively, the display device can be applied to an electronic view finder (EVF) and a head mounted display (HMD), can be applied to an eyewear, AR glasses, and EVR, and can be applied to a display device for virtual reality (VR), mixed reality (MR), or augmented reality (AR). Alternatively, the display device can constitute an image display device in an electronic paper such as an electronic book or an electronic newspaper, a bulletin board such as a signboard, a poster, or a blackboard, a rewritable paper as a substitute for printer paper, a display unit of a home appliance, a card display unit of a loyalty card or the like, an electronic advertisement, or an electronic POP. By using the display device of the present disclosure as a light emitting device, various lighting devices including a backlight device for a liquid crystal display device and a planar light source device can be constituted.

### Example 1

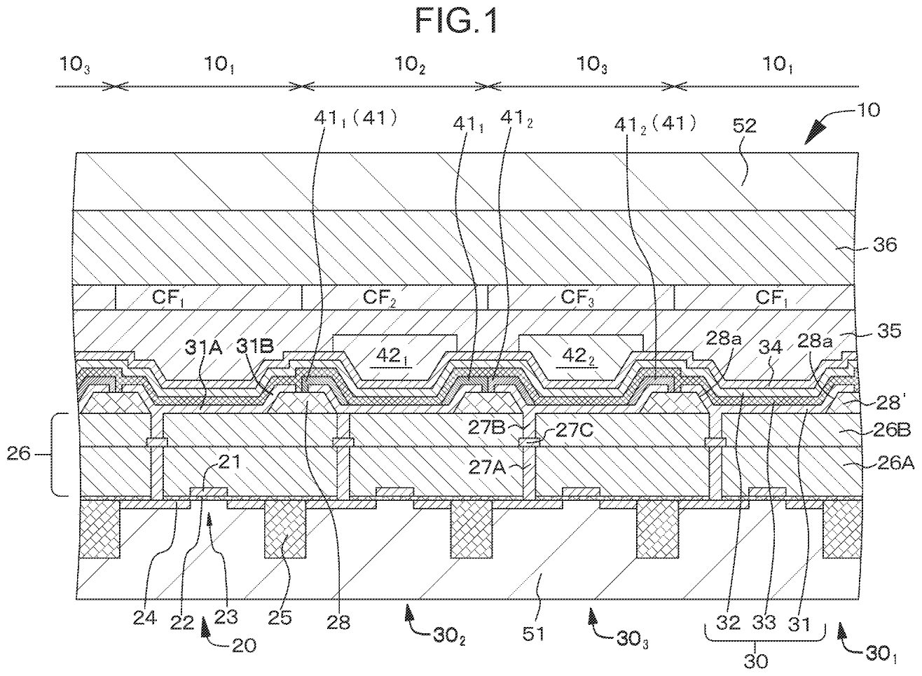

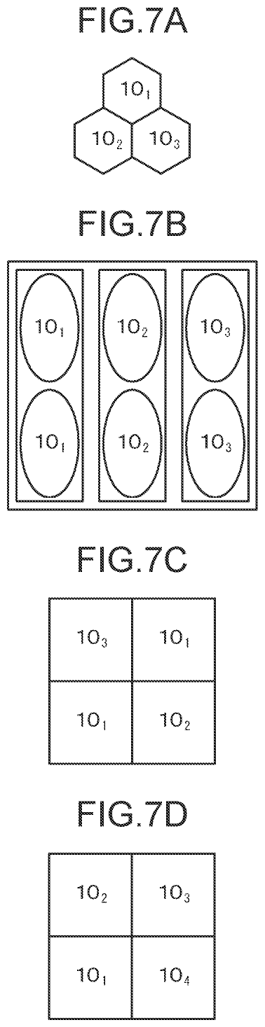

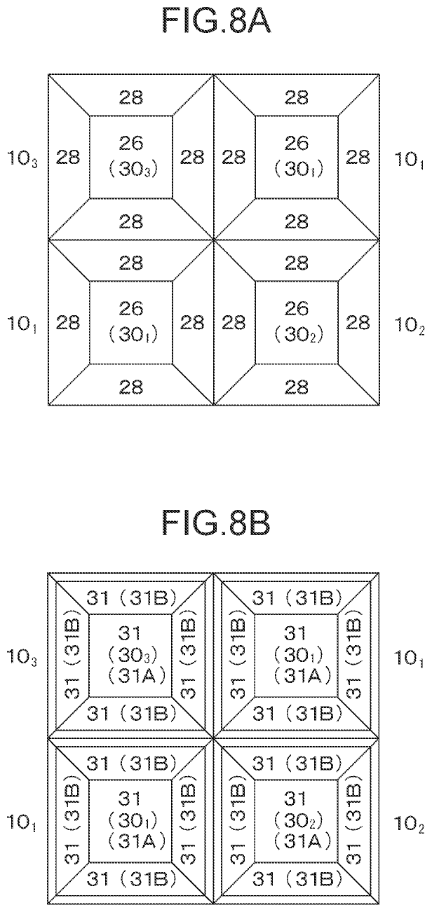

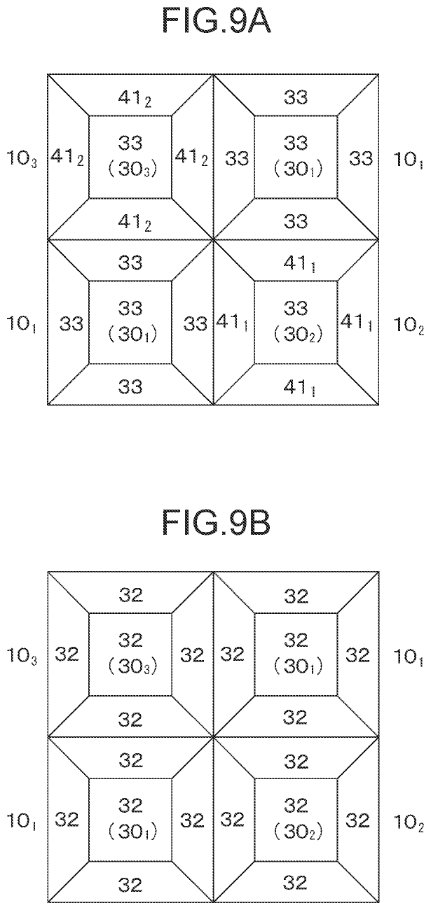

Example 1 relates to the light emitting element according to the first aspect of the present disclosure and the display device of the present disclosure. FIG. 1 illustrates a schematic partial cross-sectional view of the light emitting element and the display device of Example 1. FIGS. 7A, 7B, and 7C each schematically illustrate an arrangement of the light emitting elements (sub-pixels) in the display device of Example 1. FIG. 8A schematically illustrates an arrangement state of an arrangement state of a base and a protrusion in the display device of Example 1. FIG. 8B schematically illustrates an arrangement state of first electrodes. FIG. 9A schematically illustrates an arrangement state of an arrangement state of an organic layer and a first wavelength conversion layer. FIG. 9B schematically illustrates an arrangement state of second electrodes. In Example 1 or Examples 2 to 6 described later, a light emitting element is constituted by an organic electroluminescence element (organic EL element), and a display device is constituted by an organic electroluminescence display device (organic EL display device) and is an active matrix display device. A light emitting layer includes an organic electroluminescence layer. The display device is a top emission type display device that emits light from a second substrate. Note that the schematic partial cross-sectional view of the display device and the arrangement state of the light emitting elements in the display device do not coincide with each other in some cases in order to simplify the drawings.

Each of light emitting elements 10₂ and 10₃ of Example 1 includes:

a protrusion 28 surrounding a light emitting region 30;

a first electrode 31 including a first portion 31A formed on a portion of a base 26 constituting the light emitting region 30 and a second portion 31B extending from the first portion 31A and formed on the protrusion 28;

an organic layer 33 formed on and above the first electrode 31;

a second electrode 32 formed on the organic layer 33;

a first wavelength conversion layer 41 (41₁, 41₂) that is formed between the second portion 31B of the first electrode 31 and a portion of the organic layer 33 formed above the protrusion 28 and converts light emitted from the organic layer 33 into light on a long wavelength side; and a second wavelength conversion layer 42 (42₁, 42₂) that is formed on or above the second electrode 32 and converts light emitted from the organic layer 33 into light on a long wavelength side.

In addition, the display device of Example 1 is a display device in which a plurality of light emitting element units (pixels) each including a first light emitting element 10₁, the second light emitting element 10₂, and the third light emitting element 10₃ is arranged. The first light emitting element 10₁, the second light emitting element 10₂, and the third light emitting element 10₃ correspond to sub-pixels.

The first light emitting element 10: includes:

the protrusion 28 surrounding the light emitting region 30;

the first electrode 31 including the first portion 31A formed on a portion of the base 26 constituting the light emitting region 30 and the second portion 31B extending from the first portion 31A and formed on the protrusion 28;

the organic layer 33 that is formed on the first electrode 31 and emits first light having a wavelength λ₁; and

the second electrode 32 formed on the organic layer 33. The first light emitting element 10₁ does not include the first wavelength conversion layer or the second wavelength conversion layer. The first light emitting element 10₁ emits blue light to the outside.

The second light emitting element 10₂ corresponds to the light emitting element of Example 1, and includes:

the protrusion 28 surrounding the light emitting region 30;

the first electrode 31 including the first portion 31A formed on a portion of the base 26 constituting the light emitting region 30 and the second portion 31B extending from the first portion 31A and formed on the protrusion 28;

the organic layer 33 that is formed on and above the first electrode 31 and emits first light;

the second electrode 32 formed on the organic layer 33;

a first-A wavelength conversion layer 41₁ that is formed between the second portion 31B of the first electrode 31 and a portion of the organic layer 33 formed above the protrusion 28 and converts the first light emitted from the organic layer 33 into second light having a wavelength λ₂ (λ₂>λ₁); and

a second-A wavelength conversion layer 42₁ that is formed on or above the second electrode 32 and converts the first light emitted from the organic layer 33 into the second light. The second light emitting element 10₂ emits green light to the outside.

Furthermore, the third light emitting element 10₃ corresponds to the light emitting element of Example 1, and includes:

the protrusion 28 surrounding the light emitting region 30;

the first electrode 31 including the first portion 31A formed on a portion of the base 26 constituting the light emitting region 30 and a second portion 31B extending from the first portion 31A and formed on the protrusion 28;

the organic layer 33 that is formed on and above the first electrode 31 and emits first light;

the second electrode 32 formed on the organic layer 33;

a first-B wavelength conversion layer 41₂ that is formed between the second portion 31B of the first electrode 31 and a portion of the organic layer 33 formed above the protrusion 28 and converts the first light emitted from the organic layer 33 into third light having a wavelength λ₃ (λ₃>λ₂); and

a second-B wavelength conversion layer 42₂ that is formed on or above the second electrode 32 and converts the first light emitted from the organic layer 33 into the third light. The third light emitting element 10₃ emits red light to the outside.

In the following description, the light emitting element of Example 1 and the second light emitting element 10₂ and the third light emitting element 10₃ constituting the display device of Example 1 may be collectively referred to as “light emitting element or the like of Example 1”.

In the light emitting element or the like of Example 1, the first wavelength conversion layer 41 (41₁, 41₂) and the second wavelength conversion layer 42 (42₁, 42₂) are made of the same material. In addition, a wavelength selection unit CF₂, CF₃ through which light from at least the second wavelength conversion layer 42 passes is further included. Here, the wavelength selection unit CF₂, CF₃ is constituted by, for example, a color filter layer. The first light emitting element 10₁ also includes the wavelength selection unit CF₁, specifically, a color filter layer. Note that the wavelength selection unit CF₁, CF₂, CF₃ is not necessarily formed. Furthermore, the first portion 31A of the first electrode 31 and the second portion 31B of the first electrode 31 are made of the same material. The protrusion 28 has a forward tapered shape. That is, the size of a cross section of an opening 28a formed in the protrusion 28 when the protrusion 28 is cut along a virtual plane parallel to the base 26 increases as a distance from the base 26 increases.

Specifically, a material constituting the first wavelength conversion layer 41 (41₁) and the second wavelength conversion layer 42 (42₁) that performs wavelength conversion (color conversion) of blue light into green light is made of a resist material containing an acrylic resin containing a coumarin-based dye or an epoxy imide-based resin as a main component. A material constituting the first wavelength conversion layer 41 (41₂) and the second wavelength conversion layer 42 (42₂) that performs wavelength conversion (color conversion) of blue light into red light is made of a resist material containing an acrylic resin containing a rhodamine-based dye or an epoxy imide-based resin as a main component. A material constituting the first portion 31A and the second portion 31B of the first electrode 31 is made of a light reflecting material, specifically, for example, a conductive material such as an Al—Nd alloy layer, an Al—Cu alloy layer, or a laminated structure of an Al—Ti alloy layer and an ITO layer, and the second electrode 32 is made of a transparent conductive material such as IZO or ITO. The first electrode 31 functions as an anode electrode, and the second electrode 32 functions as a cathode electrode. Furthermore, the first electrode 31 also has a function of reflecting light. A maximum inclination angle of the protrusion 28 is 75 degrees.

In each light emitting element unit in the display device of Example 1 or Examples 2 to 6 described later, the light emitting region 30 (30₁, 30₂, 30₃) includes the first electrode 31, the organic layer (including the light emitting layer) 33, and the second electrode 32 as described above. Specifically, the first electrode 31, the organic layer 33, and the second electrode 32 are sequentially formed on the base 26. The base 26 is formed on a first substrate 51. Examples of a material constituting the base 26 include an insulating material such as SiO₂, SiN, or SiON. Each light emitting element 10 (10₁, 10₂, 10₃) disposed on the base 26 formed on the first substrate 51 includes at least:

the first electrode 31;

the second electrode 32; and

the organic layer (including a light emitting layer constituted by an organic electroluminescence layer) 33 sandwiched between the first electrode 31 and the second electrode 32. Alternatively, in other words,

the first substrate 51 and the second substrate 52;

the base 26 disposed on the first substrate 51;

a plurality of the light emitting elements 10 arranged two-dimensionally on the base 26; and

a sealing resin layer 36 formed between the light emitting element 10 and the second substrate 52

are at least included. Each light emitting element is constituted by the light emitting element of Example 1 or a light emitting element of Examples 2 to 6 described later. Light from the light emitting region 30 is emitted to the outside via the second substrate 52 or emitted to the outside via the first substrate 51. Specifically, in Example 1 or Examples 2 to 6 described later, the light is emitted to the outside via the second substrate 52. That is, the display device of Examples is a top emission type display device that emits light from the second substrate 52.

In the light emitting element 10 (10₁, 10₂, 10₃) of Example 1 or Examples 2 to 6 described later, the light emitting region 30 (30₁, 30₂, 30₃) includes the organic electroluminescence layer (light emitting layer) 33 as described above.

The second electrode 32 is covered with a protective layer 34. The second-A wavelength conversion layer 42₁ and the second-B wavelength conversion layer 42₂ are formed on the protective layer 34, and a flattening layer 35 is formed on the protective layer 34, the second-A wavelength conversion layer 42₁, and the second-B wavelength conversion layer 42₂. A wavelength selection unit (specifically, the first color filter layer CF: that selectively transmits blue light, the second color filter layer CF₂ that selectively transmits green light, or the third color filter layer CF₃ that selectively transmits red light) made of a known material is formed on the flattening layer 35. The color filter layer CF₁, CF₂, CF₃ is an on-chip color filter layer (OCCF) formed on the first substrate side. As a result, a distance between the organic layer 33 and the color filter layer CF can be shortened, and it is possible to suppress occurrence of color mixing by incidence of light emitted from the organic layer 33 on an adjacent color filter layer CF of another color. The color filter layer CF₁, CF₂, CF₃ is bonded to the second substrate 52 by the sealing resin layer 36 made of a thermosetting adhesive such as an acrylic adhesive, an epoxy-based adhesive, a urethane-based adhesive, a silicone-based adhesive, or a cyanoacrylate-based adhesive, or an ultraviolet-curable adhesive. The planar shape of the color filter layer CF only needs to appropriately coincide with the planar shape of the light emitting region 30.

In the light emitting element 10 of Example 1 constituted by an organic EL element, the organic layer 33 has a blue light emitting layer and emits blue light. One light emitting element unit (one pixel) includes three types of light emitting elements of the first light emitting element (blue light emitting element) 10₁, the second light emitting element (green light emitting element) 10₂, and the third light emitting element (red light emitting element) 10₃, and the plurality of light emitting element units is arranged two-dimensionally (specifically, in a first direction and a second direction different from the first direction). The first light emitting element 10₁ includes a combination of the organic layer 33 that emits blue light and the color filter layer CF₁. The second light emitting element 10₂ includes a combination of the organic layer 33 that emits blue light, the first-A wavelength conversion layer 41₁, the second-A wavelength conversion layer 42₁, and the color filter layer CF₂. Furthermore, the third light emitting element 10₂ includes a combination of the organic layer 33 that emits blue light, the first-B wavelength conversion layer 41₂, the second-B wavelength conversion layer 42₂, and the color filter layer CF₂. The number of pixels is, for example, 1920×1080. One light emitting element (display element) constitutes one sub-pixel, and the number of light emitting elements (specifically, organic EL elements) is three times the number of pixels. In the display device of Example 1, examples of an arrangement of sub-pixels include a delta arrangement illustrated in FIG. 7A, a stripe arrangement illustrated in FIG. 7B, a diagonal arrangement illustrated in FIG. 7C, and a rectangle arrangement. The planar shapes of the light emitting element and the light emitting region 30 are rectangular or elliptical, but are not limited thereto. The display device may include a fourth light emitting element that emits complementary color light.

A drive circuit (light emitting element driving unit) is disposed below the base (interlayer insulating layer) 26 formed on the basis of a CVD method. The drive circuit can have a known circuit configuration. The drive circuit is constituted by, for example, a transistor (specifically, for example, a MOSFET) formed on a silicon semiconductor substrate constituting the first substrate 51. A transistor 20 constituted by a MOSFET includes a gate insulating layer 22 formed on the first substrate 51, a gate electrode 21 formed on the gate insulating layer 22, a source/drain region 24 formed on the first substrate 51, a channel formation region 23 formed between the source/drain regions 24, and an element isolation region 25 surrounding the channel formation region 23 and the source/drain region 24. The base 26 includes a lower interlayer insulating layer 26A and an upper interlayer insulating layer 26B. The transistor 20 constituting the drive circuit and the first electrode 31 are electrically connected to each other via a contact plug 27A disposed in the lower interlayer insulating layer 26A, a pad 27C disposed on the lower interlayer insulating layer 26A, and a contact plug 27B disposed in the upper interlayer insulating layer 26B. Note that, in the drawings, one transistor 20 is illustrated for one drive circuit.

The second electrode 32 is connected to the drive circuit (light emitting element driving unit) via a contact hole (contact plug) (not illustrated) formed in the base (interlayer insulating layer) 26 at an outer peripheral portion (specifically, an outer peripheral portion of a pixel array unit) of the display device. In the outer peripheral portion of the display device, an auxiliary electrode connected to the second electrode 32 may be disposed below the second electrode 32, and the auxiliary electrode may be connected to the drive circuit.

The first electrode 31 is formed on the base (interlayer insulating layer) 26 and the protrusion 28 on the basis of a combination of a vacuum vapor deposition method and an etching method. The first electrode 31 is disposed for each of the light emitting elements. The second electrode 32 is formed by a film forming method in which energy of film-forming particles is small, such as a vacuum vapor deposition method, and is not patterned. That is, the second electrode 32 is an electrode shared by the plurality of light emitting elements. In other words, the second electrode 32 is a so-called solid electrode. The organic layer 33 is not patterned, either. That is, the organic layer 33 is disposed so as to be shared by the light emitting elements. That is, the organic layer 33 is also a solid film. Note that the organic layer 33 is not limited thereto, and the organic layer 33 may be patterned. That is, the organic layer 33 may be colored separately for each sub-pixel. The first substrate 51 is disposed under the base 26, and the second substrate 52 is disposed above the second electrode 32. The light emitting element is formed on the first substrate side, and the light emitting region 30 is formed on the base 26.

In Example 1, the organic layer 33 has a laminated structure of a hole injection layer (HIL), a hole transport layer (HTL), a light emitting layer, an electron transport layer (ETL), and an electron injection layer (EIL). As described above, light emitted from the organic layer 33 is blue.

The hole injection layer is a layer that enhances hole injection efficiency and functions as a buffer layer that prevents leakage, and has a thickness of, for example, about 2 nm to 10 nm. The hole injection layer is made of, for example, a hexaazatriphenylene derivative represented by the following formula (A) or (B). Note that contact of an end surface of the hole injection layer with the second electrode is a main cause of occurrence of luminance variation between pixels, leading to deterioration of display image quality.

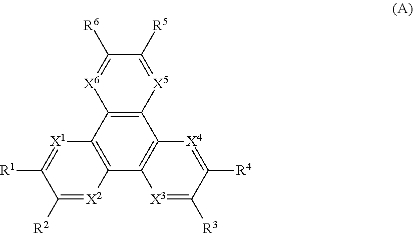

Here, R¹ to R⁶ each independently represent a substituent selected from the group consisting of a hydrogen atom, a halogen atom, a hydroxy group, an amino group, an arulamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxy group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, and a silyl group, and adjacent R^{m} (m=1 to 6) may be bonded to each other via a cyclic structure. X¹ to X⁶ each independently represent a carbon atom or a nitrogen atom.

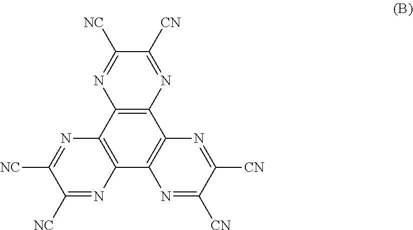 [SMILES: N#Cc1nc2c3nc(C#N)c(C#N)nc3c3nc(C#N)c(C#N)nc3c2nc1C#N]

The hole transport layer is a layer that enhances hole transport efficiency to the light emitting layer. In the light emitting layer, when an electric field is applied thereto, recombination of electrons and holes occurs, and light is generated. The electron transport layer is a layer that enhances electron transport efficiency to the light emitting layer, and the electron injection layer is a layer that enhances electron injection efficiency to the light emitting layer.

The hole transport layer is made of, for example, 4,4′,4″-tris(3-methylphenylphenylamino)triphenylamine (m-MTDATA) or α-naphthylphenyldiamine (αNPD) having a thickness of about 40 nm.

In the blue light emitting layer, when an electric field is applied thereto, some of holes injected from the first electrode 31 and some of electrons injected from the second electrode 32 are recombined to generate blue light. Such a blue light emitting layer contains, for example, at least one material among a blue light emitting material, a hole transporting material, an electron transporting material, and a both charge transporting material. The blue light emitting material may be a fluorescent material or a phosphorescent material. The blue light emitting layer having a thickness of about 30 nm is formed by, for example, mixing 2.5% by mass of 4,4′-bis[2-{4-(N,N-diphenylamino)phenyl}vinyl]biphenyl (DPAVBi) with DPVBi.

The electron transport layer having a thickness of about 20 nm is made of, for example, 8-hydroxyquinoline aluminum (Alq3). The electron injection layer having a thickness of about 0.3 nm is made of, for example, LiF or Li₂O.

Note that the materials constituting the layers are merely examples, and are not limited to these materials. For simplification of the drawings, the organic layer 33 is illustrated by one layer in the drawings.

Hereinafter, an outline of a method for manufacturing the light emitting element 10 of Example 1 illustrated in FIG. 1 will be described.

[Step-100]

First, a drive circuit (light emitting element driving unit) is formed on a silicon semiconductor substrate (first substrate 51) on the basis of a known MOSFET manufacturing process.

[Step-110]

Next, the lower interlayer insulating layer 26A is formed on the entire surface by a CVD method. Then, a connection hole is formed in a portion of the lower interlayer insulating layer 26A located above one of the source/drain regions 24 of the transistor 20 on the basis of a photolithography technique and an etching technique, a conductive material layer is formed on the lower interlayer insulating layer 26A including the connection hole on the basis of, for example, a sputtering method, and the conductive material layer is further patterned on the basis of a photolithography technique and an etching technique, whereby the contact hole (contact plug) 27A and the pad 27C can be formed.

[Step-120]

Then, the upper interlayer insulating layer 26B is formed on the entire surface, a connection hole is formed in a portion of the upper interlayer insulating layer 26B located above the desired pad 27C on the basis of a photolithography technique and an etching technique, a conductive material layer is formed on the upper interlayer insulating layer 26B including the connection hole on the basis of, for example, a sputtering method, and next, the conductive material layer is patterned on the basis of a photolithography technique and an etching technique, whereby the contact hole (contact plug) 27B electrically connecting the first electrode 31 and the transistor 20 to each other can be formed in the connection hole.

[Step-130]

Next, an insulating layer 28′ is formed on the entire surface on the basis of, for example, a CVD method, and then the insulating layer 28′ is patterned on the basis of a photolithography technique and an etching technique to form the protrusion 28 from the insulating layer 28′. The base 26 and the contact plug 27B are exposed at a bottom of the protrusion 28. FIG. 8A schematically illustrates an arrangement state of an arrangement state of the base 26 and the protrusion 28, but FIG. 8A does not illustrate the exposed contact plug 27B.

[Step-140A]

Thereafter, a conductive material layer is formed on the base 26, the contact plug 27B, and the protrusion 28 on the basis of, for example, a sputtering method, and then, the conductive material layer is patterned on the basis of a photolithography technique and an etching technique, whereby the first electrode 31 can be formed on the base 26 and the protrusion 28. The first electrode 31 is connected to the contact plug 27B. FIG. 8B schematically illustrates an arrangement state of the first electrodes 31 (31A, 31B).

[Step-140B]

Then, a first wavelength conversion layer forming layer is formed on the entire surface by a known method, and then the first wavelength conversion layer forming layer is patterned on the basis of a photolithography technique and an etching technique, whereby the first wavelength conversion layer 41 (first-A wavelength conversion layer 41₁, first-B wavelength conversion layer 41₂) can be formed on the second portion 31B of the first electrode 31 on the protrusion 28. FIG. 9A schematically illustrates an arrangement state of an arrangement state of the organic layer 33 and the first wavelength conversion layer 41₁, 41₂.

[Step-140C]

Thereafter, the organic layer 33 is formed on the first portion 31A of the first electrode 31, the first wavelength conversion layer 41 (first-A wavelength conversion layer 41₁, first-B wavelength conversion layer 41₂), and the insulating layer 28 by, for example, a PVD method such as a vacuum vapor deposition method or a sputtering method, or a coating method such as a spin coating method or a die coating method. In some cases, the organic layer 33 may be patterned into a desired shape.

[Step-140C]

Next, the second electrode 32 is formed on the entire surface on the basis of, for example, a vacuum vapor deposition method. In some cases, the second electrode 32 may be patterned into a desired shape. In this way, the organic layer 33 and the second electrode 32 can be formed on the first electrode 31. FIG. 9B schematically illustrates an arrangement state of the second electrodes 32.

[Step-140D]

Thereafter, the protective layer 34 is formed on the entire surface on the basis of, for example, a PVD method.

[Step-150]

Then, the second-A wavelength conversion layer 42₁ and the second-B wavelength conversion layer 42₂ are formed above the second electrode 32. Specifically, a second wavelength conversion layer forming layer is formed on the protective layer 34 by a known method, and then the second wavelength conversion layer forming layer is patterned on the basis of a photolithography technique and an etching technique, whereby the second-A wavelength conversion layer 42₁ and the second-B wavelength conversion layer 42₂ can be formed above the second electrode 32.

[Step-160]

Next, for example, the flattening layer 35 is formed on the entire surface on the basis of a coating method. Since the flattening layer 35 can be formed on the basis of a coating method, there are few restrictions on a processing process, a material selection width is wide, and a high refractive index material can be used. Thereafter, the color filter layer CF₁, CF₂, CF₃ is formed on the flattening layer 35 by a known method.

[Step-170]

Next, the color filter layer CF₁, CF₂, CF₃ and the second substrate 52 are bonded to each other by the sealing resin layer 36 made of, for example, an acrylic adhesive. In this way, the light emitting element (organic EL element) and the display device of Example 1 illustrated in FIG. 1 can be obtained. As described above, by adopting a so-called OCCF type in which the color filter layer CF is disposed on the first substrate side instead of disposing the color filter layer CF on the second substrate side, a distance between the organic layer 33 and the color filter layer CF can be shortened, and there is little possibility that a problem occurs in alignment with the organic layer 33.

In the light emitting element of Example 1, and the second light emitting element and the third light emitting element constituting the display device, a part of light emitted in the organic layer passes through the second wavelength conversion layer (second-A wavelength conversion layer, second-B wavelength conversion layer), further passes through the wavelength selection unit, and is emitted to the outside. The remainder of the light emitted in the organic layer (light emitted from the organic layer in a lateral direction or an oblique direction) passes through the first wavelength conversion layer (first-A wavelength conversion layer, first-B wavelength conversion layer) formed in the second portion of the first electrode on the protrusion, collides with the second portion of the first electrode on the protrusion, enters the first wavelength conversion layer (first-A wavelength conversion layer, first-B wavelength conversion layer) again, is emitted from the first wavelength conversion layer (first-A wavelength conversion layer, first-B wavelength conversion layer), passes through the second wavelength conversion layer (second-A wavelength conversion layer, second-B wavelength conversion layer) in some cases, further passes through the wavelength selection unit, and is emitted to the outside. Therefore, the light emitted in the organic layer can be efficiently used for image formation. Moreover, a light emitting element having a configuration and a structure in which optical crosstalk hardly occurs, and a display device including a plurality of the light emitting elements can be provided. That is, even if light that has entered the first wavelength conversion layer (first-A wavelength conversion layer, first-B wavelength conversion layer) enters another adjacent light emitting element, the light is finally absorbed by a wavelength selection unit in the other adjacent light emitting element, and hardly passes through the wavelength selection unit. Therefore, optical crosstalk hardly occurs.

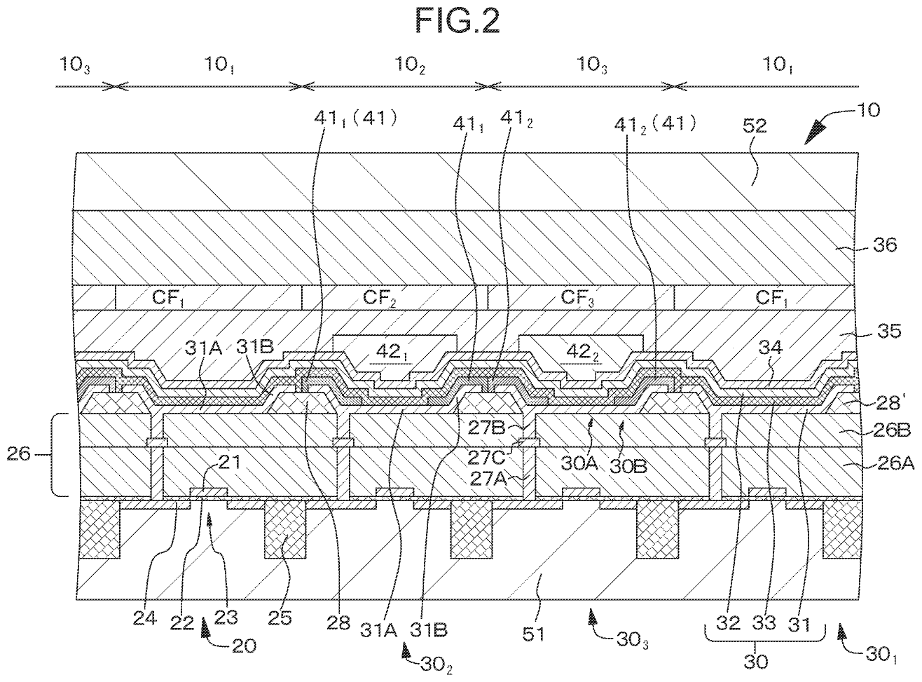

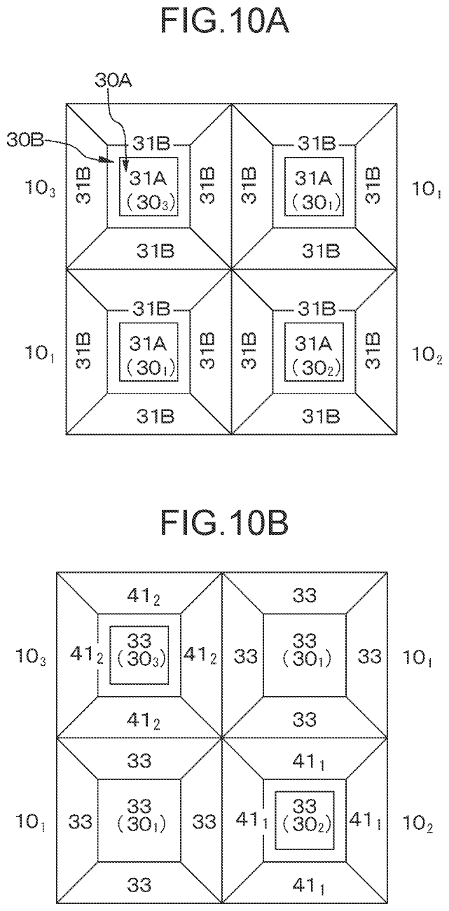

FIG. 2 illustrates a schematic partial cross-sectional view of Modification-1 of the light emitting element and the display device of Example 1. FIG. 10A schematically illustrates an arrangement state of an arrangement state of first electrodes in Modification-1 of the display device of Example 1. FIG. 10B schematically illustrates an arrangement state of an organic layer and a first wavelength conversion layer.

In this Modification-1,

the light emitting region 30 includes a light emitting region central portion 30A and a light emitting region outer peripheral portion 30B surrounding the light emitting region central portion 30A, and

the first wavelength conversion layer 41 (41₁, 41₂) extends to above a portion of the base 26 constituting the light emitting region outer peripheral portion 30B. That is, the first wavelength conversion layer 41 (41₁, 41₂) extends between the first portion 31A of the first electrode 31 located on a portion of the base 26 constituting the light emitting region outer peripheral portion 30B and a portion of the organic layer 33 located above a portion of the base 26 constituting the light emitting region outer peripheral portion 30B.

Except for the above points, the configurations and structures of the light emitting element and the display device of Modification-1, which is a modification of Example 1, can be similar to those of the light emitting element and the display device of Example 1, and thus detailed description thereof will be omitted.

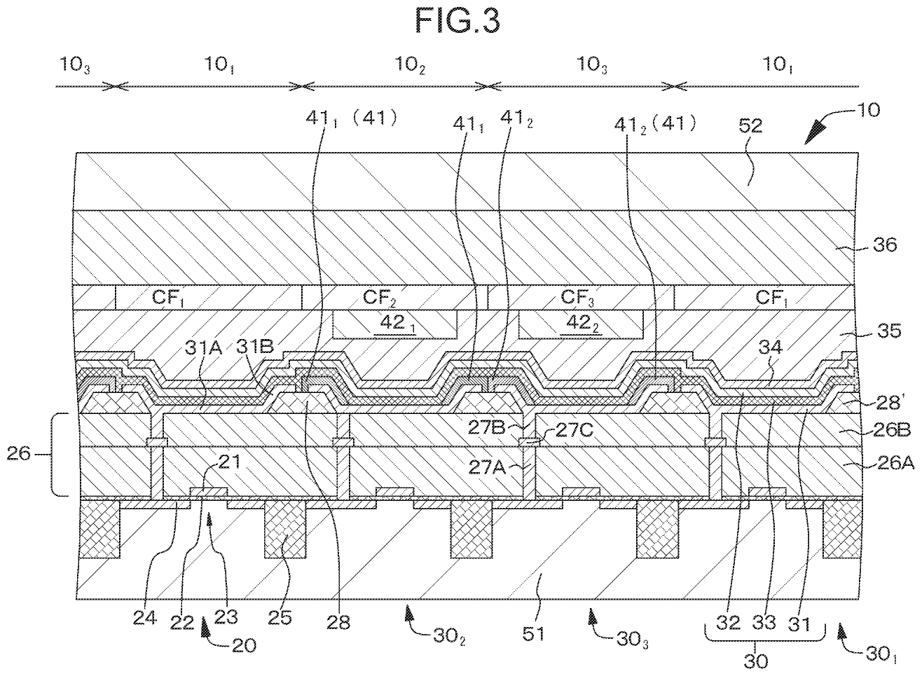

FIG. 3 illustrates a schematic partial cross-sectional view of Modification-2 of the display device of Example 1. In this Modification-2, the second wavelength conversion layer 42 (42₁, 42₂) is formed above the second electrode 32. Specifically, the protective layer 34 is formed on the second electrode 32, the flattening layer 35 is formed on the protective layer 34, and the second wavelength conversion layer 42 (42₁, 42₂) is formed on the flattening layer 35. The flattening layer 35 is formed between the second wavelength conversion layer 42 (42₁, 42₂) and the second wavelength conversion layer 42 (42₁, 42₂). The wavelength selection unit (color filter layer) CF₁, CF₂, CF₃ is formed on the second wavelength conversion layer 42 (42₁, 42₂) and the flattening layer 35.

Except for the above points, the configurations and structures of the light emitting element and the display device of Modification-2, which is a modification of Example 1, can be similar to those of the light emitting element and the display device of Example 1 or those of Modification-1, and thus detailed description thereof will be omitted.

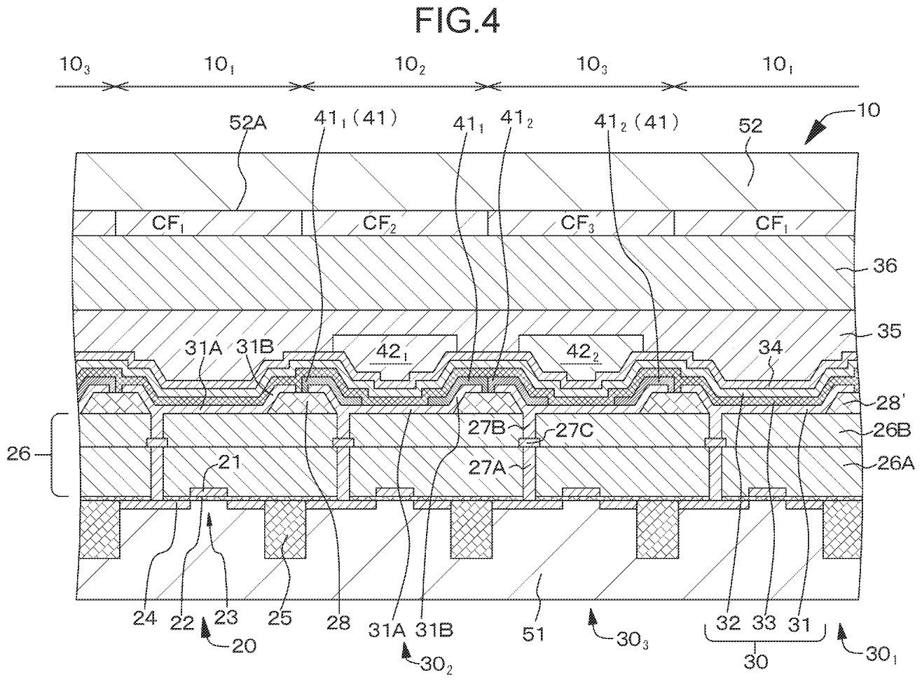

FIG. 4 illustrates a schematic partial cross-sectional view of Modification-3 of the display device of Example 1. In this Modification-3, the wavelength selection unit (color filter layer) CF₁, CF₂, CF₃ is formed on a first surface 52A of the second substrate 52. The flattening layer 35 and the wavelength selection unit (color filter layer) CF₁, CF₂, CF₃ are bonded to each other by the sealing resin layer 36.

Except for the above points, the configurations and structures of the light emitting element and the display device of Modification-3, which is a modification of Example 1, can be similar to those of the light emitting element and the display device of Example 1 or those of Modification-1 and Modification-2, and thus detailed description thereof will be omitted.

Note that FIGS. 4, 5, 6, 11, 17, 18, 21, 22, 23, 24, 25, 26, and 27 illustrate schematic partial cross-sectional views based on Modification-1 of Example 1, but the present disclosure is not limited thereto.

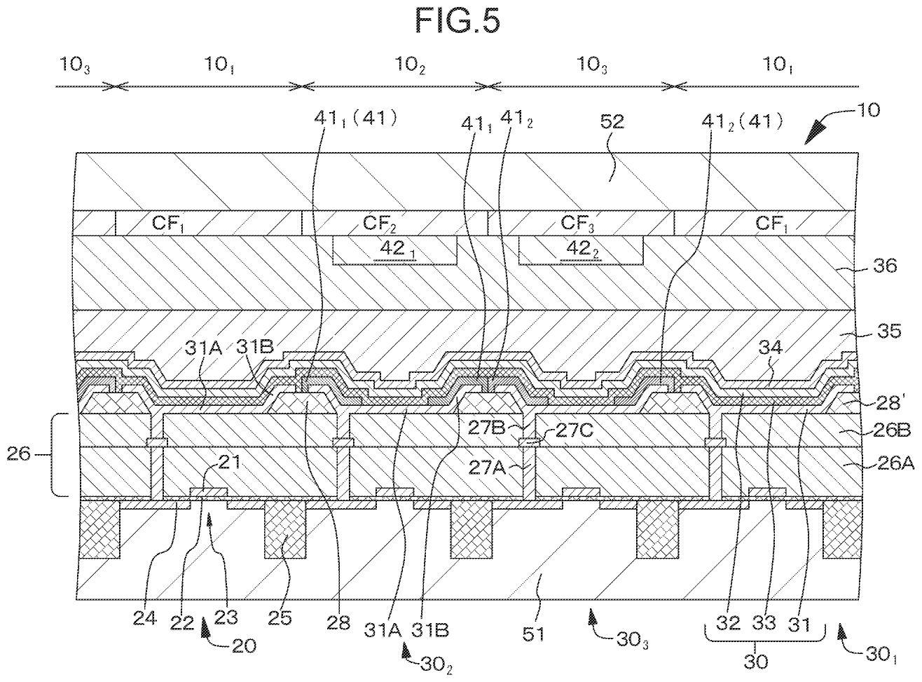

FIG. 5 illustrates a schematic partial cross-sectional view of Modification-4 of the display device of Example 1. In this Modification-4, the wavelength selection unit (color filter layer) CF₁, CF₂, CF₃ is formed on the first surface 52A of the second substrate 52. The second wavelength conversion layer 42 (42₁, 42₂) is formed on the wavelength selection unit (color filter layer) CF₁, CF₂, CF₃ facing the protective layer 34. The flattening layer 35 is bonded to the wavelength selection unit (color filter layer) CF₁, CF₂, CF₃ and the second wavelength conversion layer 42 (42₁, 42₂) by the sealing resin layer 36.

Except for the above points, the configurations and structures of the light emitting element and the display device of Modification-4, which is a modification of Example 1, can be similar to those of the light emitting element and the display device of Example 1 or those of Modification-1, and thus detailed description thereof will be omitted.

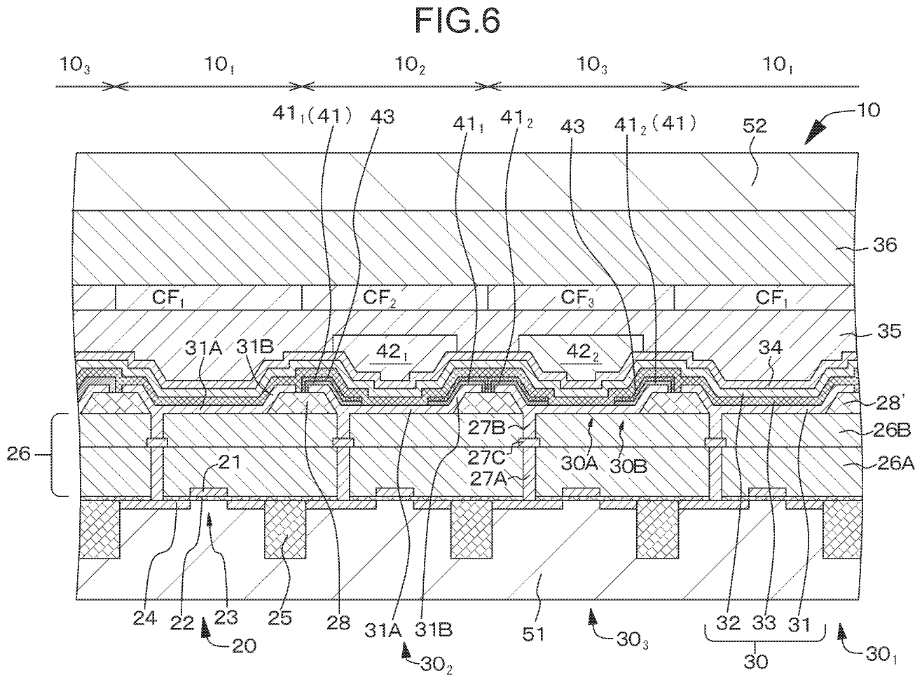

FIG. 6 illustrates a schematic partial cross-sectional view of Modification-5 of the display device of Example 1. In this Modification-5, the first wavelength conversion layer 41 is covered with a transparent insulating material layer 43. Examples of a material constituting the transparent insulating material layer 43 include polysiloxane having a refractive index n₂ of 1.3 to 1.4 and a fluororesin. Note that a value n₁ of refractive index of a material constituting the first-A wavelength conversion layer 41₁ is 1.6 to 1.7, and a value n₁ of refractive index of a material constituting the first-B wavelength conversion layer 41₂ is 1.6 to 1.7. By defining the refractive index in this manner, a phenomenon occurs in which light incident on the insulating material layer 43 from the first wavelength conversion layer 41 (41₁, 41₂) is totally reflected at the insulating material layer 43 and returned to the first wavelength conversion layer 41 (41₁, 41₂) although it depends on an incident angle to the insulating material layer 43, and as a result, wavelength conversion efficiency in the first wavelength conversion layer 41 can be further improved. Note that, in the first-A wavelength conversion layer 41₁ and the first-B wavelength conversion layer 41₂, the refractive index can be set to 1.6 to 1.7 by mixing titania particles or zirconia particles to increase the refractive index.

Except for the above points, the configurations and structures of the light emitting element and the display device of Modification-5, which is a modification of Example 1, can be similar to those of the light emitting element and the display device of Example 1 or those of Modification-1 to Example 4, and thus detailed description thereof will be omitted.

### Example 2

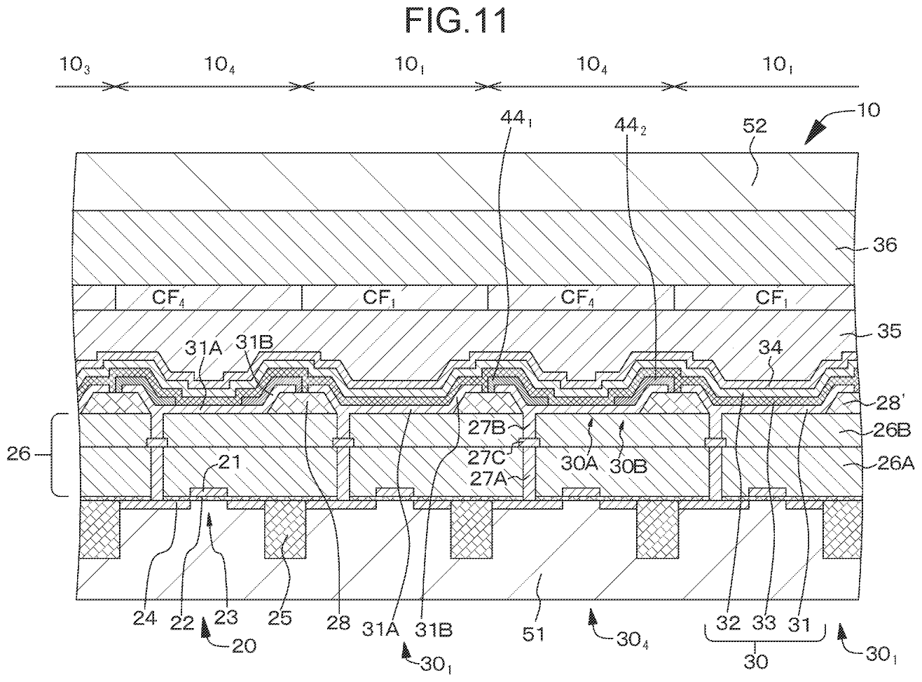

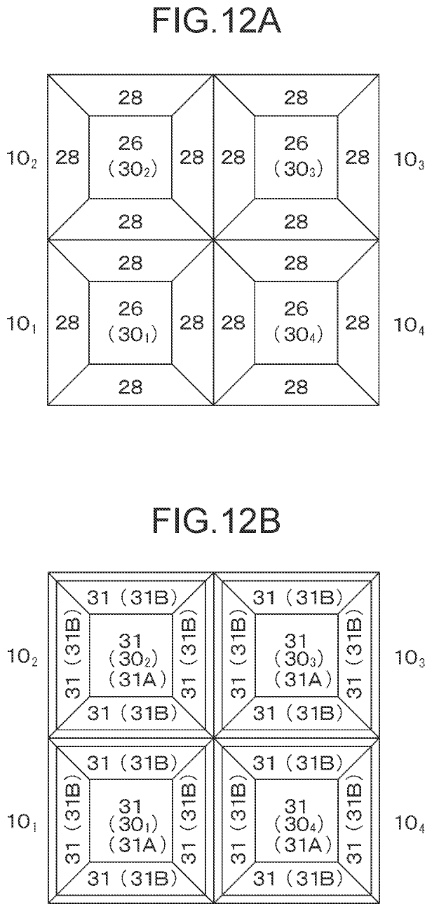

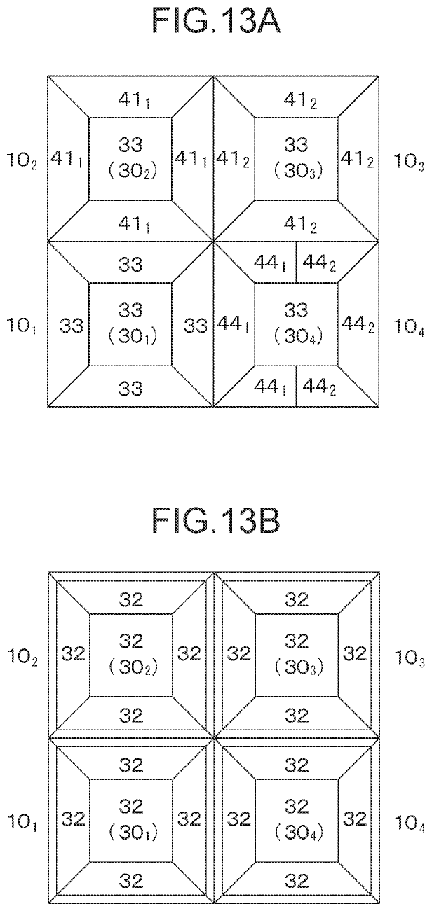

Example 2 relates to the light emitting element according to the second aspect of the present disclosure. FIG. 11 illustrates a schematic partial cross-sectional view of a light emitting element 10₄ of Example 2. FIG. 7D schematically illustrate an arrangement of light emitting elements in the display device of Example 2. FIG. 12A schematically illustrates an arrangement state of an arrangement state of a base and a protrusion in the display device of Example 2. FIG. 12B schematically illustrates an arrangement state of first electrodes. FIG. 13A schematically illustrates an arrangement state of an arrangement state of an organic layer and a first wavelength conversion layer. FIG. 13B schematically illustrates an arrangement state of second electrodes.

The light emitting element 10₄ of Example 2 includes:

the protrusion 28 surrounding the light emitting region 30;

the first electrode 31 including the first portion 31A formed on a portion of the base 26 constituting the light emitting region 30 and the second portion 31B extending from the first portion 31A and formed on the protrusion 28;

the organic layer 33 that is formed on and above the first electrode 31 and emits first light (specifically, blue light) having a wavelength λ₁;

the second electrode 32 formed on the organic layer 33;

a first-A wavelength conversion layer 44₁ that is formed between the second portion 31B of the first electrode 31 and a portion of the organic layer 33 formed above the protrusion 28 and converts the first light emitted from the organic layer 33 into second light (specifically, green light) having a wavelength λ₂ (λ₂>λ₁; and

a first-B wavelength conversion layer 44₂ that is formed in a region between the second portion 31B of the first electrode 31 and a portion of the organic layer 33 formed above the protrusion 28, different from the region where the first-A wavelength conversion layer 44₁ is formed, and converts the first light emitted from the organic layer 33 into third light (specifically, red light) having a wavelength λ₃ (λ₃>λ₂).

The first-A wavelength conversion layer 44₁ can be made of the same material as that of the first-A wavelength conversion layer 41₁ in Example 1, and the first-B wavelength conversion layer 44₂ can be made of the same material as that of the first-B wavelength conversion layer 41₂ in Example 1.

In the display device of Example 2, the light emitting element unit (pixel) includes the fourth light emitting element constituted by the light emitting element 10₄ of Example 2 in addition to the first light emitting element 10₁, the second light emitting element 10₂, and the third light emitting element 10₃ described in Example 1, and these elements constitute one pixel. The fourth light emitting element 10₄ emits white light to the outside. Note that, in the fourth light emitting element 10₄, a transparent filter layer CF₄ is disposed instead of a color filter layer. The first light emitting element 10₁, the second light emitting element 10₂, the third light emitting element 10₃, and the fourth light emitting element 10₄ correspond to sub-pixels.

The protrusion 28 has a forward tapered shape as that in Example 1.

As schematically illustrated in FIG. 13A illustrating an example of an arrangement state of the organic layer 33, the first-A wavelength conversion layer 44₁, and the first-B wavelength conversion layer 41₂, the first-A wavelength conversion layer 44₁ is formed on a half of the protrusion 28, and the first-B wavelength conversion layer 44₂ is formed on the remaining half of the protrusion 28. White light is emitted from the light emitting element (fourth light emitting element) 10₄ of Example 2 to the outside by the blue light emitted from the organic layer 33, the green light emitted from the first-A wavelength conversion layer 44₁, and the red light emitted from the first-B wavelength conversion layer 44₂.

Except for the above points, the configurations of the light emitting element and the display device of Example 2 can be similar to those of the light emitting element and the display device of Example 1 or those of Modification-1 to Modification-5, and thus detailed description thereof will be omitted.

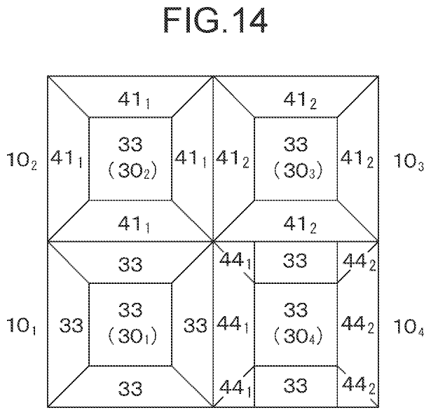

FIG. 14 schematically illustrates an arrangement state of an arrangement state of the organic layer and the first wavelength conversion layer in Modification-1 of the display device of Example 2. In the light emitting element (fourth light emitting element) 10₄ of Modification-1, the first-A wavelength conversion layer 44₁ is formed on a portion slightly more than (¼) of the protrusion 28, the first-B wavelength conversion layer 44₂ is formed on another portion slightly more than (¼) of the protrusion 28, and the organic layer 33 extends on the remaining portion of the protrusion 28. White light is also emitted from the light emitting element (fourth light emitting element) 10₄ of Modification-1 of Example 2 to the outside by the blue light emitted from the organic layer 33, the green light emitted from the first-A wavelength conversion layer 44₁, and the red light emitted from the first-B wavelength conversion layer 44₂.

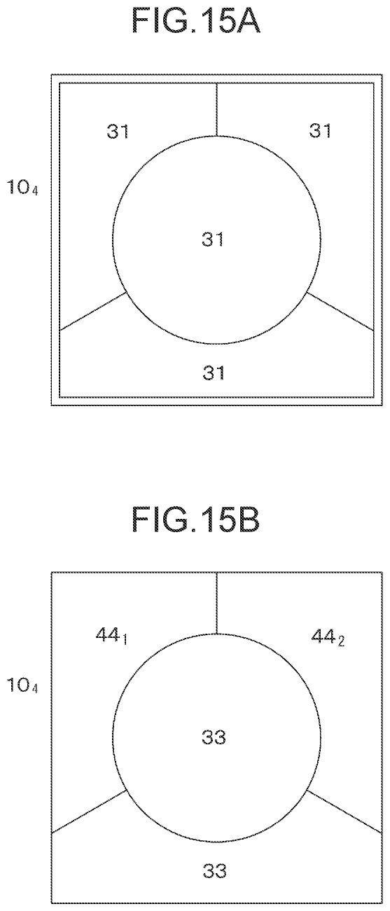

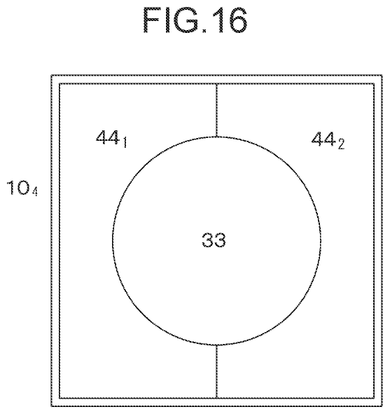

The planar shapes of the light emitting element and the light emitting region 30 are rectangular, but are not limited thereto. FIG. 15A schematically illustrates an arrangement state of first electrodes in Modification-2 of the display device of Example 2. FIG. 15B schematically illustrates an arrangement state of an arrangement state of an organic layer and a first wavelength conversion layer. The planar shape of the light emitting region 30 can be circular. In the light emitting element (fourth light emitting element) 10₄ of this Modification-2, the first-A wavelength conversion layer 44₁ is formed on (⅓) of the protrusion 28, and the first-B wavelength conversion layer 44₂ is formed on another (⅓) of the protrusion 28. The organic layer 33 extends on the remaining portion of the protrusion 28, but the first-A wavelength conversion layer 44₁ or the first-B wavelength conversion layer 44₂ is not formed thereon. Alternatively, as Modification-3, FIG. 16 schematically illustrates an arrangement state of an arrangement state of an organic layer and a first wavelength conversion layer. The first-A wavelength conversion layer 44₁ may be formed on (½) of the protrusion 28, and the first-B wavelength conversion layer 44₂ may be formed on the other (½) of the protrusion 28. In these Modification-2 and Modification-3, white light is also emitted to the outside by the blue light emitted from the organic layer 33, the green light emitted from the first-A wavelength conversion layer 44₁, and the red light emitted from the first-B wavelength conversion layer 44₂.

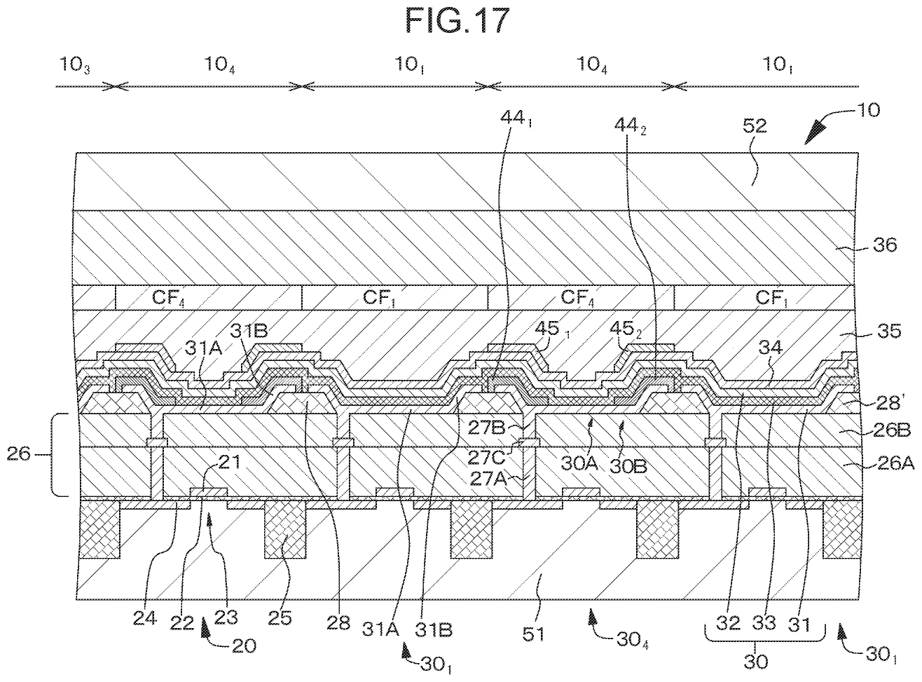

FIG. 17 illustrates a schematic partial cross-sectional view of Modification-3 of the light emitting element 10₄ and the display device of Example 2. This light emitting element 10₄ further includes:

a second-A wavelength conversion layer 45₁ that is formed on or above the second electrode 32 and converts first light emitted from the organic layer 33 into second light; and

a second-B wavelength conversion layer 45₂ that is formed on or above the second electrode 32 and converts the first light emitted from the organic layer 33 into third light, and

emits white light from the light emitting element 10₄.

Except for the above points, the configurations of the light emitting element and the display device of Modification-3, which is a modification of Example 2, can be similar to those of the light emitting element and the display device of Example 2 or those of Modification-1 and Modification-2, and thus detailed description thereof will be omitted.

### Example 3

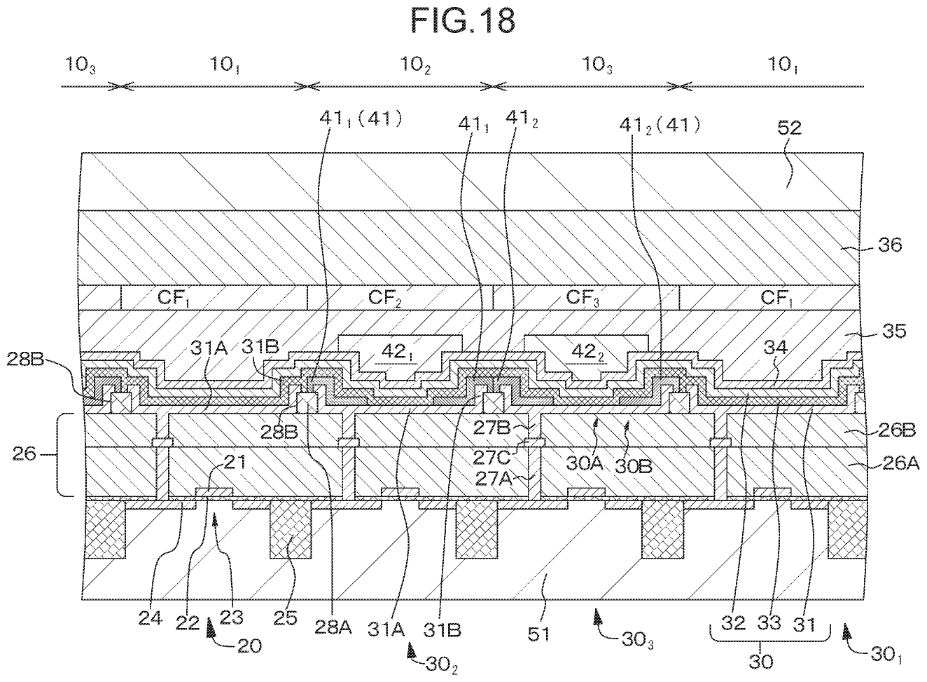

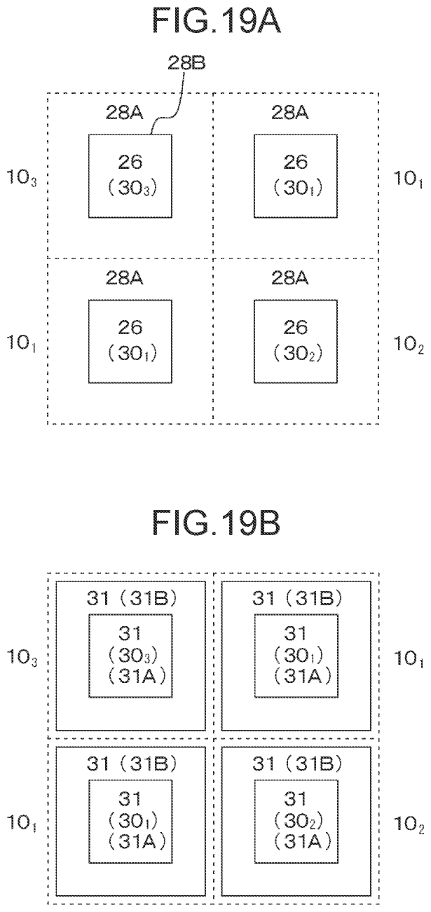

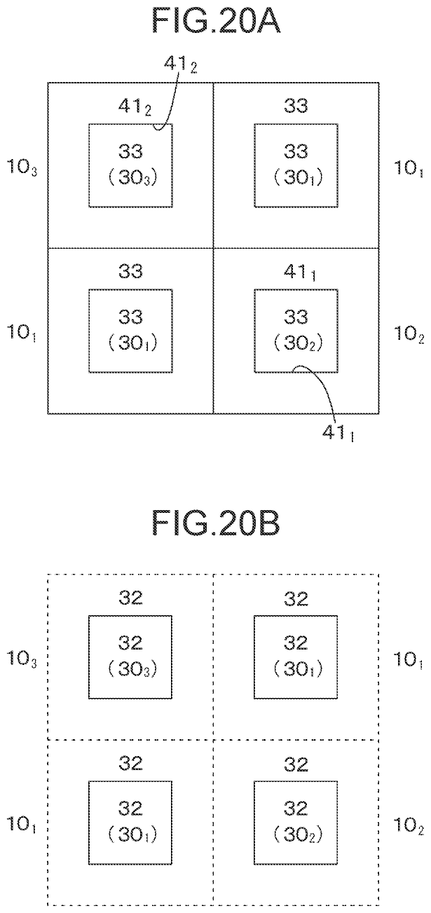

Example 3 is a modification of Examples 1 and 2. FIG. 18 illustrates a schematic partial cross-sectional view of a light emitting element and a display device of Example 3. FIG. 19A schematically illustrates an arrangement state of an arrangement state of a base and a protrusion in the display device of Example 3. FIG. 19B schematically illustrates an arrangement state of first electrodes. FIG. 20A schematically illustrates an arrangement state of an arrangement state of an organic layer and a first wavelength conversion layer. FIG. 20B schematically illustrates an arrangement state of second electrodes. Note that, in FIGS. 19A, 19B, and 20B, a boundary between the light emitting element and the light emitting element is indicated by a dotted line.

In the light emitting element and the display device of Example 3, a side surface 28B of a protrusion 28A forms an angle of 90°±10° with respect to the base 26.

In the light emitting element of Example 3, and the second light emitting element and the third light emitting element constituting the display device, a part of light emitted in the organic layer 33 passes through the second wavelength conversion layer (second-A wavelength conversion layer, second-B wavelength conversion layer), further passes through the wavelength selection unit CF₂, CF₃, and is emitted to the outside. The remainder of the light emitted in the organic layer 33 (light emitted from the organic layer 33 in a lateral direction or an oblique direction) passes through the first wavelength conversion layer 41 (first-A wavelength conversion layer 41₁, first-B wavelength conversion layer 41₂) formed on the second portion 31B of the first electrode on the side surface 28B of the protrusion 28A, collides with the second portion 31B of the first electrode on the side surface 28B of the protrusion 28A, is reflected, is returned to the first wavelength conversion layer 41 (first-A wavelength conversion layer 41₁, first-B wavelength conversion layer 41₂), is emitted from the first wavelength conversion layer 41 (first-A wavelength conversion layer 41₁, first-B wavelength conversion layer 41₂), finally passes through the second wavelength conversion layer 42 (second-A wavelength conversion layer 42₂₁, second-B wavelength conversion layer 42₂), further passes through the wavelength selection unit CF₂, CF₃, and is emitted to the outside. Therefore, the light emitted in the organic layer 33 can be more efficiently used for image formation. Moreover, a light emitting element having a configuration and a structure in which optical crosstalk hardly occurs, and a display device including a plurality of the light emitting elements can be provided. The behavior of the fourth light emitting element 10₄ in a case where the light emitting element of Example 2 is applied is also substantially similar.

Except for the above points, the light emitting element and the display device of Example 3 can be similar to the light emitting elements and the display devices of Example 1 or Modification-1 to Modification-5, which are modifications of Example 1, or Example 2 or Modification-1 to Modification-3, which are modifications of Example 2, and thus detailed description thereof will be omitted.

### Example 4

Example 4 is a modification of Example 3. A light emitting element of Example 4 has a resonator structure.

The organic EL display device preferably has a resonator structure in order to further improve light extraction efficiency. Specifically, light emitted in the light emitting layer is caused to resonate between a first interface constituted by an interface between the first electrode and the organic layer (or an interface constituted by an interface between a light reflecting layer and an interlayer insulating material layer in a structure in which the interlayer insulating material layer is formed under the first electrode and the light reflecting layer is formed under the interlayer insulating material layer) and a second interface constituted by an interface between the second electrode and the organic layer, and a part of the light is emitted from the second electrode. When a distance from a maximum light emitting position (light emitting surface) of the light emitting layer to the first interface is represented by L₁, an optical distance thereof is represented by OL₁, a distance from the maximum light emitting position (light emitting surface) of the light emitting layer to the second interface is represented by L₂, an optical distance thereof is represented by OL₂, and m₁ and m₂ are integers, a configuration satisfying the following formulas (1-1) and (1-2) can be adopted.

0.7{−Φ₁/(2π)+m₁}≤2×OL₁/λ≤1.2{−Φ₁/(2π)+m₁} (1-1)

0.7{−Φ₂/(2π)+m₂}≤2×OL₂/λ≤1.2{−Φ₂/(2π)+m₂} (1-2)

in which

λ: maximum peak wavelength of spectrum of light generated in light emitting layer (or desired wavelength of light generated in light emitting layer)

Φ₁: phase shift amount (unit: radian) of light reflected at first interface, provided that −2π<Φ₁≤0

Φ₂: phase shift amount (unit: radian) of light reflected at second interface, provided that −2π<Φ₂≤0

Here, a value of m₁ is a value of 0 or more, and a value of m₂ is a value of 0 or more independently of the value of m₁. A form of (m₁, m₂)=(0, 0), a form of (m₁, m₂)=(0, 1), a form of (m₁, m₂)=(1, 0), and a form of (m₁, m₂)=(1, 1) can be exemplified.

The distance L₁ from the maximum light emitting position of the light emitting layer to the first interface refers to an actual distance (physical distance) from the maximum light emitting position of the light emitting layer to the first interface, and the distance L₂ from the maximum light emitting position of the light emitting layer to the second interface refers to an actual distance (physical distance) from the maximum light emitting position of the light emitting layer to the second interface. The optical distance is also referred to as an optical path length, and generally refers to n×L when a light beam passes through a medium having a refractive index n by a distance L. The same applies to the following. Therefore, when an average refractive index is represented by nₐᵥₑ,

OL₁=L₁×nₐᵥₑ and

OL₂=L₂×nₐᵥₑ

are satisfied. Here, the average refractive index nₐᵥₑ is obtained by summing up a product of a refractive index and a thickness of each layer constituting the organic layer (or the organic layer, the first electrode, and the interlayer insulating material layer) and dividing the sum by the thickness of the organic layer (or the organic layer, the first electrode, and the interlayer insulating material layer).

It is only required to design the light emitting element by determining a desired wavelength λ₁ of light generated in the light emitting layer (specifically, a blue wavelength) and determining various parameters such as OL₁ and OL₂ in the light emitting element on the basis of formulas (1-1) and (1-2).

The first electrode or the light reflecting layer and the second electrode absorb a part of incident light and reflect the remaining light. Therefore, a phase shift occurs in reflected light. The phase shift amounts Φ₁ and Φ₂ can be determined by measuring values of a real number part and an imaginary number part of a complex refractive index of a material constituting the first electrode or the light reflecting layer and the second electrode using, for example, an ellipsometer and performing calculation based on these values (see, for example, “Principles of Optic”, Max Born and Emil Wolf, 1974 (PERGAMON PRESS)). In a case where the first electrode absorbs a part of incident light and reflects the remaining light, a refractive index of the organic layer, the interlayer insulating material layer, or the like can also be determined by measurement using an ellipsometer.

Examples of a material constituting the light reflecting layer include aluminum, an aluminum alloy (for example, Al—Nd or Al—Cu), an Al/Ti laminated structure, an Al—Cu/Ti laminated structure, chromium (Cr), silver (Ag), and a silver alloy (for example, Ag—Cu, Ag—Pd—Cu, or Ag—Sm—Cu). The light reflecting layer can be formed by, for example, a vapor deposition method including an electron beam vapor deposition method, a hot filament vapor deposition method, and a vacuum vapor deposition method, a sputtering method, a CVD method, or an ion plating method; a plating method (electroplating method or electroless plating method); a lift-off method; a laser ablation method; or a sol-gel method. Depending on a material constituting the light reflecting layer, it is preferable to form a base layer, for example, made of TiN in order to control a crystalline state of the light reflecting layer to be formed.

As described above, in the light emitting element 10 having a resonator structure, blue light emitted in the organic layer is caused to resonate. In Examples 1 to 3 including various modifications, the first electrode 31 also functions as a light reflecting material layer. Therefore, the organic layer 33 is used as a resonance unit, and a resonator structure sandwiched between the first electrode 31 and the second electrode 32 is formed. In order to appropriately adjust a distance from a light emitting surface to a reflecting surface (specifically, a distance from the light emitting surface to the first electrode 31 and the second electrode 32), the thickness of the organic layer 33 is, for example, preferably 8×10⁻⁸ m or more and 5×10⁻⁷ m or less, and more preferably 1.5×10⁻⁷ m or more and 3.5×10⁻⁷ m or less. A value of (L₁+L₂=L₀) only needs to be the same in the first light emitting element, the second light emitting element, and the third light emitting element.

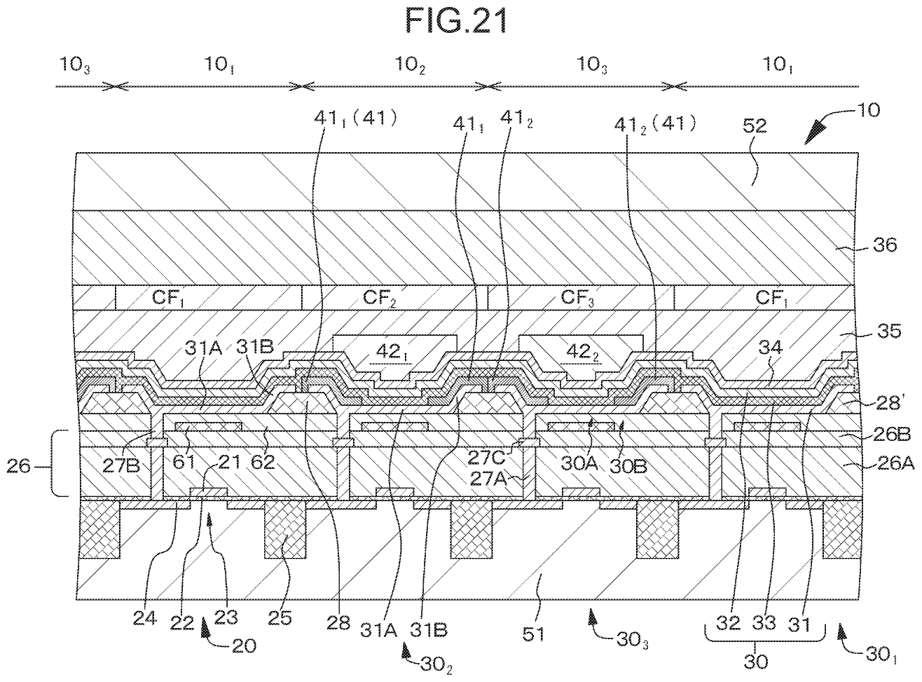

As illustrated in FIG. 21 illustrating a schematic partial cross-sectional view, the first portion 31A of the first electrode 31 and the second portion 31B of the first electrode 31 are made of different materials. Specifically, the second portion 31B of the first electrode 31 is made of the material constituting the first electrode 31 described in Example 1. Meanwhile, the first portion 31A of the first electrode 31 is made of a transparent conductive material, for example, ITO. A light reflecting layer 61 is formed below the first electrode 31 (on the first substrate side), the organic layer 33 is used as a resonance unit, and a resonator structure sandwiched between the light reflecting layer 61 and the second electrode 32 is formed. That is, the light reflecting layer 61 is formed on the base 26, the interlayer insulating material layer 62 made of the above-described material is formed on the light reflecting layer 61, and the first electrode 31 is disposed on the interlayer insulating material layer 62. By appropriately setting the thickness of the interlayer insulating material layer 62, it is possible to set an optical distance at which optimum resonance is generated with respect to the light emission wavelength λ₁ of the light emitting region 30. The light reflecting layer 61 may be connected to the contact hole (contact plug) 27B or does not have to be connected thereto.

The interlayer insulating material layer 62 can also be made of an oxide film in which a surface of the light reflecting layer 61 is oxidized. The interlayer insulating material layer 62 made of an oxide film is made of, for example, aluminum oxide, tantalum oxide, titanium oxide, magnesium oxide, or zirconium oxide depending on a material constituting the light reflecting layer 61. The surface of the light reflecting layer 61 can be oxidized by, for example, the following method. That is, the first substrate 51 in which the light reflecting layer 61 is formed is immersed in an electrolytic solution filled in a container. A cathode is disposed so as to face the light reflecting layer 61. Then, the light reflecting layer 61 is anodized using the light reflecting layer 61 as an anode. The film thickness of an oxide film due to anodization is proportional to a potential difference between the light reflecting layer 61 as an anode and a cathode. Therefore, anodization is performed in a state where an appropriate voltage is applied. As a result, the interlayer insulating material layers 62 can be collectively formed on the surface of the light reflecting layer 61. Note that a base film (not illustrated) may be disposed below the light reflecting layer 61.

### Example 5

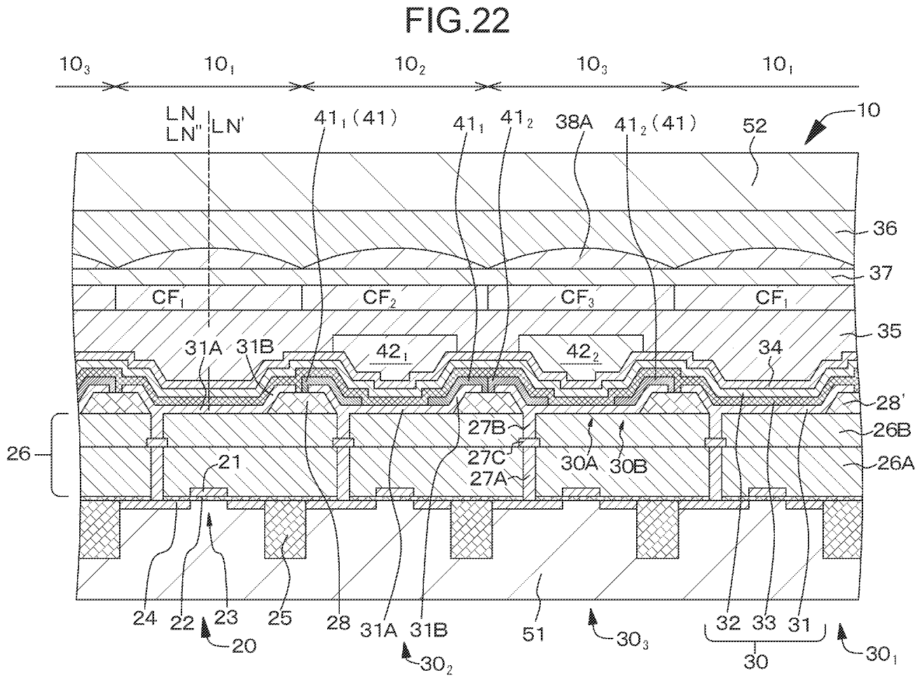

Example 5 is a modification of Examples 1 to 4. A display device of Example 5 includes an optical path control unit through which light emitted from the light emitting region passes. FIGS. 22, 23, 24, 25, and 26 each illustrate a schematic partial cross-sectional view of the display device and a light emitting element of Example 5.

In the display device or the light emitting element of the present disclosure, an optical path control unit through which light emitted from the light emitting region passes may be disposed. The optical path control unit is disposed above the light emitting region. Specifically, a form in which the optical path control unit is formed on or above the flattening layer, a form in which the optical path control unit is formed on or above the wavelength selection unit, or a form in which the optical path control unit is formed on or above the flattening layer and the wavelength selection unit is formed on or above the optical path control unit can be adopted. The optical path control unit is disposed on the first substrate side or the second substrate side. The form in which the optical path control unit is formed on the wavelength selection unit includes a form in which a second flattening layer for flattening unevenness of the wavelength selection unit is formed between the wavelength selection unit and the optical path control unit.

The optical path control unit is constituted by, for example, a lens member (on-chip microlens). In a case where the optical path control unit is constituted by a lens member, the lens member can be convex in a direction away from (along) the light emitting region. In this case, light emitted from the light emitting region passes through the lens member, further passes through, for example, the sealing resin layer and the second substrate, and is emitted to the outside. It is desirable to decrease a refractive index value in the order of the refractive index of a material constituting the lens member, the refractive index of a material constituting the sealing resin layer, and the refractive index of a material constituting the second substrate. Alternatively, the lens member can be concave in a direction away from (along) the light emitting region. In this case, light emitted from the light emitting region passes through, for example, the sealing resin layer and the lens member, further passes through, the second substrate, and is emitted to the outside. It is desirable to increase a refractive index value in the order of the refractive index of a material constituting the sealing resin layer, the refractive index of a material constituting the lens member, and the refractive index of a material constituting the second substrate. Light (image) emitted from the entire display device is, for example, a converged type. However, the degree of the converged type depends on specifications of the display device, and also depends on how much viewing angle dependency and wide viewing angle characteristics are required for the display device. In some cases, a form can be adopted in which a light emitting element having a lens member that is convex in a direction away from the light emitting region and a light emitting element having a lens member that is concave in a direction away from the light emitting region are mixed.

The lens member can be formed in a hemispherical shape or a shape formed of a part of a sphere, or can be formed in a shape suitable to function as a lens in a broad sense. Specifically, the lens member can be formed of a convex lens member (on-chip micro-convex lens) or a concave lens member (on-chip micro-concave lens). In the following description, the convex lens member and the concave lens member may be collectively referred to as “lens member”. The lens member can be a spherical lens or an aspherical lens. In addition, the convex lens member can be formed of a plano-convex lens, and the concave lens member can be formed of a plano-concave lens. Furthermore, the lens member can be a refractive lens or a diffractive lens.

Alternatively, a rectangular parallelepiped (including a cube approximating a rectangular parallelepiped) having a square or rectangular bottom surface is assumed, and the lens member can be formed such that four side surfaces and one top surface of the rectangular parallelepiped are convex or planar. In this case, furthermore, the lens member can be formed so as to have a three-dimensional shape in which a part of a ridge where the side surfaces intersect with each other is rounded, a part of a ridge where the top surface intersects with the side surfaces is also rounded, and the lens member is rounded as a whole.

The lens member can be obtained by melt-flowing or etching back a transparent resin material constituting the lens member, can be obtained by a combination of a photolithography technique using a gray tone mask or a halftone mask and an etching method, or can be obtained by a method for forming a transparent resin material into a lens shape on the basis of a nanoimprint method. Examples of a material constituting the lens member (microlens) include a high refractive resin material (for a convex lens), a high refractive inorganic material (for a convex lens), a low refractive resin material (for a concave lens), and a low refractive inorganic material (for a concave lens). Alternatively, the lens member (on-chip microlens) can be made of, for example, a transparent resin material such as an acrylic resin, an epoxy-based resin, a polycarbonate resin, or a polyimide-based resin, or a transparent inorganic material such as SiO₂, but is not limited thereto.

Alternatively, a form can be adopted in which the optical path control unit is constituted by a light exit direction control member having a rectangular or isosceles trapezoidal cross-sectional shape when being cut along a virtual plane (perpendicular virtual plane) including a thickness direction. In other words, the light exit direction control member can be constituted by a light exit direction control member whose cross-sectional shape is constant or changes (specifically, convexly curved or concavely curved) in a thickness direction thereof. A cross-sectional shape of a side surface of the light exit direction control member in a thickness direction thereof may be linear, convexly curved, or concavely curved. That is, a side surface of a prism or a truncated pyramid described next may be flat, convexly curved, or concavely curved.

Specifically, examples of a three-dimensional shape of the light exit direction control member can include a columnar shape, an elliptical columnar shape, an oval columnar shape, a cylindrical shape, a prismatic shape (including a quadrangular prism, a hexagonal prism, an octagonal prism, and a prismatic shape with rounded ridges), a truncated conical shape, and a truncated pyramid shape (including a truncated pyramid shape with rounded ridges). The prism shape and the truncated pyramid shape include a regular prism shape and a regular truncated pyramid shape, respectively. A part of a ridge where a side surface and a top surface of the light exit direction control member intersect with each other may be rounded. A bottom surface of the truncated pyramid shape may be located on the first substrate side or on the second electrode side. Alternatively, specific examples of a planar shape of the light exit direction control member include a circle, an ellipse, an oval, and a polygon including a triangle, a quadrangle, a hexagon, and an octagon. The polygon includes a regular polygon (including a rectangle and a regular polygon such as a regular hexagon (honeycomb shape)). The light exit direction control member can be made of, for example, a transparent resin material such as an acrylic resin, an epoxy-based resin, a polycarbonate resin, or a polyimide-based resin, or a transparent inorganic material such as SiO₂.

A shortest distance between side surfaces of adjacent light exit direction control members can be 0.4 μm or more and 1.2 μm or less, preferably 0.6 μm or more and 1.2 μm or less, more preferably 0.8 μm or more and 1.2 μm or less, and still more preferably 0.8 μm or more and 1.0 μm or less, but is not limited thereto. By defining a minimum value of the shortest distance between side surfaces of adjacent light exit direction control members to be 0.4 μm, a shortest distance between the adjacent light exit direction control members can be set to be about the same as a lower limit value of a wavelength band of visible light. Therefore, it is possible to suppress deterioration of function of a material or a layer surrounding the light exit direction control member, and as a result, it is possible to effectively enhance a light condensing effect in the vicinity of an outer edge portion (side surface) of the light exit direction control member. Meanwhile, by defining a maximum value of the shortest distance between side surfaces of adjacent light exit direction control members to be 1.2 μm, the size of the light exit direction control members can be reduced, and as a result, a light condensing effect in the vicinity of the outer edge portion (side surface) of the light exit direction control member can be effectively enhanced.

In order to increase light use efficiency of the entire display device, it is preferable to effectively condense light at an outer edge portion of the light emitting element. However, in a hemispherical lens, although an effect of condensing light near the center of the light emitting element on the front is large, an effect of condensing light near an outer edge portion of the light emitting element may be small.

A state in which a side surface of the light exit direction control member is in contact with a material having a refractive index n_{M} lower than a refractive index n_{R} of a material constituting the light exit direction control member can be obtained. A waveguide effect can be imparted to the light exit direction control member, and a light condensing effect in the vicinity of an outer edge portion (side surface) of the light exit direction control member can be effectively enhanced. When a light beam is incident on a side surface of the light exit direction control member, in a case where the incidence is considered in geometrical optics, an incident angle and a reflection angle are equal to each other, and therefore it is difficult to improve extraction in a front direction. However, in a case where the incidence is considered in wave analysis (FDTD), light extraction efficiency in the vicinity of the outer edge portion (side surface) of the light exit direction control member is improved. Therefore, light in the vicinity of the outer edge portion of the light emitting element can be effectively condensed, and as a result, light extraction efficiency in a front direction of the entire light emitting element is improved. Therefore, high light emission efficiency of the display device can be achieved. That is, high luminance and low power consumption of the display device can be achieved. In addition, since the light exit direction control member has a flat plate shape, the light exit direction control member is easily formed, and a manufacturing process can be simplified.

A light exit direction control member extending portion having a smaller thickness than the light exit direction control member may be formed between adjacent light exit direction control members.

A top surface of the light exit direction control member may be flat, may have an upward convex shape, or may have a concave shape, but the top surface of the light exit direction control member is preferably flat from a viewpoint of improving luminance in a front direction of an image display region (display panel) of the display device. The light exit direction control member can be obtained by, for example, a combination of a photolithography technique and an etching method, or can be formed on the basis of a nanoprinting method.

The size of the planar shape of the light exit direction control member may be changed depending on a light emitting element. For example, when one pixel is constituted by three sub-pixels, the size of the planar shape of the light exit direction control member may be the same value in three sub-pixels constituting one pixel, may be the same value in two sub-pixels except for one sub-pixel, or may be different values among three sub-pixels. In addition, the refractive index of a material constituting the light exit direction control member may be changed depending on a light emitting element. For example, when one pixel is constituted by three sub-pixels, the refractive index of a material constituting the light exit direction control member may be the same value in three sub-pixels constituting one pixel, may be the same value in two sub-pixels except for one sub-pixel, or may be different values among three sub-pixels.

The planar shape of the light exit direction control member is preferably similar to that of the light emitting region, or the light emitting region is preferably included in an orthographic projection image of the light exit direction control member. Note that the present disclosure is not limited thereto, and the orthographic projection image of the optical path control unit can coincide with the orthographic projection image of the wavelength selection unit, or can be included in the orthographic projection image of the wavelength selection unit. By adopting the latter configuration, occurrence of color mixing between adjacent light emitting elements can be reliably suppressed. Note that the orthographic projection image is an orthographic projection image obtained by projection onto the first substrate, and the same applies hereinafter.

A side surface of the light exit direction control member is preferably perpendicular or substantially perpendicular. Specifically, an inclination angle of the side surface of the light exit direction control member can be, for example, 80 degrees to 100 degrees, preferably 81.8 degrees or more and 98.2 degrees or less, more preferably 84.0 degrees or more and 96.0 degrees or less, still more preferably 86.0 degrees or more and 94.0 degrees or less, particularly preferably 88.0 degrees or more and 92.0 degrees or less, and most preferably 90 degrees.

An average height of the light exit direction control member can be, for example, 1.5 μm or more and 2.5 μm or less, and this can effectively enhance a light condensing effect in the vicinity of the outer edge portion of the light exit direction control member. The height of the light exit direction control member may be changed depending on a light emitting element. For example, when one pixel is constituted by three sub-pixels, the height of the light exit direction control member may be the same value in three sub-pixels constituting one pixel, may be the same value in two sub-pixels except for one sub-pixel, or may be different values among three sub-pixels.

A distance between the centers of adjacent light exit direction control members is preferably 1 μm or more and 10 μm or less, but is not limited thereto. By setting the distance to 10 μm or less, a wave property of light is remarkably exhibited. Therefore, a high light condensing effect can be imparted to the light exit direction control member.

A maximum distance (maximum distance in a height direction) from a light emitting region to a bottom surface of the light exit direction control member is desirably more than 0.35 μm and 7 μm or less, preferably 1.3 μm or more and 7 μm or less, more preferably 2.8 μm or more and 7 μm or less, and still more preferably 3.8 μm or more and 7 μm or less. By defining that the maximum distance from the light emitting region to the light exit direction control member is more than 0.35 μm, a light condensing effect in the vicinity of the outer edge portion of the light exit direction control member can be effectively enhanced. Meanwhile, by defining that the maximum distance from the light emitting region to the light exit direction control member is 7 μm or less, it is possible to suppress deterioration of viewing angle characteristics.

The number of light exit direction control members for one pixel is essentially arbitrary, and only needs to be one or more. For example, when one pixel is constituted by a plurality of sub-pixels, one light exit direction control member may be disposed corresponding to one sub-pixel, one light exit direction control member may be disposed corresponding to a plurality of sub-pixels, or a plurality of light exit direction control members may be disposed corresponding to one sub-pixel. When p×q light exit direction control members are disposed corresponding to one sub-pixel, examples of values of p and q include 10 or less, 5 or less, and 3 or less.

Alternatively, the optical path control unit may be constituted by a light reflecting member. Examples of the light reflecting member include a simple substance or an alloy of a metal such as aluminum (Al) or silver (Ag), and a dielectric multilayer film. In the light emitting element or the like of the present disclosure, examples of a material constituting the light reflecting member include a material having a refractive index such that light from the light emitting region is totally reflected by the light reflecting member when the light collides with the light reflecting member. Specifically, the light reflecting member can fill a space between the flattening layer and the flattening layer, for example. The light reflecting member preferably has a forward tapered shape (a shape expanding from a light incident surface side toward a light exit surface side). A cross-section of the forward tapered inclined surface when the light reflecting member is cut along a virtual plane (vertical virtual plane) including an axis of the light reflecting member may be formed of a curve or a line segment.

The orthographic projection image of the optical path control unit can coincide with the orthographic projection image of the wavelength selection unit, or can be included in the orthographic projection image of the wavelength selection unit. By adopting the latter configuration, occurrence of color mixing between adjacent light emitting elements can be reliably suppressed.

FIG. 22 illustrates a schematic partial cross-sectional view of the light emitting element and the display device of Example 5.

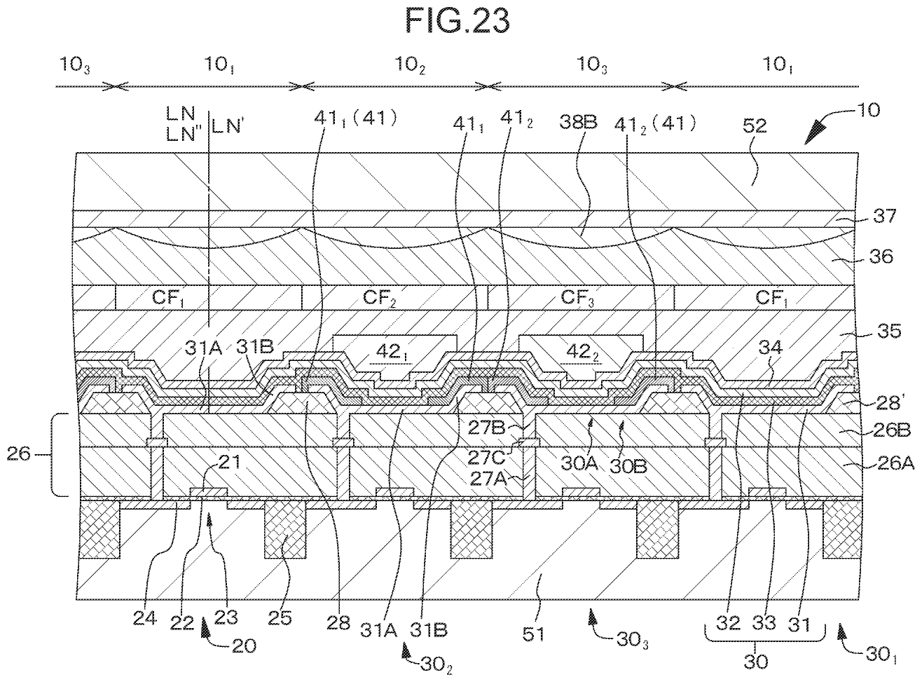

In the light emitting element and the display device of Example 5, a second flattening layer 37 is formed on the wavelength selection unit CF₁, CF₂, CF₃, and the optical path control unit, specifically, for example, a lens member (on-chip microlens) 38A is formed on the second flattening layer 37. The lens member 38A is, for example, convex in a direction away (along) from the light emitting region 30, and specifically constituted by a plano-convex lens. Alternatively, as illustrated in FIG. 23 illustrating a schematic partial cross-sectional view of Modification-1 of the light emitting element and the display device of Example 5, the lens member 38B is concave in a direction away (along) from the light emitting region 30, and specifically constituted by a plano-concave lens. The second flattening layer 37 is formed between the lens member 38B and the second substrate 52. The lens member 38B and the color filter layer CF are bonded to each other via, for example, the sealing resin layer 36. Examples of a material constituting the lens members 38A and 38B include an acrylic transparent resin.

In these cases, light emitted from the light emitting region passes through the lens member 38A, 38B, further passes through the sealing resin layer 36, the second flattening layer 37, and the second substrate 52, and is emitted to the outside. Light (image) emitted from the entire display device is, for example, a converged type. However, the degree of the converged type depends on specifications of the display device, and also depends on how much viewing angle dependency and wide viewing angle characteristics are required for the display device. In some cases, a form can be adopted in which a light emitting element having a lens member that is convex in a direction away from the light emitting region and a light emitting element having a lens member that is concave in a direction away from the light emitting region are mixed.

In the illustrated Example, one lens member is disposed for one light emitting region, but one lens member may be shared by a plurality of light emitting elements in some cases. For example, a light emitting element may be disposed at each vertex of an equilateral triangle (a total of three light emitting elements are disposed), and one lens member may be shared by these three light emitting elements, or a light emitting element may be disposed at each vertex of a rectangle (a total of four light emitting elements are disposed), and one lens member may be shared by these four light emitting elements. Alternatively, a plurality of lens members may be disposed for one light emitting region.

The lens member 38A can be manufactured, for example, by the following method. That is, a lens member forming layer for forming the lens member 38A is formed on the second flattening layer 37, and a resist material layer is formed thereon. Then, the resist material layer is patterned and further subjected to heat treatment to form the resist material layer into a lens member shape. Next, the resist material layer and the lens member forming layer are etched back to transfer the shape formed in the resist material layer to the lens member forming layer. In this way, the lens member 38A can be obtained.

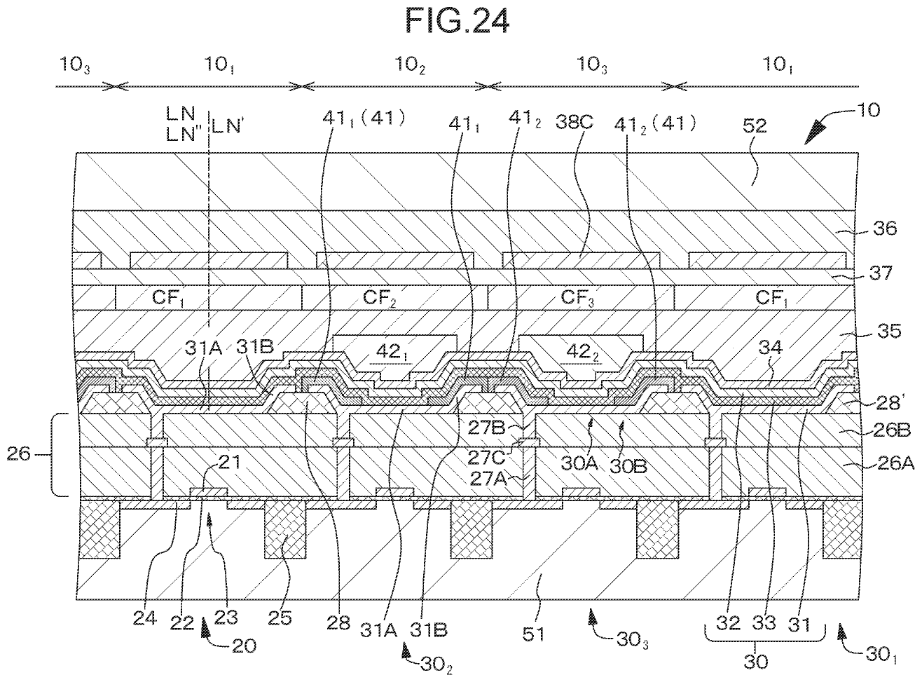

Alternatively, as illustrated in FIG. 24 illustrating a schematic partial cross-sectional view of Modification-2 of the display device of Example 5, a light exit direction control member 38C as an optical path control unit is disposed above the light emitting region 30, specifically, above the color filter layer CF via the second flattening layer 37. The color filter layer CF and the light exit direction control member 38C are covered with the flattening layer 35, and the flattening layer 35 and the second substrate 52 are bonded to each other via, for example, the sealing resin layer 36. A cross-sectional shape of the light exit direction control member 38C when the light exit direction control member is cut along a virtual plane (perpendicular virtual plane) including a thickness direction of the light exit direction control member 38C is rectangular. A three-dimensional shape of the light exit direction control member 38C is, for example, a columnar shape or a quadrangular shape. When a refractive index of a material constituting the light exit direction control member 38C is represented by n_{R} and a refractive index of a material constituting the sealing resin layer 36 is represented by n_{M} (<n_{R}), since the light exit direction control member 38C is surrounded by the sealing resin layer 36, the light exit direction control member 38C has a function as a kind of lens, and furthermore, can effectively enhance a light condensing effect in the vicinity of an outer edge portion of the light exit direction control member 38C. In addition, since the light exit direction control member 38C has a flat plate shape, the light exit direction control member is easily formed, and a manufacturing process can be simplified. The light exit direction control member 38C may be surrounded by a material different from the material constituting the flattening layer 35 as long as the material satisfies the refractive index condition (n_{M}<n_{R}). Alternatively, the light exit direction control member 38C may be surrounded by, for example, an air layer or a decompression layer (vacuum layer).

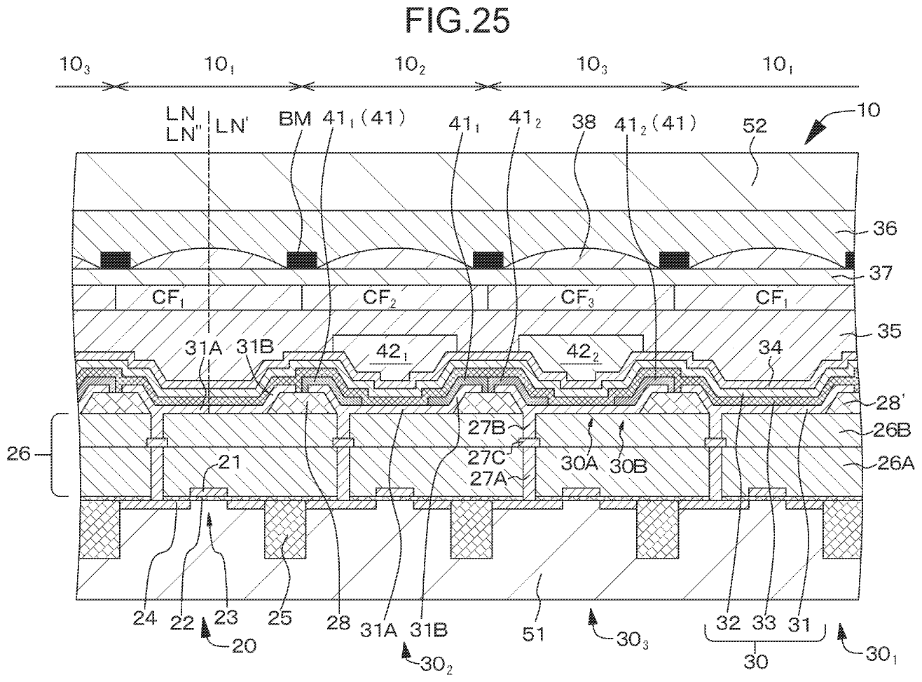

As illustrated in FIG. 25 illustrating a schematic partial cross-sectional view of Modification-3 of the display device of Example 5, a light absorption layer (black matrix layer) BM can be formed between the optical path control units 38C of adjacent light emitting elements. This can reliably suppress occurrence of color mixing between adjacent light emitting elements.

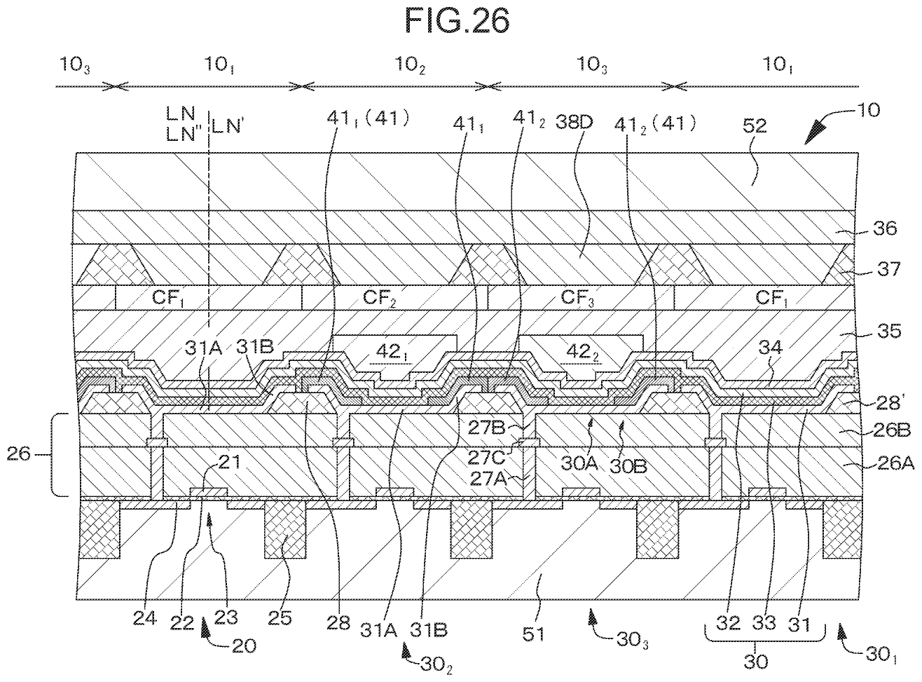

As illustrated in FIG. 26 illustrating a schematic partial cross-sectional view of Modification-4 of Example 5, the optical path control unit can be constituted by a light reflecting member 38D. Examples of the light reflecting member 38D include a simple substance or an alloy of a metal such as aluminum (Al) or silver (Ag), and a dielectric multilayer film. Alternatively, examples of the light reflecting member 38D include a material having a refractive index n_{M}′ (for example, SiO₂ in which n_{M}′=1.52) such that light from the light emitting region 30 is totally reflected by the light reflecting member 38D when the light collides with the light reflecting member 38D. Specifically, the light reflecting member 38D constituting the optical path control unit fills a space between the second flattening layer 37 and the second flattening layer 37. The light reflecting member 38D has a forward tapered shape (a shape expanding from a light incident surface side toward a light exit surface side). A cross-section of the forward tapered inclined surface when the light reflecting member 38D is cut along a virtual plane (vertical virtual plane) including an axis of the light reflecting member 38D may be formed of a curve, or may be formed of a line segment as illustrated in FIG. 26.

### Example 6

Example 6 is a modification of Examples 1 to 5. In Example 6, a relationship among a normal line LN passing through the center of the light emitting region, a normal line LN′ passing through the center of the optical path control unit, and a normal line LN″ passing through the center of the wavelength selection unit (color filter layer CF), and a modification thereof will be described. Here, the various normal lines are perpendicular lines to a light exit surface of the display device.

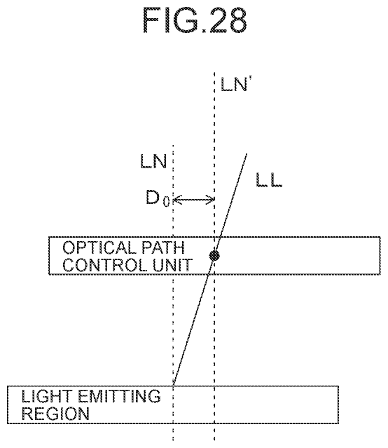

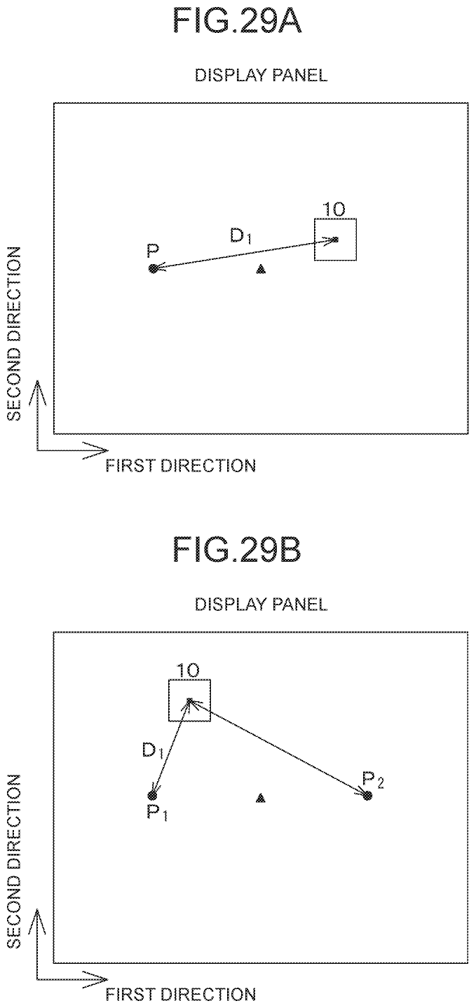

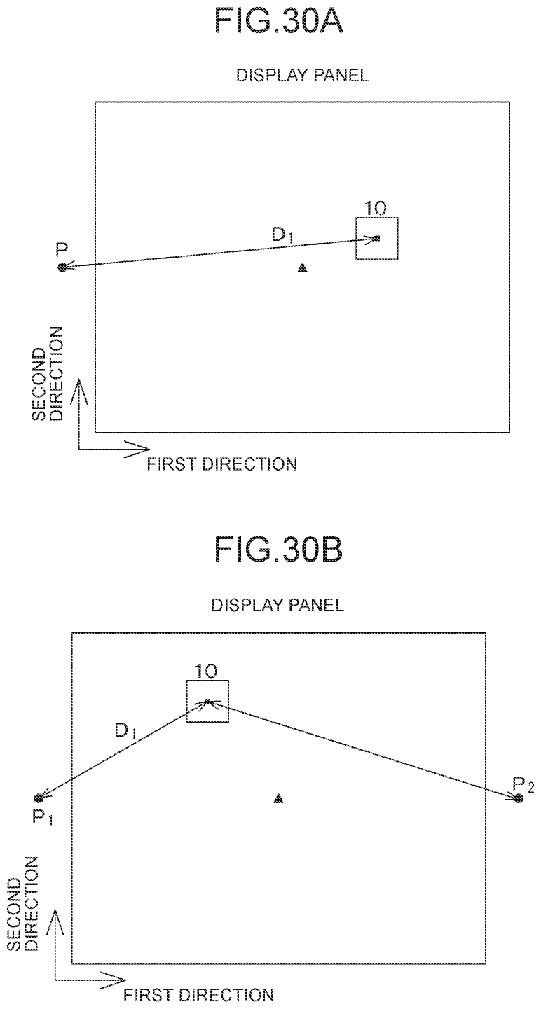

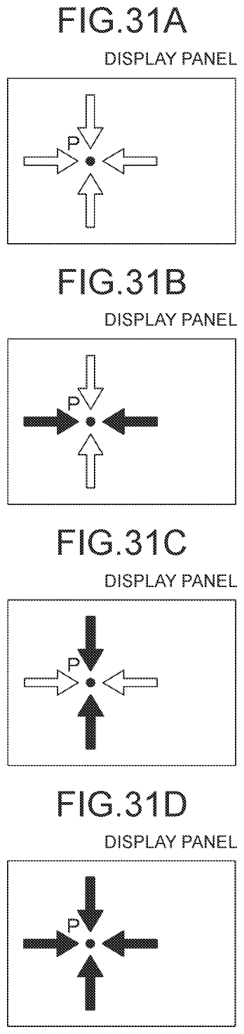

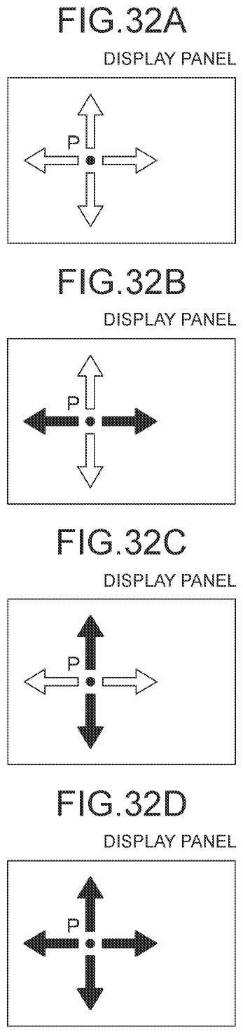

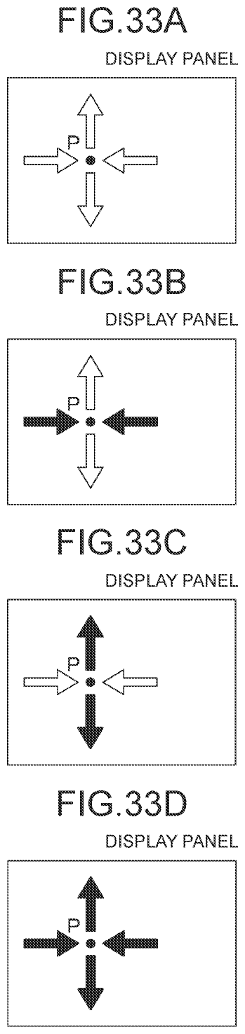

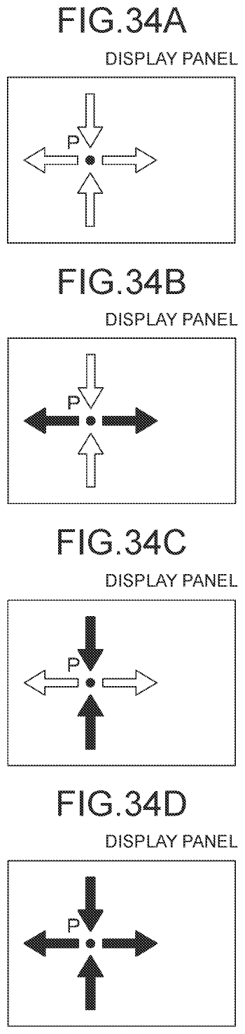

FIG. 28 illustrates a conceptual diagram of a distance (offset amount) D₀ between a normal line LN passing through the center of the light emitting region 30 and a normal line LN′ passing through the center of the optical path control unit in the display device of Example 6. FIGS. 29A, 29B, 30A, and 30B each illustrate a schematic diagram illustrating a positional relationship between the light emitting element and the reference point in the display device of Example 6, and FIGS. 31A, 31B, 31C, 31D, 32A, 32B, 32C, 32D, 33A, 33B, 33C, 33D, 34A, 34B, 34C, and 34D each schematically illustrate a change in D_{0-X} with respect to a change in D_{1-X} and a change in D_{0-Y} with respect to a change in D_{1-Y}.

Specifically, a relationship among the normal line LN, the normal line LN′, and the normal line LN″ may be as follows. That is, in a light emitting element in which a value of a distance (offset amount) D₀ between a normal line passing through the center of the light emitting region 30 and a normal line passing through the center of the optical path control unit is zero,

[A] a form in which LN, LN′, and LN″ coincide with each other

can be mentioned. In addition, in a light emitting element in which the value of the offset amount D₀ is not zero,

[B] a form in which LN and LN′ coincide with each other but do not coincide with LN″,

[C] a form in which LN and LN″ coincide with each other but do not coincide with LN′

[D] a form in which LN′ and LN″ coincide with each other but do not coincide with LN,

[E] a form in which LN, LN′, and LN″ do not coincide with each other

can be mentioned. By adopting these forms, occurrence of color mixing between adjacent light emitting elements can be reliably suppressed.

As illustrated in the conceptual diagram of FIG. 28, in the display device of Example 6, when a distance (offset amount) between the normal line LN passing through the center of the light emitting region 30 and the normal line LN′ passing through the center of the optical path control unit is represented by D₀, a form can be adopted in which a value of the distance (offset amount) D₀ is not zero in at least some of the light emitting elements 10 constituting the display device. A straight line LL is a straight line connecting the center of the light emitting region 30 and the center of the optical path control unit. In the following description, an example in which the optical path control unit is constituted by the lens member 38A will be described.

In a display panel (region in which an image is displayed) constituting the display device of Example 6, a reference point (reference region) P is assumed, and the offset amount D₀ depends on a distance D₁ from the reference point (reference region) P to the normal line LN passing through the center of the light emitting region 30. The distance D₀ may be changed among the plurality of light emitting elements (sub-pixels) constituting one pixel. That is, for example, in a case where one pixel is constituted by three sub-pixels, a value of Do may be the same value in the three sub-pixels constituting one pixel, may be the same value in two sub-pixels except for one sub-pixel, or may be different values among the three sub-pixels. Note that the reference point (reference region) can include a certain extent of spread.

A configuration can be adopted in which the reference point P is assumed to be in the display panel constituting the display device. In this case, a configuration can be adopted in which the reference point P is not located in the center region of the display panel, or a configuration can be adopted in which the reference point P is located in the center region of the display panel. Furthermore, in these cases, a configuration can be adopted in which one reference point P is assumed, or a configuration can be adopted in which a plurality of reference points P is assumed. In these cases, a configuration can be adopted in which values of the distance D₀ are zero in some of the light emitting elements (for example, see FIG. 22) and values of the distance D₀ are not zero in the remaining light emitting elements.

Alternatively, in a case where one reference point P is assumed, a configuration can be adopted in which the reference point P is not included in the center region of the display panel, or a configuration can be adopted in which the reference point P is included in the center region of the display panel. In a case where a plurality of reference points P is assumed, a configuration can be adopted in which at least one reference point P is not included in the center region of the display panel.

Alternatively, a configuration can be adopted in which the reference point P is assumed outside the display panel. In this case, a configuration can be adopted in which one reference point P is assumed, or a configuration can be adopted in which a plurality of reference points P is assumed. In these cases, a configuration can be adopted in which values of the distance D₀ are not zero in all the light emitting elements.

Furthermore, light beams that have been emitted from the light emitting elements and have passed through the lens member 38A can be converged (condensed) on a certain region in a space outside the display device. Alternatively, the light beams that have been emitted from the light emitting elements and have passed through the lens member 38A can diverge in the space outside the display device. Alternatively, the light beams that have been emitted from the light emitting elements and have passed through the lens member 38A can be parallel light beams.

Furthermore, in the display device of Example 6, a form can be adopted in which a value of the distance (offset amount) D₀ is different depending on a position where the light emitting element occupies the display panel. Specifically,

a form can be adopted in which

the reference point P is set,

the plurality of light emitting elements is arranged in a first direction and a second direction different from the first direction, and

when a distance from the reference point P to the normal line LN passing through the center of the light emitting region 30 is represented by D₁, values of the distance D₀ in the first direction and the second direction are represented by D_{0-X} and D_{0-Y}, respectively, and values of the distance D₁ in the first direction and the second direction are represented by D_{1-X} and D_{1-Y}, respectively,

D_{0-X} changes linearly with respect to a change in D_{1-X} and D_{0-Y} changes linearly with respect to a change in D_{1-Y},

D_{0-X} changes linearly with respect to a change in D_{1-X} and D_{0-Y} changes nonlinearly with respect to a change in D_{1-Y},

D_{0-X} changes nonlinearly with respect to a change in D_{1-X} and D_{0-Y} changes linearly with respect to a change in D_{1-Y}, or

D_{0-X} changes nonlinearly with respect to a change in D_{1-X} and D_{0-Y} changes nonlinearly with respect to a change in D_{1-Y}.

Alternatively, a form can be adopted in which a value of the distance D₀ increases as a value of the distance D₁ increases. That is, in the display device of Example 6,

a form can be adopted in which

the reference point P is set, and

when a distance from the reference point P to the normal line LN passing through the center of the light emitting region 30 is represented by D₁, a value of the distance D₀ increases as a value of the distance D₁ increases.

Here, the phrase that D_{0-X} changes linearly with respect to a change in D_{1-X} and D_{0-Y} changes linearly with respect to a change in D_{1-Y} means that

D_{0-X}=k_{X}·D_{1-X} and

D_{0-Y}=k_{Y}·D_{1-Y}

are satisfied. Note that k_{X} and k_{Y} are constants. That is, D_{0-X} and D_{0-Y} each change on the basis of a linear function. Meanwhile, the phrase that D_{0-X} changes nonlinearly with respect to a change in D_{1-X} and D_{0-Y} changes linearly with respect to a change in D_{1-Y} means that

D_{0-X}=f_{X}(D_{1-X}) and

D_{0-Y}=f_{Y}(D_{1-Y})

are satisfied. Here, f_{X} and f_{Y} are each a function that is not a linear function (for example, a quadratic function).

Alternatively, the change in D_{0-X} with respect to the change in D_{1-X} and the change in D_{0-Z} with respect to the change in D_{1-Y} can also be stepwise changes. In this case, when the stepwise change is diagramed as a whole, a form can be adopted in which the change is a linear change, or a form can be adopted in which the change is a nonlinear change. Furthermore, when the display panel is divided into M×N regions, in one region, the change in D_{0-X} with respect to the change in D_{1-X} and the change in D_{0-Y} with respect to the change in D_{1-Y} may be unchanged or constant changes. The number of light emitting elements in one region may be, for example, 10×10, but is not limited thereto.

Furthermore, in the display device of Example 6, the orthographic projection image of the lens member can coincide with the orthographic projection image of the wavelength selection unit, or can be included in the orthographic projection image of the wavelength selection unit. By adopting the latter configuration, occurrence of color mixing between adjacent light emitting elements can be reliably suppressed.

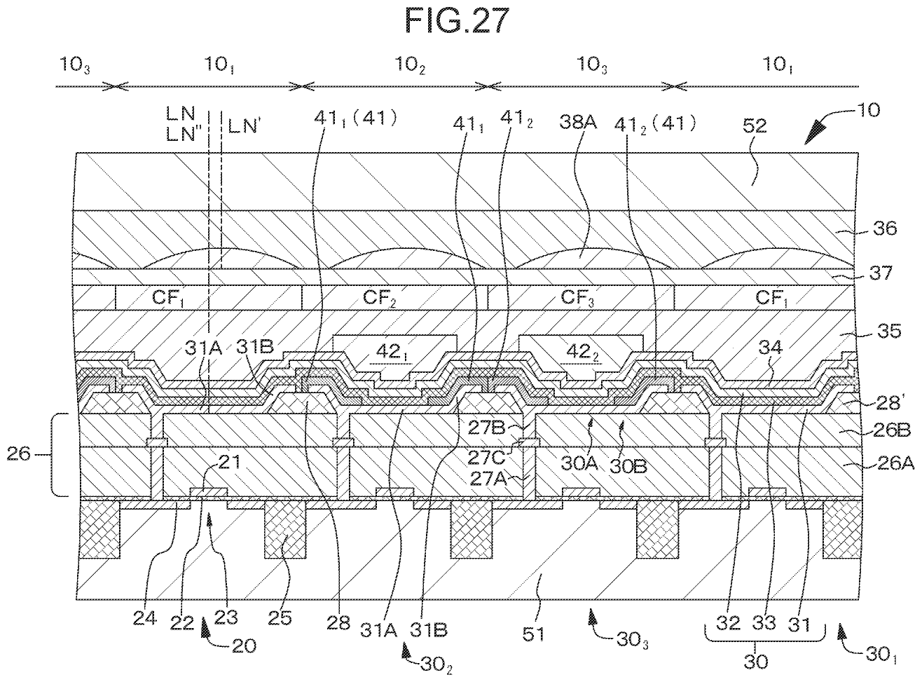

FIG. 27 illustrates a schematic partial cross-sectional view of the display device of Example 6.

In Example 6, when a distance (offset amount) between the normal line LN passing through the center of the light emitting region 30 and the normal line LN′ passing through the center of the lens member 38A is represented by D₀, a value of the distance (offset amount) D₀ is not zero in at least some of the light emitting elements 10 included in the display panel constituting the display device. In the display device, a reference point (reference region) is assumed, and the distance D₀ depends on a distance D₁ from the reference point (reference region) to the normal line LN passing through the center of the light emitting region 30.

In the display device of Example 6 whose conceptual diagram is illustrated in FIGS. 29A and 29B, the reference point P is assumed to be in the display panel. Note that the reference point P is not located (not included) in a center region of the display panel. That is, an orthographic projection image of the reference point P is included in an image display region (display panel) of the display device, but the reference point P is not located in the center region of the display device (display region of display device, display panel). In FIGS. 29A, 29B, 30A, and 30B, the center region of the display panel is indicated by a black triangle, the light emitting element 10 is indicated by a square, the center of the light emitting region 30 is indicated by a black square, and the reference point P is indicated by a black circle. A positional relationship between the light emitting element 10 and the reference point P is schematically illustrated in FIG. 29A, and one reference point P is assumed. Since the reference point P can include a certain extent of spread, values of the distance D₀ are zero in some of the light emitting elements 10 (specifically, one or more light emitting elements 10 included in the orthographic projection image of the reference point P), and values of the distance D₀ are not zero in the remaining light emitting elements 10. A value of the distance (offset amount) D₀ varies depending on a position occupied by the light emitting element in the display panel.

In the display device of Example 6, light beams that have been emitted from the light emitting elements 10 and have passed through the lens member 38A are converged (condensed) on a certain region of a space outside the display device. Alternatively, the light beams that have been emitted from the light emitting elements 10 and have passed through the lens member 38A diverge in a space outside the display device. Alternatively, the light beams that have been emitted from the light emitting elements 10 and have passed through the lens member 38A are parallel light beams. Whether the light beams that have passed through the lens member 38A are formed into converged light beams, divergent light beams, or parallel light beams depends on specifications required for the display device, and also depends on how much viewing angle dependency and wide viewing angle characteristics are required for the display device. Power or the like of the lens member 38A only needs to be designed on the basis of the specifications. In a case where the light beams that have passed through the lens member 38A are converged light beams, the position of a space in which an image emitted from the display device is formed may be on a normal line of the reference point P or is not on the normal line of the reference point P in some cases, and depends on specifications required for the display device. An optical system through which an image emitted from the display device passes may be disposed in order to control a display dimension, a display position, and the like of the image emitted from the display device. Which optical system is disposed depends on specifications required for the display device, and examples thereof include an imaging lens system.

In the display device of Example 6, the reference point P is set, and the plurality of light emitting elements 10 is arranged in the first direction and the second direction different from the first direction. When a distance from the reference point P to the normal line LN passing through the center of the light emitting region 30 is represented by D₁, values of the distance D₀ in the first direction and the second direction are represented by D_{0-X} and D_{0-Y}, respectively, and values of the distance D₁ in the first direction and the second direction are represented by D_{1-X} and D_{1-Y}, respectively,

[A] a design may be made such that D_{0-X} changes linearly with respect to a change in D_{1-X} and D_{0-Y} changes linearly with respect to a change in D_{1-Y},

[B] a design may be made such that D_{0-X} changes linearly with respect to a change in D_{1-Z} and D_{0-Y} changes nonlinearly with respect to a change in D_{1-Y},

[C] a design may be made such that D_{0-X} changes nonlinearly with respect to a change in D_{1-X} and D_{0-Y} changes linearly with respect to a change in D_{1-Y}, or

[D] a design may be made such that D_{0-X} changes nonlinearly with respect to a change in D_{1-X} and D_{0-Y} changes nonlinearly with respect to a change in D_{1-Y}.

FIGS. 31A, 31B, 31C, 31D, 32A, 32B, 32C, 32D, 33A, 33B, 33C, 33D, 34A, 34B, 34C, and 34D schematically illustrate a change in D_{0-X} with respect to a change in D_{1-X} and a change in D_{0-Y} with respect to a change in D_{1-Y}. In these drawings, an outlined arrow indicates a linear change, and a black arrow indicates a nonlinear change. An arrow directed to the outside of the display panel indicates that the light beams that have passed through the lens member 38A are divergent light beams, and an arrow directed to the inside of the display panel indicates that the light beams that have passed through the lens member 38A are converged light beams or parallel light beams.

Alternatively, a design may be made such that the reference point P is set, and when a distance from the reference point P to the normal line LN passing through the center of the light emitting region 30 is represented by D₁, a value of the distance D₀ increases as a value of the distance D₁ increases.

That is, the changes in D_{0-X} and D_{0-Y} depending on the changes in D_{1-X} and D_{1-Y} only need to be determined on the basis of specifications required for the display device.

In the display device of Example 6, a plurality of reference points P can be assumed. Note that the plurality of reference points P is arranged in the display region of the display panel. A positional relationship between the light emitting element 10 and the reference points P₁ and P₂ is schematically illustrated in FIG. 29B, and the two reference points P₁ and P₂ are assumed in the illustrated example. Specifically, with the center of the display panel as a symmetry point, the two reference points P₁ and P₂ are arranged in two-fold rotational symmetry. Here, at least one reference point P is not included in the center region of the display panel. In the illustrated example, the two reference points P₁ and P₂ are not included in the center region of the display panel. Values of the distance D₀ are zero in some of the light emitting elements (specifically, one or more light emitting elements included in the reference point P), and values of the distance D₀ are not zero in the remaining light emitting elements. Regarding the distance D₁ from the reference point P to the normal line LN passing through the center of the light emitting region 30, a distance from the normal line LN passing through the center of a certain light emitting region 30 to a reference point P closer to the normal line LN is defined as the distance D₁.

In a display device of a modification of Example 6, the reference point P is assumed to be outside the display panel. FIGS. 30A and 30B schematically illustrate a positional relationship between the light emitting element 10 and the reference points P, P₁, and P₂. A configuration can be adopted in which one reference point P is assumed (see FIG. 30A), or a configuration can be adopted in which a plurality of reference points P (FIG. 30B illustrates two reference points P₁ and P₂) is assumed. With the center of the display panel as a symmetry point, the two reference points P₁ and P₂ are arranged in two-fold rotational symmetry. Here, at least one reference point P is not included in the center region of the display panel. In the illustrated example, the two reference points P₁ and P₂ are not included in the center region of the display panel. Values of the distance D₀ are zero in some of the light emitting elements (specifically, one or more light emitting elements included in the reference point P), and values of the distance D₀ are not zero in the remaining light emitting elements. Regarding the distance D₁ from the reference point P to the normal line LN passing through the center of the light emitting region 30, a distance from the normal line LN passing through the center of a certain light emitting region 30 to a reference point P closer to the normal line LN is defined as the distance D₁. Alternatively, values of the distance D₀ are not zero in all the light emitting elements. Regarding the distance D₁ from the reference point P to the normal line LN passing through the center of the light emitting region 30, a distance from the normal line LN passing through the center of a certain light emitting region 30 to a reference point P closer to the normal line LN is defined as the distance D₁. Regarding the distance D₁ from the reference point P to the normal line LN passing through the center of the light emitting region 30, a distance from the normal line LN passing through the center of a certain light emitting region 30 to a reference point P closer to the normal line LN is defined as the distance D₁. In these cases, light beams that have been emitted from the light emitting elements 10 and have passed through the lens member 38A are converged (condensed) on a certain region of a space outside the display device. Alternatively, the light beams that have been emitted from the light emitting elements 10 and have passed through the lens member 38A diverge in a space outside the display device.

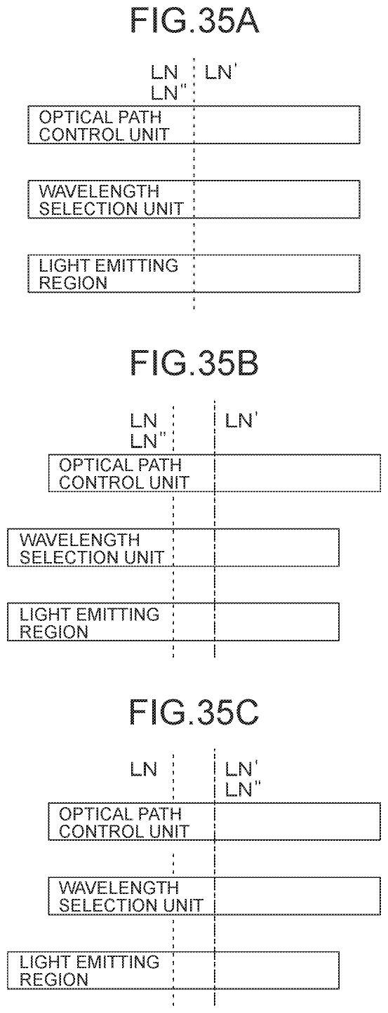

As illustrated in the conceptual diagram of FIG. 35A, the normal line LN passing through the center of the light emitting region 30, the normal line LN″ passing through the center of the wavelength selection unit, and the normal line LN′ passing through the center of the lens member 38A may coincide with each other. That is, D₀=d₀=0 is satisfied (see, for example, FIGS. 1 and 22). Note that, as described above, do represents a distance (offset amount) between the normal line LN passing through the center of the light emitting region 30 and the normal line LN″ passing through the center of the wavelength selection unit.

In the example illustrated in FIG. 27, as illustrated in the conceptual diagram of FIG. 35B, the normal line LN passing through the center of the light emitting region 30 coincides with the normal line LN″ passing through the center of the wavelength selection unit, but the normal line LN passing through the center of the light emitting region 30 or the normal line LN″ passing through the center of the wavelength selection unit does not coincide with the normal line LN′ passing through the center of the lens member 38A. That is, D₀≠d₀=0 is satisfied.

Furthermore, as illustrated in the conceptual diagram of FIG. 35C, in some cases, the normal line LN passing through the center of the light emitting region 30 does not coincide with the normal line LN″ passing through the center of the wavelength selection unit or the normal line LN′ passing through the center of the lens member 38A, and the normal line LN″ passing through the center of the wavelength selection unit coincides with the normal line LN′ passing through the center of the lens member 38A. That is, D₀=d₀>0 is satisfied.

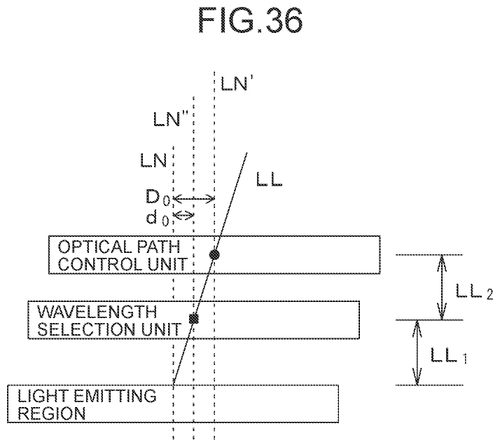

In addition, as illustrated in the conceptual diagram of FIG. 36, in some cases, the normal line LN passing through the center of the light emitting region 30 does not coincide with the normal line LN″ passing through the center of the wavelength selection unit or the normal line LN′ passing through the center of the lens member 38A, and the normal line LN′ passing through the center of the lens member 38A does not coincide with the normal line LN passing through the center of the light emitting region 30 or the normal line LN″ passing through the center of the wavelength selection unit. Here, the center of the wavelength selection unit (indicated by a black square in FIG. 36) is preferably located on a straight line LL connecting the center of the light emitting region 30 and the center of the lens member 38A (indicated by a black circle in FIG. 36). Specifically, when a distance from the center of the light emitting region 30 to the center of the wavelength selection unit in the thickness direction is represented by LL₁, and a distance from the center of the wavelength selection unit to the center of the lens member 38A in the thickness direction is represented by LL₂,

D₀>d₀>0 is satisfied, and

considering manufacturing variation,

d₀:D₀=LL₁:(LL₁+LL₂)

is preferably satisfied.

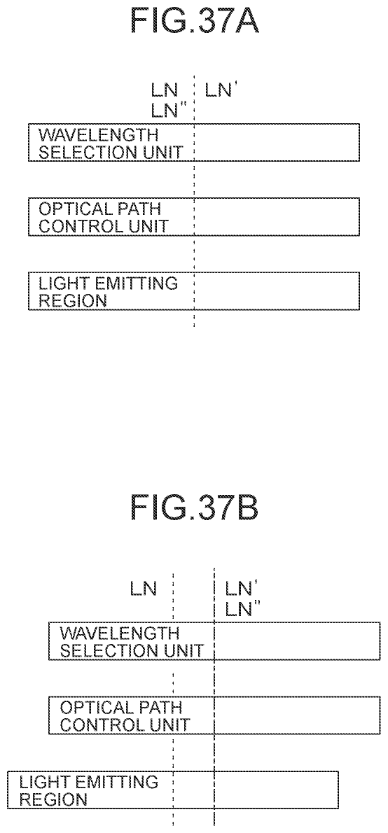

Alternatively, as illustrated in the conceptual diagram of FIG. 37A, the normal line LN passing through the center of the light emitting region 30, the normal line LN″ passing through the center of the wavelength selection unit, and the normal line LN′ passing through the center of the lens member 38A may coincide with each other. That is, D₀=d₀=0 is satisfied.

In addition, as illustrated in the conceptual diagram of FIG. 37B, in some cases, the normal line LN passing through the center of the light emitting region 30 does not coincide with the normal line LN″ passing through the center of the wavelength selection unit or the normal line LN′ passing through the center of the lens member 38A, and the normal line LN″ passing through the center of the wavelength selection unit coincides with the normal line LN′ passing through the center of the lens member 38A. That is, D₀=d₀>0 is satisfied.

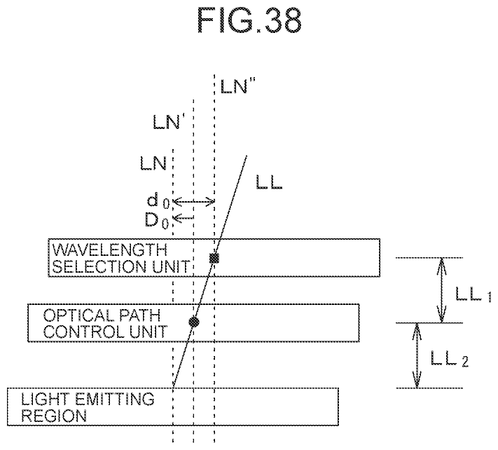

Furthermore, as illustrated in the conceptual diagram of FIG. 38, in some cases, the normal line LN passing through the center of the light emitting region 30 does not coincide with the normal line LN″ passing through the center of the wavelength selection unit or the normal line LN′ passing through the center of the lens member 38A, and the normal line LN′ passing through the center of the lens member 38A does not coincide with the normal line LN passing through the center of the light emitting region 30 or the normal line LN″ passing through the center of the wavelength selection unit. Here, the center of the wavelength selection unit is preferably located on a straight line LL connecting the center of the light emitting region 30 and the center of the lens member 38A. Specifically, when a distance from the center of the light emitting region 30 to the center of the wavelength selection unit (indicated by a black square in FIG. 38) in the thickness direction is represented by LL₁, and a distance from the center of the wavelength selection unit to the center of the lens member 38A (indicated by a black circle in FIG. 38) in the thickness direction is represented by LL₂,

d₀>D₀>0 is satisfied, and

considering manufacturing variation,

D₀:d₀=LL₂:(LL₁+LL₂)

is preferably satisfied.

In the display device of Example 6, when a distance between the normal line LN passing through the center of the light emitting region and the normal line LN′ passing through the center of the optical path control unit is represented by D₀, a value of the distance D₀ is not zero in at least some of the light emitting elements constituting the display device. Therefore, a traveling direction of light that has been emitted from the light emitting layer and has passed through the optical path control unit can be reliably and accurately controlled depending on the position of the light emitting element in the display device. That is, it is possible to reliably and accurately control to which region in an external space an image from the display device is emitted in what state. In addition, by disposing the optical path control unit, not only an increase in brightness (luminance) of an image emitted from the display device and prevention of color mixing between adjacent pixels can be achieved, but also light can appropriately diverge depending on a required viewing angle, and a longer lifetime and a higher luminance of each of the light emitting element and the display device can be achieved. Therefore, it is possible to achieve miniaturization, weight reduction, and high quality of the display device. In addition, applications to an eyewear, augmented reality (AR) glasses, and EVR are remarkably expanded.

Although the present disclosure has been described above on the basis of preferable Examples, the present disclosure is not limited to these Examples. The configurations and configurations of structures of the display device (organic EL display device) and the light emitting element (organic EL element) described in Examples are examples and can be appropriately changed, and the methods for manufacturing the light emitting element and the display device are also examples and can be appropriately changed. In Examples, the drive circuit is constituted by a MOSFET, but can be constituted by a TFT. The first electrode and the second electrode may each have a single-layer structure or a multilayer structure. In Examples, the display device that emits light of three colors is constituted, but a display device that emits light of four colors or more can be used, or a display device that emits light of two colors can be used.

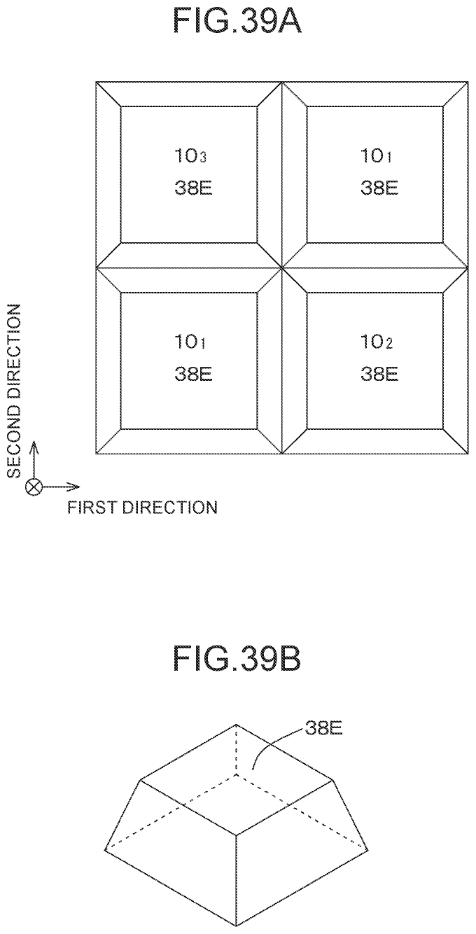

In Examples, the planar shape of the lens member can be a circle, but is not limited thereto, and as illustrated in FIGS. 39A and 39B, a lens member 38E can have a truncated quadrangular pyramid shape. Note that FIG. 39A is a schematic plan view of a lens member having a truncated quadrangular pyramid shape, and FIG. 39B is a schematic perspective view thereof.

In order to prevent light emitted from a certain light emitting unit from entering a light emitting element adjacent to the certain light emitting element to generate optical crosstalk, a light shielding unit may be disposed between the light emitting element and the light emitting element. That is, the light shielding unit may be formed by forming a groove portion between the light emitting element and the light emitting element and embedding the groove portion with a light shielding material. When the light shielding unit is disposed in such a manner, it is possible to reduce a ratio at which light emitted from a certain light emitting element enters an adjacent light emitting element, and it is possible to suppress occurrence of a phenomenon in which color mixing occurs and chromaticity of the entire pixels deviates from desired chromaticity. Then, since color mixing can be prevented, color purity when the pixels emit light in a single color is increased, and a chromaticity point is deepened. Therefore, a color gamut is widened, and a range of color representation of the display device is widened. In addition, the color filter layer is disposed for each pixel in order to improve color purity, and depending on the configuration of the light emitting element, the color filter layer can be thinned or omitted, and light absorbed in the color filter layer can be extracted, resulting in improvement of light emission efficiency. Alternatively, a light shielding property may be imparted to the light absorption layer (black matrix layer).

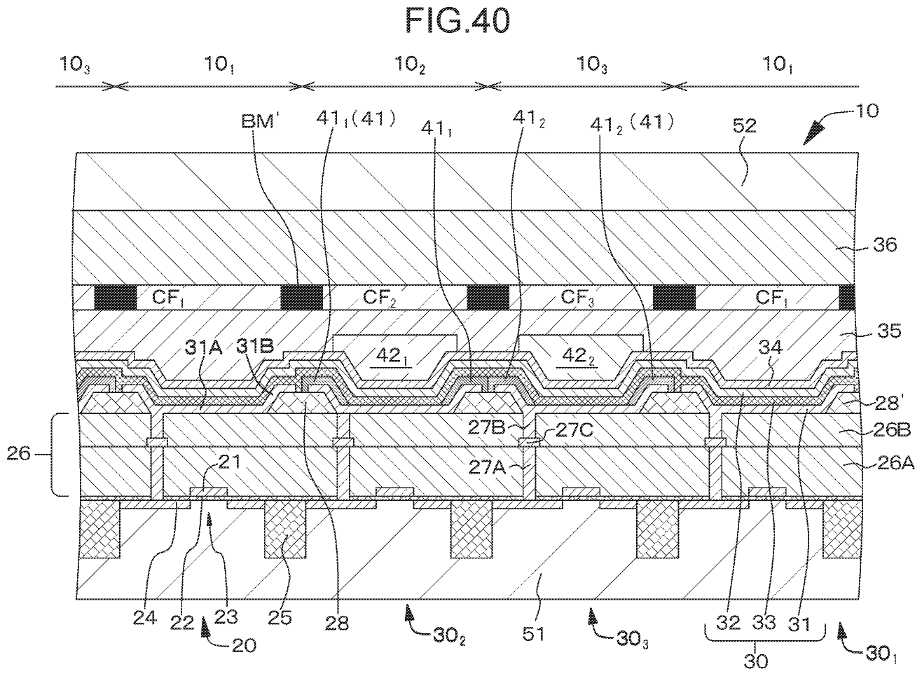

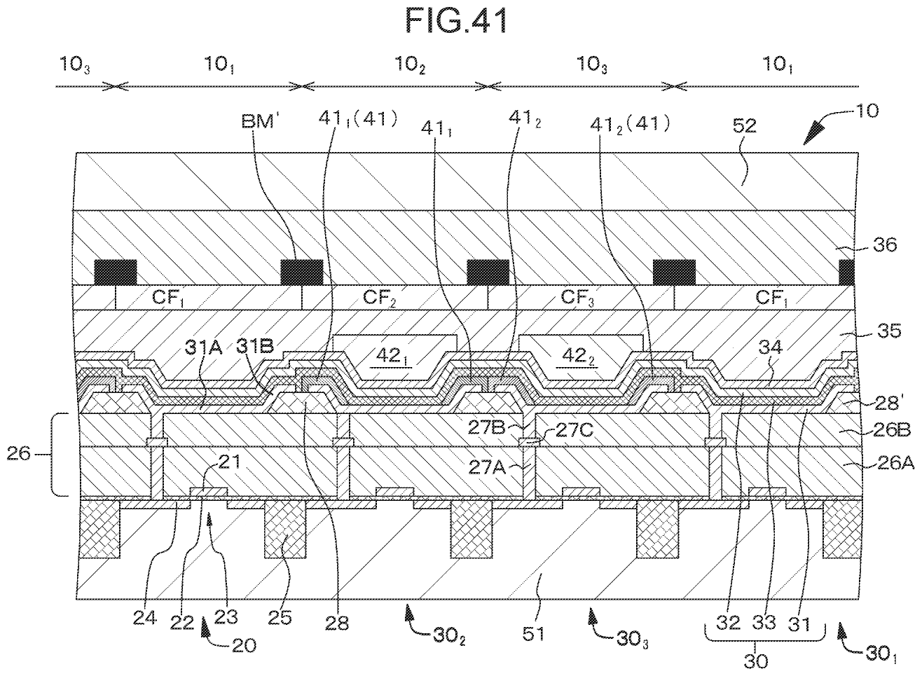

As illustrated in FIG. 40, in the display device of Example 1, a light absorption layer (black matrix layer) BM′ may be formed between the wavelength selection unit and the wavelength selection unit, or as illustrated in FIG. 41, the light absorption layer (black matrix layer) BM′ may be formed above a space between the wavelength selection unit and the wavelength selection unit. The light absorption layer is constituted by, for example, a black resin film (specifically, for example, a black polyimide-based resin) mixed with a black colorant and having an optical density of 1 or more.

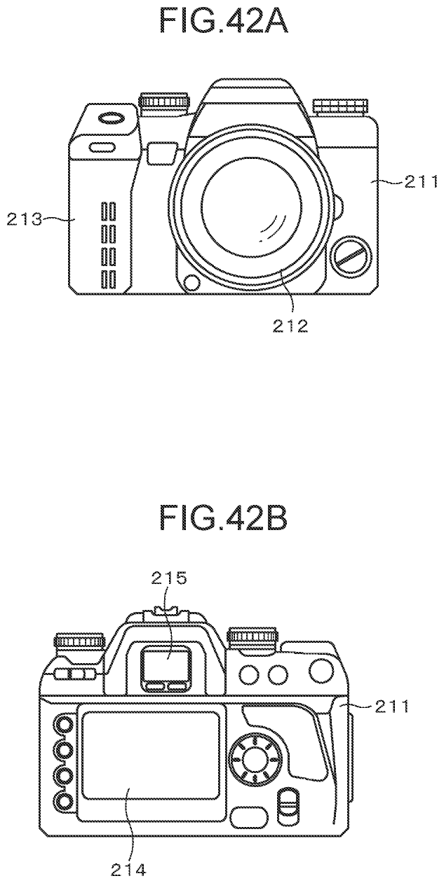

The display device of the present disclosure can be applied to a lens interchangeable mirrorless type digital still camera. A front view of a digital still camera is illustrated in FIG. 42A, and a rear view thereof is illustrated in FIG. 42B. This lens interchangeable mirrorless type digital still camera includes, for example, an interchangeable imaging lens unit (interchangeable lens) 212 on a front right side of a camera body 211, and a grip 213 to be held by a photographer on a front left side. A monitor device 214 is disposed substantially at the center of a rear surface of the camera body 211. An electronic viewfinder (eyepiece window) 215 is disposed above the monitor device 214. By looking into the electronic view finder 215, a photographer can visually recognize an optical image of a subject guided from the imaging lens unit 212 and determine a composition. In the lens interchangeable mirrorless type digital still camera having such a configuration, the display device of the present disclosure can be used as the electronic view finder 215.

Ultraviolet light may be generated in the organic layer 33 constituting the light emitting element 10. In this case, the first light emitting element in the display device of the present disclosure includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-A wavelength conversion layer that is formed between the second portion of the first electrode and a portion of the organic layer formed above the protrusion and converts ultraviolet light (wavelength: λ₀) emitted from the organic layer into first light having a wavelength λ₁ (λ₁>λ₀); and

a second-A wavelength conversion layer that is formed on or above the second electrode and converts ultraviolet light emitted from the organic layer into the first light,

the second light emitting element includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-B wavelength conversion layer that is formed between the second portion of the first electrode and a portion of the organic layer formed above the protrusion, and converts ultraviolet light emitted from the organic layer into second light having a wavelength λ₂ (λ₂>λ₁); and

a second-B wavelength conversion layer that is formed on or above the second electrode and converts ultraviolet light emitted from the organic layer into the second light, and

the third light emitting element includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-C wavelength conversion layer that is formed between the second portion of the first electrode and a portion of the organic layer formed above the protrusion, and converts ultraviolet light emitted from the organic layer into third light having a wavelength λ₃ (λ₃>λ₂); and

a second-C wavelength conversion layer that is formed on or above the second electrode and converts ultraviolet light emitted from the organic layer into the third light. The configurations and structures of the first light emitting element, the second light emitting element, and the third light emitting element only need to be basically similar to those of the light emitting element in Example 1, the first light emitting element, and the second light emitting element.

Specific examples of a wavelength conversion material that is excited by ultraviolet rays and emits blue light include blue light emitting phosphor particles, and more specific examples thereof include BaMgAl₁₀O₁₇:Eu, BaMg₂Al₁₆O₂₇:Eu, Sr₂P₂O₇:Eu, Sr₅ (PO₄)₃Cl:Eu, (Sr, Ca, Ba, Mg)₅ (PO₄)₃Cl:Eu, CaWO₄, and CaWO₄:Pb.

Specific examples of a wavelength conversion material that is excited by ultraviolet rays and emits green light include green light emitting phosphor particles, and more specific examples thereof include LaPO₄:Ce, Tb, BaMgAl₁₀O₁₇:Eu, Mn, Zn₂SiO₄:Mn, MgAl₁₁O₁₉:Ce, Tb, Y₂SiO₅:Ce, Tb, MgAl₁₁O₁₉:CE, Tb, Mn, and Si_{6-Z} Al_{Z}O_{Z}N_{8-Z}:Eu.

Furthermore, specific examples of a wavelength conversion material that is excited by ultraviolet rays and emits red light include red light emitting phosphor particles, and more specific examples thereof include Y₂O₃:Eu, YVO₄:Eu, Y (P, V)O₄:Eu, 3.5MgO·0.5MgF₂·Ge₂:Mn, CaSiO₃:Pb, Mn, Mg₆AsO₁₁:Mn, (Sr, Mg)₃ (PO₄)₃:Sn, La₂O₂S:Eu, and Y₂O₂S:Eu.

Furthermore, specific examples of a wavelength conversion material that is excited by blue light and emits yellow light include yellow light emitting phosphor particles, and more specific examples thereof include yttrium aluminum garnet (YAG)-based phosphor particles.

By using a mixture of two or more types of wavelength conversion materials, emitted light of a color other than yellow, green, and red can be emitted from the wavelength conversion material mixture. Specifically, for example, cyan light may be emitted. In this case, a mixture of green light emitting phosphor particles (for example, LaPO₄:Ce, Tb, BaMgAl₁₀O₁₇:Eu, Mn, Zn₂SiO₄:Mn, MgAl₁₁O₁₉:Ce, Tb, Y₂SiO₅:Ce,Tb, or MgAl₁₁O₁₉:CE, Tb, Mn) and blue light emitting phosphor particles (for example, BaMgAl₁₀O₁₇:Eu, BaMg₂Al₁₆O₂₇:Eu, Sr₂P₂O₇:Eu, Sr₅ (PO₄)₃Cl:Eu, (Sr, Ca, Ba, Mg)₅ (PO₄)₃Cl:Eu, CaWO₄, or CaWO₄:Pb) only needs to be used.

Furthermore, specific examples of a wavelength conversion material that is excited by ultraviolet rays and emits yellow light include yellow light emitting phosphor particles, and more specific examples thereof include YAG-based phosphor particles. Note that the wavelength conversion material may be used singly or in combination of two or more types thereof. Furthermore, by using a mixture of two or more types of wavelength conversion materials, emission light of a color other than yellow, green, and red can be emitted from the wavelength conversion material mixture. Specifically, cyan light may be emitted. In this case, the above mixture of green light emitting phosphor particles and blue light emitting phosphor particles only needs to be used.

Note that the present disclosure can also have the following configurations.

[A01]<<Light Emitting Element . . . First Aspect>>

A light emitting element comprising:

a protrusion surrounding a light emitting region;

a first electrode including a first portion formed on a portion of a base constituting the light emitting region and a second portion extending from the first portion and formed on the protrusion;

an organic layer formed on and above the first electrode;

a second electrode formed on the organic layer;

a first wavelength conversion layer that is formed between the second portion of the first electrode and a portion of the organic layer formed above the protrusion and converts light emitted from the organic layer into light on a long wavelength side; and

a second wavelength conversion layer that is formed on or above the second electrode and converts light emitted from the organic layer into light on a long wavelength side.

[A02] The light emitting element according to [A01], wherein

the light emitting region includes a light emitting region central portion and a light emitting region outer peripheral portion surrounding the light emitting region central portion, and

the first wavelength conversion layer extends to above a portion of the base constituting the light emitting region outer peripheral portion.

[A03] The light emitting element according to [A01] or [A02], wherein the first wavelength conversion layer and the second wavelength conversion layer are made of the same material.

[A04] The light emitting element according to any one of [A01] to [A03], further comprising a wavelength selection unit through which light from at least the second wavelength conversion layer passes.

[A05] The light emitting element according to any one of [A01] to [A04], wherein the first portion of the first electrode and the second portion of the first electrode are made of the same material.

[A06] The light emitting element according to any one of [A01] to [A04], wherein the first portion of the first electrode and the second portion of the first electrode are made of different materials.

[A07] The light emitting element according to any one of [A01] to [A06], wherein the first wavelength conversion layer is covered with a transparent insulating material layer.

[A08] The light emitting element according to [A07], wherein a value of refractive index of a material constituting the first wavelength conversion layer is higher than a value of refractive index of a material constituting the insulating material layer.

[A09] The light emitting element according to any one of [A01] to [A08], wherein the protrusion has a forward tapered shape.

[A010] The light emitting element according to any one of [A01] to [A08], wherein a side surface of the protrusion is perpendicular to the base.

[B01]<<Light Emitting Element . . . Second Aspect>>

A light emitting element comprising:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits first light having a wavelength λ₁;

a second electrode formed on the organic layer;

a first-A wavelength conversion layer that is formed between the second portion of the first electrode and a portion of the organic layer formed above the protrusion and converts the first light emitted from the organic layer into second light having a wavelength λ₂ (λ₂>λ₁); and

a first-B wavelength conversion layer that is formed in a region between the second portion of the first electrode and a portion of the organic layer formed above the protrusion, different from the region where the first-A wavelength conversion layer is formed, and converts the first light emitted from the organic layer into third light having a wavelength λ₃ (λ₃>λ₂).

[B02] The light emitting element according to [B01], further comprising:

a second-A wavelength conversion layer that is formed on or above the second electrode and converts the first light emitted from the organic layer into second light; and

a second-B wavelength conversion layer that is formed on or above the second electrode and converts the first light emitted from the organic layer into third light.

[B03] The light emitting element according to [B01] or [B02], in which

the light emitting region includes a light emitting region central portion and a light emitting region outer peripheral portion surrounding the light emitting region central portion, and

the first wavelength conversion layer extends to above a portion of the base constituting the light emitting region outer peripheral portion.

[B04] The light emitting element according to any one of [B01] to [B03], in which the first portion of the first electrode and the second portion of the first electrode are made of the same material.

[B05] The light emitting element according to any one of [B01] to [B03], in which the first portion of the first electrode and the second portion of the first electrode are made of different materials.

[B06] The light emitting element according to any one of [B01] to [B05], in which the first-A wavelength conversion layer and the first-B wavelength conversion layer are covered with a transparent insulating material layer.

[B07] The light emitting element according to [B06], in which a value of refractive index of a material constituting the first wavelength conversion layer is higher than a value of refractive index of a material constituting the insulating material layer.

[B08] The light emitting element according to any one of [B01] to [B07], further including:

a second-A wavelength conversion layer that is formed on or above the second electrode and converts the first light emitted from the organic layer into second light; and

a second-B wavelength conversion layer that is formed on or above the second electrode and converts the first light emitted from the organic layer into third light.

[B09] The light emitting element according to [B08], in which the first-A wavelength conversion layer and the second-A wavelength conversion layer are made of the same material, and the first-B wavelength conversion layer and the second-B wavelength conversion layer are made of the same material.

[B10] The light emitting element according to any one of [B01] to [B09], in which white light is emitted to the outside.

[B11] The light emitting element according to any one of [B01] to [B10], in which the protrusion has a forward tapered shape.

[B12] The light emitting element according to any one of [B01] to [B10], in which a side surface of the protrusion is perpendicular to the base.

[C01]<<Display Device>>

A display device in which a plurality of light emitting element units each including a first light emitting element, a second light emitting element, and a third light emitting element is arranged, wherein the first light emitting element includes:

a protrusion surrounding a light emitting region;

a first electrode including a first portion formed on a portion of a base constituting the light emitting region and a second portion extending from the first portion and formed on the protrusion;

an organic layer that is formed on the first electrode and emits first light having a wavelength λ₁; and

a second electrode formed on the organic layer, the second light emitting element includes:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits the first light;

a second electrode formed on the organic layer;

a first-A wavelength conversion layer that is formed between the second portion of the first electrode and a portion of the organic layer formed above the protrusion, and converts the first light emitted from the organic layer into second light having a wavelength λ₂ (λ₂>λ₁); and

a second-A wavelength conversion layer that is formed on or above the second electrode and converts the first light emitted from the organic layer into the second light, and

the third light emitting element includes:

a protrusion surrounding a light emitting region;

a first electrode including a first portion formed on a portion of a base constituting the light emitting region and a second portion extending from the first portion and formed on the protrusion;

an organic layer that is formed on and above the first electrode and emits the first light;

a second electrode formed on the organic layer;

a first-B wavelength conversion layer that is formed between the second portion of the first electrode and a portion of the organic layer formed above the protrusion, and converts the first light emitted from the organic layer into third light having a wavelength λ₃ (λ₃>λ₂); and

a second-B wavelength conversion layer that is formed on or above the second electrode and converts the first light emitted from the organic layer into the third light.

[C02] Display Device>>

A display device in which a plurality of light emitting element units each including a first light emitting element, a second light emitting element, and a third light emitting element is arranged, in which

the first light emitting element includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-A wavelength conversion layer that is formed between the second portion of the first electrode and a portion of the organic layer formed above the protrusion and converts ultraviolet light (wavelength: λ₀) emitted from the organic layer into first light having a wavelength λ₁ (λ₁>λ₀); and

a second-A wavelength conversion layer that is formed on or above the second electrode and converts ultraviolet light emitted from the organic layer into the first light,

the second light emitting element includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-B wavelength conversion layer that is formed between the second portion of the first electrode and a portion of the organic layer formed above the protrusion, and converts ultraviolet light emitted from the organic layer into second light having a wavelength λ₂ (λ₂>λ₁); and

a second-B wavelength conversion layer that is formed on or above the second electrode and converts ultraviolet light emitted from the organic layer into the second light, and

the third light emitting element includes:

a protrusion surrounding a light emitting region;

a first electrode including a first portion formed on a portion of the base 26 constituting the light emitting region and a second portion extending from the first portion and formed on the protrusion;

an organic layer that is formed on and above the first electrode and emits ultraviolet light;

a second electrode formed on the organic layer;

a first-C wavelength conversion layer that is formed between the second portion of the first electrode and a portion of the organic layer formed above the protrusion, and converts ultraviolet light emitted from the organic layer into third light having a wavelength λ₃ (λ₃>λ₂); and a second-C wavelength conversion layer that is formed on or above the second electrode and converts ultraviolet light emitted from the organic layer into the third light.

### REFERENCE SIGNS LIST

10, 10₁, 10₂, 10₃, 10₄ LIGHT EMITTING ELEMENT
20 TRANSISTOR
21 GATE ELECTRODE
22 GATE INSULATING LAYER
23 CHANNEL FORMATION REGION
24 SOURCE/DRAIN REGION
25 ELEMENT ISOLATION REGION
26 BASE (INTERLAYER INSULATING LAYER)
26A LOWER INTERLAYER INSULATING LAYER
26B UPPER INTERLAYER INSULATING LAYER
27A, 27B CONTACT PLUG
27C PAD
28, 28A PROTRUSION
28a OPENING FORMED IN PROTRUSION
28B SIDE SURFACE OF PROTRUSION
28′ INSULATING LAYER
30₁, 30₁, 30₂, 30₃ LIGHT EMITTING REGION
30A LIGHT EMITTING REGION CENTRAL PORTION
30B LIGHT EMITTING REGION OUTER PERIPHERAL PORTION
31 FIRST ELECTRODE
31A FIRST PORTION OF FIRST ELECTRODE
31B SECOND PORTION OF FIRST ELECTRODE
32 SECOND ELECTRODE
33 ORGANIC LAYER
34 PROTECTIVE LAYER
35 FLATTENING LAYER
36 SEALING RESIN LAYER
37 SECOND FLATTENING LAYER
38A, 38B, 38E OPTICAL PATH CONTROL UNIT (LENS MEMBER)
38C OPTICAL PATH CONTROL UNIT (LIGHT EXIT DIRECTION CONTROL MEMBER)
38D OPTICAL PATH CONTROL UNIT (LIGHT REFLECTING MEMBER)
41, 41₁, 41₂, 44₁, 44₂ FIRST WAVELENGTH CONVERSION LAYER (FIRST-A WAVELENGTH CONVERSION LAYER, FIRST-B WAVELENGTH CONVERSION LAYER)
42, 42₁, 42₂, 45₁, 45₂ SECOND WAVELENGTH CONVERSION LAYER (SECOND-A WAVELENGTH CONVERSION LAYER, SECOND-B WAVELENGTH CONVERSION LAYER)
43 INSULATING MATERIAL LAYER
51 FIRST SUBSTRATE
52 SECOND SUBSTRATE
52A FIRST SURFACE OF SECOND SUBSTRATE
61 LIGHT REFLECTING LAYER
62 INTERLAYER INSULATING MATERIAL LAYER
CF₁, CF₂, CF₃ WAVELENGTH SELECTION UNIT (COLOR FILTER LAYER)
CF₄ TRANSPARENT FILTER LAYER
LN NORMAL LINE PASSING THROUGH CENTER OF LIGHT EMITTING REGION
LN′ NORMAL LINE PASSING THROUGH CENTER OF OPTICAL PATH CONTROL UNIT (LENS MEMBER)
LN″ NORMAL LINE PASSING THROUGH CENTER OF WAVELENGTH SELECTION UNIT
BM, BM′ LIGHT ABSORPTION LAYER (BLACK MATRIX LAYER)
P, P₁, P₂ REFERENCE POINT

1. A light emitting element comprising:
a protrusion surrounding a light emitting region;
a first electrode including a first portion formed on a portion of a base constituting the light emitting region and a second portion extending from the first portion and formed on the protrusion;
an organic layer formed on and above the first electrode;
a second electrode formed on the organic layer;
a first wavelength conversion layer that is formed between the second portion of the first electrode and a portion of the organic layer formed above the protrusion and converts light emitted from the organic layer into light on a long wavelength side; and
a second wavelength conversion layer that is formed on or above the second electrode and converts light emitted from the organic layer into light on a long wavelength side.

2. The light emitting element according to claim 1, wherein
the light emitting region includes a light emitting region central portion and a light emitting region outer peripheral portion surrounding the light emitting region central portion, and
the first wavelength conversion layer extends to above a portion of the base constituting the light emitting region outer peripheral portion.

3. The light emitting element according to claim 1, wherein the first wavelength conversion layer and the second wavelength conversion layer are made of the same material.

4. The light emitting element according to claim 1, further comprising a wavelength selection unit through which light from at least the second wavelength conversion layer passes.

5. The light emitting element according to claim 1, wherein the first portion of the first electrode and the second portion of the first electrode are made of the same material.

6. The light emitting element according to claim 1, wherein the first portion of the first electrode and the second portion of the first electrode are made of different materials.

7. The light emitting element according to claim 1, wherein the first wavelength conversion layer is covered with a transparent insulating material layer.

8. The light emitting element according to claim 7, wherein a value of refractive index of a material constituting the first wavelength conversion layer is higher than a value of refractive index of a material constituting the insulating material layer.

9. The light emitting element according to claim 1, wherein the protrusion has a forward tapered shape.

10. The light emitting element according to claim 1, wherein a side surface of the protrusion is perpendicular to the base.

11. A light emitting element comprising:
a protrusion surrounding a light emitting region;
a first electrode including a first portion formed on a portion of a base constituting the light emitting region and a second portion extending from the first portion and formed on the protrusion;
an organic layer that is formed on and above the first electrode and emits first light having a wavelength λ₁;
a second electrode formed on the organic layer;
a first-A wavelength conversion layer that is formed between the second portion of the first electrode and a portion of the organic layer formed above the protrusion and converts the first light emitted from the organic layer into second light having a wavelength λ₂ (λ₂>λ₁); and
a first-B wavelength conversion layer that is formed in a region between the second portion of the first electrode and a portion of the organic layer formed above the protrusion, different from the region where the first-A wavelength conversion layer is formed, and converts the first light emitted from the organic layer into third light having a wavelength λ₃ (λ₃>λ₂).

12. The light emitting element according to claim 11, further comprising:
a second-A wavelength conversion layer that is formed on or above the second electrode and converts the first light emitted from the organic layer into second light; and
a second-B wavelength conversion layer that is formed on or above the second electrode and converts the first light emitted from the organic layer into third light.

13. The light emitting element according to claim 11, wherein white light is emitted to an outside.

14. The light emitting element according to claim 11, wherein the protrusion has a forward tapered shape.

15. The light emitting element according to claim 11, wherein a side surface of the protrusion is perpendicular to the base.

16. A display device in which a plurality of light emitting element units each including a first light emitting element, a second light emitting element, and a third light emitting element is arranged, wherein
the first light emitting element includes:
a protrusion surrounding a light emitting region;
a first electrode including a first portion formed on a portion of a base constituting the light emitting region and a second portion extending from the first portion and formed on the protrusion;
an organic layer that is formed on the first electrode and emits first light having a wavelength λ₁; and
a second electrode formed on the organic layer,
the second light emitting element includes:
a protrusion surrounding a light emitting region;
a first electrode including a first portion formed on a portion of a base constituting the light emitting region and a second portion extending from the first portion and formed on the protrusion;
an organic layer that is formed on and above the first electrode and emits the first light;
a second electrode formed on the organic layer;
a first-A wavelength conversion layer that is formed between the second portion of the first electrode and a portion of the organic layer formed above the protrusion, and converts the first light emitted from the organic layer into second light having a wavelength λ₂ (λ₂>λ₁); and
a second-A wavelength conversion layer that is formed on or above the second electrode and converts the first light emitted from the organic layer into the second light, and
the third light emitting element includes:
a protrusion surrounding a light emitting region;
a first electrode including a first portion formed on a portion of a base constituting the light emitting region and a second portion extending from the first portion and formed on the protrusion;
an organic layer that is formed on and above the first electrode and emits the first light;
a second electrode formed on the organic layer;
a first-B wavelength conversion layer that is formed between the second portion of the first electrode and a portion of the organic layer formed above the protrusion, and converts the first light emitted from the organic layer into third light having a wavelength λ₃ (λ₃>λ₂); and
a second-B wavelength conversion layer that is formed on or above the second electrode and converts the first light emitted from the organic layer into the third light.
